(19) United States
(12) Patent Application Publication
(10) Pub. No.: US 2026/0354241 A1
(43) Pub. Date: Nov. 5, 2026

(54) SEMICONDUCTOR PACKAGE AND MANUFACTURING METHOD OF SEMICONDUCTOR PACKAGE

(71) Applicant: FUJIFILM Corporation, Tokyo (JP)

(72) Inventors: Yuki Nara, Shizuoka (JP); DAISUKE KASHIWAGI, Shizuoka (JP); SHUNSUKE KITAJIMA, Shizuoka (JP)

(73) Assignee: FUJIFILM Corporation, Tokyo (JP)

(21) Appl. No.: 19/562,959

(22) Filed: Mar. 11, 2026

Related U.S. Application Data
(63) Continuation of application No. PCT/JP2024/033256, filed on Sep. 18, 2024.

(30) Foreign Application Priority Data
Sep. 22, 2023 (JP) 2023-158193
Apr. 4, 2024 (JP) 2024-060774

(51) Int. Cl. H10W 70/695; C08G 73/12; C08G 73/16; G03F 7/00; G03F 7/031; G03F 7/038; G03F 7/20; H10W 70/09; H10W 70/685; H10W 74/01; H10W 74/10

(52) U.S. Cl. CPC H10W 70/695; C08G 73/126; C08G 73/127; C08G 73/16; G03F 7/031; G03F 7/0387; G03F 7/2004; G03F 7/70008; H10W 70/09; H10W 70/685; H10W 74/01; H10W 74/111

(57) ABSTRACT

There are provided a semiconductor package, including: a sealing layer containing at least one semiconductor die and a sealing material; a re-distribution layer A in contact with the at least one semiconductor die and connected to a circuit of the semiconductor die; a conductive connecting portion connected to the re-distribution layer A; and a substrate connected to the conductive connecting portion, in which the re-distribution layer A is formed by laminating layers including an insulating pattern A and a conductive pattern A existing between patterns of the insulating pattern A, and the insulating pattern A has a via structure, and an angle formed by a side surface of the via structure and a bottom surface of the insulating pattern A is 70° to 110°, and a manufacturing method thereof.

### CROSS-REFERENCE TO RELATED APPLICATIONS

This application is a Continuation of PCT International Application No. PCT/JP2024/033256 filed on Sep. 18, 2024, which claims priority under 35 U.S.C § 119(a) to Japanese Patent Applications No. 2023-158193 filed on Sep. 22, 2023 and No. 2024-060774 filed on Apr. 4, 2024. Each of the above application(s) is hereby expressly incorporated by reference, in its entirety, into the present application.

### BACKGROUND OF THE INVENTION

### 1. Field of the Invention

The present invention relates to a semiconductor package and a manufacturing method of a semiconductor package.

### 2. Description of the Related Art

Currently, a semiconductor package is used in a mobile phone, a tablet terminal, and various other electronic apparatuses. The semiconductor package is a case for protecting a delicate member such as a semiconductor chip or an electronic circuit from an external environment and mounting the member on a base material such as a printed wiring board. The semiconductor package has a function of transmitting a signal generated from the member to another device and transmitting a signal from the other device to the member.

In the mobile phone, the tablet terminal, and other electronic apparatuses, the size reduction, the weight reduction, and the multifunctionalization are advanced, and in order to meet the demand, there is a demand for further size reduction, high integration, high-density mounting, and the like in the semiconductor package, and for example, the progress of a wiring technique using a re-distribution layer is desired.

For example, US2023/0089795A discloses a semiconductor package including a semiconductor die, a sealing material that seals the semiconductor die, a connector disposed on the sealing material, a re-distribution conductive layer including a first conductive pad that is disposed on the sealing material, is in contact with the connector, and is disposed between the sealing material and the connector, a second conductive pad that is in contact with the re-distribution conductive layer, and a semiconductor member that is electrically connected to the second conductive pad, and having a bridge structure in which the first conductive pad is installed at a height lower than a height of the second conductive pad, a first interlayer dielectric layer is disposed on the semiconductor die and the re-distribution conductive layer, the first interlayer dielectric layer includes an opening portion, a part of the opening portion is occupied by a first conductive pad and a first electrical connector, a second interlayer dielectric layer and a third interlayer dielectric layer are disposed above the semiconductor die and below the first interlayer dielectric layer, a third conductive pad is disposed on the second interlayer dielectric layer, is covered by the first interlayer dielectric layer, is fitted in the second interlayer dielectric layer, is disposed on the third interlayer dielectric layer, and connects the first conductive pad and the third conductive pad, the bridge structure including a first conductive via, a routing line, and a second conductive via, in which the via and the first conductive via directly connect the first conductive pad and the routing line, the routing line directly connects the first conductive via and the second conductive via, the second conductive via directly connects the routing line and the third conductive pad, and a bottom surface of the entire routing line is in direct contact with an upper surface of the third interlayer dielectric layer.

US2021/0035908A discloses a semiconductor package including: a first re-distribution layer; a second re-distribution layer; a first semiconductor die; and a second semiconductor die,
in which the first re-distribution layer includes a first surface and a second surface opposite to the first surface,
the second re-distribution layer is disposed on the first surface of the first re-distribution layer,
the first semiconductor die is disposed on the first re-distribution layer and the second re-distribution layer, and is electrically connected to the first re-distribution layer and the second re-distribution layer, and
the second semiconductor die is disposed on the second re-distribution layer and is electrically connected to the second re-distribution layer.

### SUMMARY OF THE INVENTION

Here, in the semiconductor package using the re-distribution layer, it is required to suppress the occurrence of cracks in a long-term heat test and a moisture resistance test.

An object of the present invention is to provide a semiconductor package in which the occurrence of an abnormality such as a crack, peeling, and a void is suppressed in a long-term heat test and a moisture resistance test, and a manufacturing method of the semiconductor package.

Examples of representative embodiments according to the present invention are described below.

<1> A semiconductor package comprising:
a sealing layer containing at least one semiconductor die and a sealing material;
a re-distribution layer A in contact with the at least one semiconductor die and connected to a circuit of the semiconductor die;
a conductive connecting portion connected to the re-distribution layer A; and
a substrate connected to the conductive connecting portion,
in which the re-distribution layer A is formed by laminating layers including an insulating pattern A and a conductive pattern A existing between patterns of the insulating pattern A, and
the insulating pattern A has a via structure, and an angle formed by a side surface of the via structure and a bottom surface of the insulating pattern A is 70° to 110°.

<2> The semiconductor package according to <1>,
in which the sealing layer is a sealing layer including two or more semiconductor dies and a sealing material, and circuits of at least two of the two or more semiconductor dies are connected to the re-distribution layer A.

<3> The semiconductor package according to <1> or <2>, further comprising:
one or more semiconductor dies existing outside the sealing layer and connected to the re-distribution layer A.

<4> The semiconductor package according to any one of <1> to <3>,
in which the re-distribution layer A includes a laminated structure of four or more layers.

<5> The semiconductor package according to any one of <1> to <4>,
in which wiring in the re-distribution layer A includes a line pattern, and a minimum line width of the line pattern is 0.1 to 10 μm.

<6> The semiconductor package according to any one of <1> to <5>,
in which the insulating pattern A contains a resin having a repeating unit represented by Formula (1-1).

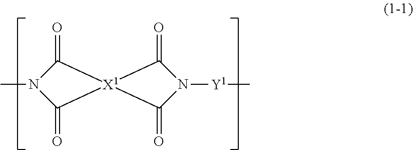

In Formula (1-1), X¹ represents an organic group having 4 or more carbon atoms, and Y¹ represents an organic group having 4 or more carbon atoms.

<7> The semiconductor package according to <6>,
in which X¹ and Y¹ in Formula (1-1) each independently represent an organic group including a structure in which two or more hydrogen atoms are removed from a structure represented by any one of Formulae (V-1) to (V-4).

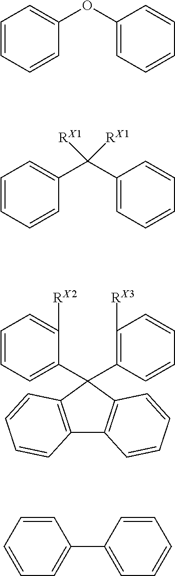

In Formula (V-2), Rx's each independently represent a hydrogen atom, an alkyl group, or a halogenated alkyl group.

In Formula (V-3), R^{X2} and R^{X3} each independently represent a hydrogen atom or a substituent, and R^{X2} and R^{X3} may be bonded to each other to form a ring structure.

<8> The semiconductor package according to any one of <1> to <7>,
in which a breaking elongation of the insulating pattern A is 40% or more.

<9> The semiconductor package according to any one of <1> to <8>,
in which a glass transition temperature of the insulating pattern A is 220 °C or higher.

<10> The semiconductor package according to any one of <1> to <9>,
in which a Young's modulus of the insulating pattern A is 2.7 GPa or more.

<11> A manufacturing method of a semiconductor package, comprising:
a sealing layer forming step of embedding a semiconductor die in a sealing material and forming a sealing layer in which a circuit of the semiconductor die is exposed on one surface and the circuit of the semiconductor die is not exposed on the other surface;
a re-distribution layer A forming step of forming a re-distribution layer A by laminating layers including an insulating pattern A and a conductive pattern A existing between patterns of the insulating pattern A, on the surface of the sealing layer on which the circuit is exposed;
a connecting portion forming step of forming a conductive connecting portion on a surface of the re-distribution layer A different from a surface in contact with the sealing layer; and
a step of connecting the connecting portion and a substrate,
in which the re-distribution layer A forming step includes forming a via structure by the insulating pattern A, and
an angle formed by a side surface of the via structure and a bottom surface of the insulating pattern A is 70° to 110°.

<12> The manufacturing method of a semiconductor package according to <11>,
in which the insulating pattern A is formed of a negative-tone photosensitive resin composition.

<13> The manufacturing method of a semiconductor package according to <12>,
in which the negative-tone photosensitive resin composition contains a resin having at least one repeating unit of a repeating unit represented by Formula (4-1) or a repeating unit represented by Formula (4-2).

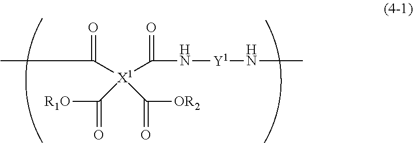

In Formula (4-1), X¹ represents a tetravalent organic group, Y¹ is a divalent organic group, and R¹ and R² each independently represent a hydrogen atom or a monovalent organic group.

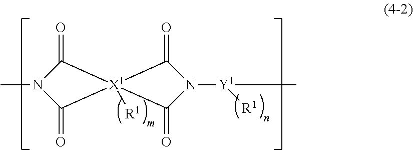

In Formula (4-2), X¹ represents an organic group having 4 or more carbon atoms, Y¹ represents an organic group having 4 or more carbon atoms, R¹'s each independently represent a structure including a polymerizable group, and n and m each independently represent an integer of 0 to 4.

<14> The manufacturing method of a semiconductor package according to <13>,
in which X¹ and Y¹ in Formula (4-1) each independently represent an organic group including a structure in which two or more hydrogen atoms are removed from a structure represented by any one of Formulae (V-1) to (V-4), and X¹ and Y¹ in Formula (4-2) each independently represent an organic group including a structure in which two or more hydrogen atoms are removed from the structure represented by any one of Formulae (V-1) to (V-4).

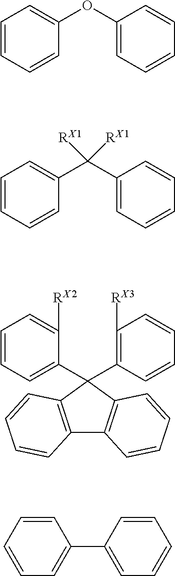

In Formula (V-2), R^{X1}'s each independently represent a hydrogen atom, an alkyl group, or a halogenated alkyl group.

In Formula (V-3), R^{X2} and R^{X3} each independently represent a hydrogen atom or a substituent, and R^{X2} and R^{X3} may be bonded to each other to form a ring structure.

<15> The manufacturing method of a semiconductor package according to any one of <12> to <14>,
in which the negative-tone photosensitive resin composition contains an oxime initiator.

<16> The manufacturing method of a semiconductor package according to any one of <12> to <15>,
in which the negative-tone photosensitive resin composition contains a polymerizable compound having two or more ethylenically unsaturated bonds.

<17> The manufacturing method of a semiconductor package according to any one of <12> to <16>,
in which in the re-distribution layer A forming step, a photosensitive film formed of the negative-tone photosensitive resin composition is exposed using an i-line stepper.

<18> The manufacturing method of a semiconductor package according to <17>, in which a numerical aperture of the i-line stepper is 0.10 to 0.60.

<19> The manufacturing method of a semiconductor package according to <17> or <18>,
in which an exposure illuminance of the i-line stepper is 500 to 50,000 W/m².

<20> The manufacturing method of a semiconductor package according to any one of <17> to <19>,
in which an exposure amount using the i-line stepper is 1 to 2,000 mJ/cm².

<21> The manufacturing method of a semiconductor package according to any one of <11> to <20>,
in which the via structure is formed by development using a solvent as a developer.

According to the present invention, a semiconductor package in which the occurrence of an abnormality such as a crack, peeling, and a void is suppressed in a long-term heat test and a moisture resistance test, and a manufacturing method of the semiconductor package are provided.

### BRIEF DESCRIPTION OF THE DRAWINGS

FIG. 1 is a schematic cross-sectional view showing an example of a re-distribution layer A.

FIG. 2 is an enlarged view of a one-dot chain line portion in FIG. 1.

FIGS. 3A to 3C are schematic cross-sectional views showing a specific example of a conductive connecting portion.

FIG. 4 is a schematic cross-sectional view showing an example of a semiconductor package according to the present invention.

FIG. 5 is a schematic cross-sectional view showing another example of the semiconductor package according to the present invention.

FIGS. 6A to 6E are schematic cross-sectional views showing an example of a manufacturing method of a semiconductor package according to the present invention.

FIGS. 7A to 7C are schematic cross-sectional views showing another example of the manufacturing method of a semiconductor package according to the present invention.

FIG. 8 is a schematic cross-sectional view showing a configuration of a laminate used in Examples.

### DESCRIPTION OF THE PREFERRED EMBODIMENTS

Hereinafter, the main embodiments according to the present invention will be described. However, the present invention is not limited to the specified embodiments.

In the present specification, a numerical value range described by using “to” means a range including numerical values described before and after the preposition “to” as a lower limit value and an upper limit value, respectively.

In the present specification, the term “step” means not only an independent step but also a step that cannot be clearly distinguished from other steps as long as the desired action of the step can be achieved.

In describing a group (an atomic group) in the present specification, in a case where a description of substitution and unsubstitution is not provided, the description means the group includes a group (an atomic group) having a substituent as well as a group (an atomic group) having no substituent. For example, the “alkyl group” includes not only an alkyl group that does not have a substituent (an unsubstituted alkyl group) but also an alkyl group that has a substituent (a substituted alkyl group).

In the present specification, the “exposure” includes not only exposure using light but also exposure using corpuscular beams such as an electron beam and an ion beam, unless otherwise specified. In addition, examples of the light that is used for exposure include an actinic ray such as a bright line spectrum of a mercury lamp, a far ultraviolet ray represented by an excimer laser, an extreme ultraviolet ray (EUV light), an X-ray, or an electron beam, and a radioactive ray.

In the present specification, “(meth)acrylate” means one or both of “acrylate” and “methacrylate”, “(meth)acryl” means one or both of “acryl” and “methacryl”, and “(meth)acryloyl” means one or both of “acryloyl” and “methacryloyl”.

In the structural formulae of the present specification, Me represents a methyl group, Et represents an ethyl group, Bu represents a butyl group, and Ph represents a phenyl group.

In the present specification, the total solid content refers to the total mass of components excluding a solvent from the entire components of the composition. In addition, in the present specification, the concentration of solid contents is a mass percentage of other components excluding a solvent with respect to the total mass of the composition.

In the present specification, weight-average molecular weight (Mw) and number-average molecular weight (Mn) are each a value measured using gel permeation chromatography (GPC) unless otherwise specified, which are defined as a polystyrene equivalent value. In the present specification, the weight-average molecular weight (Mw) and the number-average molecular weight (Mn) can be determined, for example, by using HLC-8220 GPC (manufactured by Tosoh Corporation) and using GUARD COLUMN HZ-L, TSKgel Super HZM-M, TSK gel Super HZ4000, TSK gel Super HZ3000, and TSK gel Super HZ2000 (all of which are manufactured by Tosoh Corporation) as a column connected in series. The measurements of the above molecular weights are carried out using tetrahydrofuran (THF) as an eluent unless otherwise specified. However, N-methyl-2-pyrrolidone (NMIP) can also be used in a case where THF is not suitable as the eluent, for example, in a case where the solubility is low. In addition, the detection in GPC measurement is carried out using a detector with an ultraviolet ray (a UV ray) of a wavelength of 254 nm unless otherwise specified.

In the present specification, in a case where the positional relationship of respective layers constituting the laminate is described as “upper” or “lower”, it suffices that another layer is on the upper side or the lower side of the reference layer among the plurality of layers of interest. That is, a third layer or element may be further interposed between the reference layer and the other layer, and the reference layer and the other layer need not be in contact with each other. Unless otherwise specified, the direction in which the layers are laminated on the base material (sealing layer) is referred to as “upward”, or in a case where a resin composition layer is present, the direction from the base material to the resin composition layer is referred to as “upper”. The opposite direction thereof is referred to as “downward”. Furthermore, such a setting of upward and downward directions is for convenience in the present specification, and in a practical aspect, the “upward” direction in the present specification may be different from a vertically upward direction.

In the present specification, a composition may contain, as each component contained in the composition, two or more compounds corresponding to the component unless otherwise specified. The content of each component in the composition means the total content of all the compounds corresponding to the component unless otherwise specified.

In the present specification, unless otherwise specified, the temperature is 23 °C, the atmospheric pressure is 101,325 Pa (1 atm), and the relative humidity is 50% RH.

In addition, in the present specification, a combination of preferred aspects is a more preferred aspect.

### (Semiconductor Package)

A semiconductor package according to the embodiment of the present invention includes: a sealing layer containing at least one semiconductor die and a sealing material; a re-distribution layer A in contact with the at least one semiconductor die and connected to a circuit of the semiconductor die; a conductive connecting portion connected to the re-distribution layer A; and a substrate connected to the conductive connecting portion, in which the re-distribution layer A is formed by laminating layers including an insulating pattern A and a conductive pattern A existing between patterns of the insulating pattern A, and the insulating pattern A has a via structure, and an angle formed by a side surface of the via structure and a bottom surface of the insulating pattern A is 70° to 110°.

Hereinafter, the angle between the side surface of the via structure and the bottom surface of the insulating pattern A is also simply referred to as a “taper angle”.

In the semiconductor package according to the embodiment of the present invention, the occurrence of an abnormality such as a crack, peeling, and a void is suppressed in a long-term heat test and a moisture resistance test.

Although the mechanism by which the above effect is obtained is not revealed, it is presumed as follows.

In the related art, a via structure for connecting adjacent layers is formed in the re-distribution layer, but an abnormality such as a crack, peeling, and a void may occur in the insulating pattern near the via structure in a long-term heat test and a moisture resistance test.

The via structure is formed by, for example, forming a via hole by patterning an insulating material and embedding a metal such as copper in the via hole.

However, in a case where the resolution of the insulating pattern is low, the shape of the via hole may be, for example, an inverted truncated cone, and the taper angle may be small.

It is presumed that, in a case where the taper angle is small in this way, the stress is concentrated on a portion where the side surface of the via structure and the bottom surface of the insulating pattern A intersect each other due to the expansion of the insulating pattern A in the long-term heat test and the moisture resistance test, and thus an abnormality such as a crack, peeling, and a void is likely to occur.

On the contrary, it is presumed that, in a case where the taper angle is too large, the stress is concentrated on a portion where the side surface of the via structure and the upper surface of the insulating pattern A intersect each other, and thus an abnormality such as a crack, peeling, and a void is likely to occur.

Therefore, the present inventors have considered adopting a configuration in which the taper angle is set to 70° to 110°. With the above-described configuration, it is considered that the concentration of the stress is suppressed, and thus an abnormality such as a crack, peeling, and a void is unlikely to occur.

Hereinafter, the semiconductor package according to the embodiment of the present invention will be described in detail.

### <Sealing Layer>

It is preferable that the sealing layer includes a sealing material and at least one semiconductor die, and the semiconductor die is embedded in the sealing material.

### [Sealing Material]

The sealing material is not particularly limited, and a known sealing material can be used, but it is preferably a cured sealing material obtained by curing a curable composition (curing type adhesive).

As the curable composition, various curable compositions such as a photocurable composition such as an ultraviolet curable type, a reactive curable composition such as an anaerobic curable type or a moisture curable type, and a thermosetting composition can be used. In addition, a two-liquid mixed composition, an adhesive sheet, or the like may be used.

As the curable composition, a curable resin composition is preferable, and examples of the resin used include an epoxy resin, a silicone resin, an acrylic resin, a phenol resin, a polyimide resin, an imide resin, a polyvinyl chloride (PVC) resin, a polyvinyl butyral (PVB) resin, and an ethylene vinyl acetate (EVA) resin.

The curable resin composition may further include other components such as a filler, a polymerization initiator, a curing agent, and a drying agent, in addition to the resin. As these components, components known in the related art can be used without particular limitation.

### [Semiconductor Die]

In the present invention, the semiconductor die refers to a chip in which a circuit is incorporated, and a die that exhibits a function such as a memory and logic.

It is preferable that the semiconductor die is a semiconductor chip. The semiconductor die is obtained, for example, by forming a circuit pattern on a substrate such as silicon and dicing the circuit pattern.

The semiconductor die is not particularly limited, and examples thereof include a memory IC, a logic IC, an ASIC, and an integrated circuit obtained by further integrating these.

The number of semiconductor dies sealed in the sealing layer is not particularly limited, and may be one or a plurality. Here, an aspect in which the sealing layer is a sealing layer including two or more semiconductor dies and a sealing material, and circuits of two or more of the two or more semiconductor dies are connected to the re-distribution layer A is also one of the preferred aspects of the present invention.

The size of the semiconductor die is not particularly limited, and examples thereof include a semiconductor die having one side of 100 μm to 10 cm.

The semiconductor die may comprise a conductive member connected to the circuit in the semiconductor die.

Examples of the conductive member include a conductive pad.

Examples of the material of the conductive member include copper, aluminum, nickel, vanadium, titanium, chromium, cobalt, gold, tungsten, tin, silver, and an alloy containing at least one of these metals, and copper, aluminum, or an alloy containing at least one of these metals is preferable, copper or an alloy containing copper is more preferable, and copper is still more preferable.

It is preferable that a circuit in the semiconductor die or the conductive member is exposed on one surface of the sealing layer, and it is preferable that a circuit in the semiconductor die or the conductive member is exposed on one surface of the sealing layer and neither a circuit in the semiconductor die nor the conductive member is exposed on the other surface of the sealing layer.

In addition, it is preferable that the exposed circuit or the conductive member connected to the circuit is connected to the re-distribution layer A described later.

### —Conductive Portion—

It is preferable that the sealing layer further includes a conductive portion that causes the one surface and the other surface of the sealing layer to communicate with each other. Such a conductive portion is preferably included as, for example, a conductive through-via penetrating the sealing layer.

The conductive portion connects, for example, the re-distribution layer A and another member.

A thickness of the sealing layer is not particularly limited, and may be determined in consideration of a thickness of the semiconductor die or the like, but is, for example, preferably 1 μm to 500 μm and more preferably 10 μm to 200 μm.

### <Re-Distribution Layer A>

The re-distribution layer A is a layer that is in contact with at least one of the semiconductor dies and that is connected to a circuit of the semiconductor die, and is formed by laminating layers including an insulating pattern A and a conductive pattern A that is present between patterns of the insulating pattern A.

Here, the conductive pattern A is connected to the semiconductor die in the sealing layer.

For example, an aspect in which at least a part of the conductive pattern A and a circuit in the semiconductor member exposed on one surface of the sealing layer or a conductive member connected to the circuit are in contact with each other is also one of the preferred aspects.

### [Insulating Pattern A]

A volume resistivity of the insulating pattern A at 25 °C is not particularly limited, but is preferably 1×10⁸ Ω·cm or more, more preferably 1×10¹⁰ Ω·cm or more, and still more preferably 1×10¹² Ω·cm or more. The upper limit thereof is not particularly limited, but is, for example, preferably 1×10¹⁸ Ω·cm or less.

The insulating pattern A has a via structure.

The via structure is a structure for connecting adjacent layers in the re-distribution layer A, and is preferably a substantially cylindrical structure, a substantially polygonal columnar structure, or the like.

A diameter of the via structure (an equivalent circle diameter in a case of a polygonal columnar shape) is not particularly limited, but is preferably 1 to 20 μm and more preferably 2 to 10 μm.

It is preferable that the conductive pattern A is disposed in the via structure.

In addition, another layer such as a seed layer for forming the conductive pattern A may be further formed in the via structure.

In the re-distribution layer A, an angle (taper angle) between the side surface of the via structure and the bottom surface of the insulating pattern A is 70° to 110°, preferably 75° to 105°, and more preferably 80° to 100°.

Here, in a case where the side surface of the via structure is distorted, the taper angle is an angle between a straight line connecting an end point of the bottom surface of the insulating pattern A and an end point of an exposed portion on the upper surface side of the insulating pattern A and the bottom surface of the insulating pattern A.

In the present specification, the bottom surface refers to a surface on a side close to the sealing layer, and the upper surface refers to a surface on a side far from the sealing layer.

The taper angle is obtained by cutting the semiconductor package along a surface including the center of the via structure, polishing a cross section with a milling device ArBlade 5000 (manufactured by Hitachi, Ltd.), acquiring an SEM image using FE-SEM SU-4800 (manufactured by Hitachi, Ltd.), and measuring an angle between the bottom surface of the insulating pattern A and the side surface of the insulating pattern A.

Details of the measurement method can be found in Examples described later.

The taper angle can be adjusted by a structure, a content, a numerical aperture of exposure light, an exposure amount, an exposure illuminance, a type of developer in development, and the like of a resin, a polymerizable compound, and the like contained in a negative-tone photosensitive resin composition described later, which are included in the insulating pattern A.

The insulating pattern A preferably includes a resin, and more preferably includes a polyimide.

In addition, the insulating pattern A is preferably a cured substance of a composition for forming an insulating pattern A, which will be described later.

The insulating pattern A preferably contains a resin having a repeating unit represented by Formula (1-1).

Such a resin is included in the insulating pattern, for example, as a polyimide contained in the negative-tone photosensitive resin composition described later or a polyimide obtained by cyclization of a polyimide precursor contained in the negative-tone photosensitive resin composition.

Here, in the insulating pattern, it is preferable that a polymerizable group in the polyimide or the polyimide precursor contained in the negative-tone photosensitive resin composition described later is polymerized.

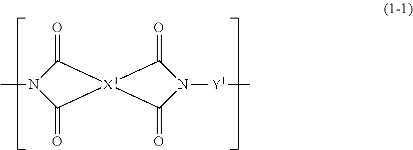

In Formula (1-1), X¹ represents an organic group having 4 or more carbon atoms, and Y¹ represents an organic group having 4 or more carbon atoms.

Preferred aspects of X¹ and Y¹ in Formula (1-1) are the same as preferred aspects of X¹ and Y¹ in Formula (4-2) described later.

Among these, it is preferable that X¹ and Y¹ in Formula (1-1) are each independently an organic group including a structure in which two or more hydrogen atoms are removed from a structure represented by any one of Formulae (V-1) to (V-4).

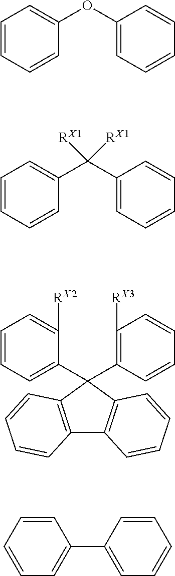

In Formula (V-2), R^{X1}'s each independently represent a hydrogen atom, an alkyl group, or a halogenated alkyl group.

In Formula (V-3), R^{X2} and R^{X3} each independently represent a hydrogen atom or a substituent, and R^{X2} and R^{X3} may be bonded to each other to form a ring structure.

Preferred aspects of the organic group including a structure in which two or more hydrogen atoms are removed from a structure represented by any one of Formulae (V-1) to (V-4) will be described later.

The breaking elongation of the insulating pattern A is preferably 30% or more, more preferably 40% or more, and still more preferably 50% or more.

The upper limit of the breaking elongation is not particularly limited, but is, for example, preferably 100% or less.

The breaking elongation is measured at 25 °C and 65% RH (relative humidity) in an environment using a tensile tester (TENSILON) at a crosshead speed of 300 mm/min, with reference to the method described in JIS-K6251.

The breaking elongation can be adjusted by a structure, a content, and the like of a resin, a polymerizable compound, and the like contained in the negative-tone photosensitive resin composition described later.

A glass transition temperature of the insulating pattern A is preferably 200 °C or higher, more preferably 210 °C or higher, and still more preferably 220 °C or higher.

The upper limit of the glass transition temperature is not particularly limited; however, it can be set to, for example, 350 °C or lower.

The glass transition temperature can be measured as a temperature of an intersection between a straight line obtained by extending a baseline on a low-temperature side in a differential scanning calorimetry curve to a high-temperature side and a tangent line drawn at a point where a gradient of a curve of a step-like change portion of the glass transition is maximized, by changing a temperature condition of the insulating pattern A in the following order of (1) to (4).
(1) The temperature is raised from 25 °C to 300 °C at a rate of 10 °C/min.
(2) Cooling is carried out from 300 °C to 25 °C.
(3) The temperature is raised from 25 °C to 500 °C at a rate of 10 °C/min.
(4) Cooling is carried out from 500 °C to 25 °C.

The glass transition temperature can be adjusted by a structure, a content, and the like of a specific resin, a polymerizable compound, and the like contained in the negative-tone photosensitive resin composition described later.

A Young's modulus of the insulating pattern A is preferably 2.7 GPa or more.

The Young's modulus is more preferably 2.8 GPa or more and still more preferably 3.0 GPa or more. The upper limit of the Young's modulus is not particularly limited; however, it is, for example, preferably 10.0 GPa or less.

The Young's modulus (modulus) is measured using a tensile tester (Tensilon) in an environment of 25 °C and 65% RH (relative humidity) at a crosshead speed of 300 mm/min, with reference to the method described in JIS-K6251:2017.

A coefficient of thermal expansion (CTE) of the insulating pattern A is preferably 0 to 80 ppm/K, more preferably 5 to 75 ppm/K, and still more preferably 10 to 70 ppm/K.

The coefficient of thermal expansion of the insulating pattern A is measured by the following method.

The insulating pattern A is measured for elongation (displacement) while changing the temperature using a thermal mechanical analyzer/thermal expansion coefficient measuring device Discovery TMA (manufactured by TA Instruments Japan Inc.).

The temperature rising and falling conditions at the time of evaluation are set to the following (1) to (4).
(1) The temperature is raised from room temperature to 130 °C at a temperature rising rate of 5 °C/min.
(2) The temperature is cooled from 130 °C to 10 °C at a cooling rate of 5 °C/min.
(3) The temperature is raised from 10 °C to 220 °C at a temperature rising rate of 5 °C/min.
(4) The sample is naturally cooled to room temperature.

In the above-described temperature rising and falling processes (1) to (4), the elongation (displacement) of the specimen is measured, and a calculation is carried out to determine a value obtained by dividing the elongation (displacement) of the specimen at 25 °C and 125 °C in a longitudinal direction in the process (3) by the temperature, where the value is defined as the coefficient of thermal expansion.

### [Conductive Pattern A]

A volume resistivity of the conductive pattern A at 25 °C is not particularly limited, but is preferably 1×10⁻⁵ Ω·cm or less, more preferably 1×10⁻⁶ Ω·cm or less, and still more preferably 1×10⁻⁷ Ω·cm or less. The lower limit thereof is not particularly limited, but is, for example, preferably 1×10⁻¹¹ Ω·cm or more.

As a material constituting the conductive pattern A, a metal is preferable.

The metal is not particularly limited, and an existing metal can be used, but examples thereof include copper, aluminum, nickel, vanadium, titanium, chromium, cobalt, gold, tungsten, tin, silver, and an alloy containing at least one of these metals, and copper, aluminum, or an alloy containing at least one of these metals is preferable, copper or an alloy containing copper is more preferable, and copper is still more preferable.

The conductive pattern A preferably includes a line and space pattern. The line pattern is included, for example, as a line and space pattern in which the conductive pattern A is a line portion and the insulating pattern A is a space portion.

In a case where the conductive pattern A includes a line pattern, a minimum line width of the line pattern is preferably 0.1 to 20 μm, more preferably 0.2 to 15 μm, and still more preferably 0.3 to 10 μm.

It is preferable that the conductive pattern A has a barrier layer at least in a part thereof.

It is preferable that the conductive pattern A has a barrier layer at least at one of an interface between the conductive pattern A and the insulating pattern A or an interface between the re-distribution layer A and the outside (that is, a position where the conductive pattern A is exposed in the re-distribution layer A).

By having the barrier layer, it is possible to suppress the material (metal or the like) constituting the conductive pattern from being transferred (migrated) to the insulating pattern A or other members such as the sealing layer.

The member constituting the barrier layer is not particularly limited, and examples thereof include tungsten, titanium, and an alloy containing at least one of these metals.

In addition, the barrier layer can be formed of a metal having a lower ionization tendency than the material constituting the conductive pattern A.

### [Configuration of Re-Distribution Layer A]

The re-distribution layer A is formed to be electrically connectable to a conductive connecting portion described later.

Specifically, the re-distribution layer A can have an aspect in which the conductive pattern A is exposed on the surface of the re-distribution layer A on a surface different from the surface in contact with the sealing layer, or the barrier layer in contact with the conductive pattern A is exposed.

For example, the exposed conductive pattern A or the barrier layer is connected to a conductive connecting portion described later, whereby the re-distribution layer A is electrically connected to other members.

In addition, the re-distribution layer A may include a conductive pad in the outermost layer (that is, the layer farthest from the sealing layer).

As a material of the conductive pad, a metal is preferable.

The metal is not particularly limited, and an existing metal can be used, but examples thereof include copper, aluminum, nickel, vanadium, titanium, chromium, cobalt, gold, tungsten, tin, silver, and an alloy containing at least one of these metals, and copper, aluminum, or an alloy containing at least one of these metals is preferable, copper or an alloy containing copper is more preferable, and copper is still more preferable.

In a case where the conductive pad is provided, the conductive pattern A is electrically connected to the other members via the conductive pad.

The re-distribution layer A is a layer formed by laminating layers including the insulating pattern A and the conductive pattern A.

The re-distribution layer A preferably includes 1 to 20 layers including the insulating pattern A and the conductive pattern A, and more preferably includes 2 to 10 layers.

A thickness of the re-distribution layer A is preferably 1 to 100 μm, more preferably 1 to 50 μm, and still more preferably 1 to 20 μm.

An example of the re-distribution layer A will be described with reference to the drawing.

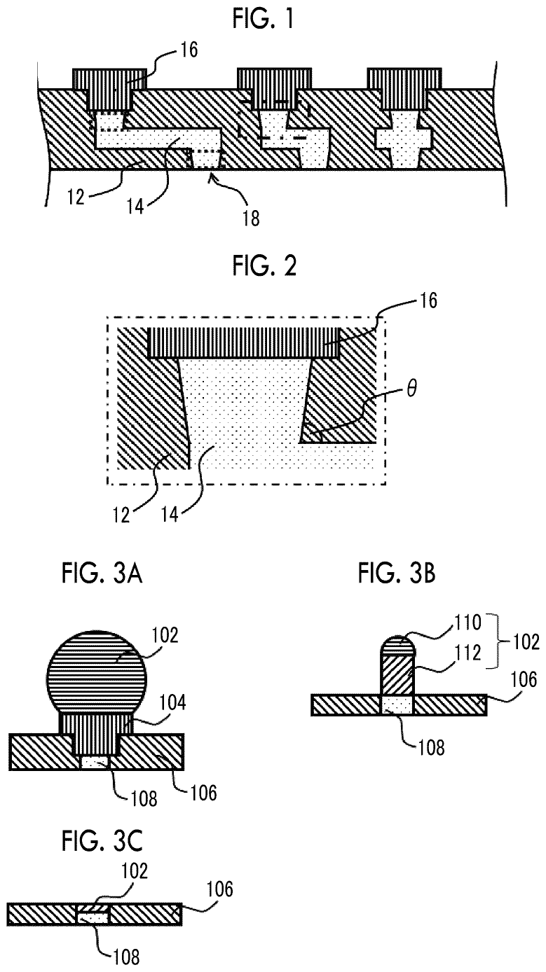

FIG. 1 is a schematic cross-sectional view showing an example of the re-distribution layer A.

The re-distribution layer A is formed to include an insulating pattern A12, a conductive pattern A14, and a conductive pad 16.

The conductive pattern A14 is connected to the semiconductor die included in the sealing layer in an exposed portion 18.

A conductive connecting portion described later is further formed on the conductive pad.

Here, a portion surrounded by a broken line in the re-distribution layer A corresponds to the via structure.

In FIG. 1, the re-distribution layer A is shown as a case where three layers including the insulating pattern A and the conductive pattern A are included.

FIG. 2 is an enlarged view of a one-dot chain line portion in FIG. 1.

In FIG. 2, θ is an angle (taper angle) between the side surface of the via structure and the bottom surface of the insulating pattern A.

### <Other Semiconductor Dies>

It is also preferable that the semiconductor package according to the embodiment of the present invention further includes one or more semiconductor dies that are present outside the sealing layer and that are connected to the re-distribution layer A.

A preferred aspect of the other semiconductor die is the same as the preferred aspect of the semiconductor die included in the sealing layer described above, except that the other semiconductor die is not sealed in the sealing layer.

For example, it is preferable that the other semiconductor die is disposed on a surface of the sealing layer opposite to the re-distribution layer A and is connected to the re-distribution layer A by the above-described conductive portion.

In a case where the semiconductor package according to the embodiment of the present invention includes the other semiconductor die, the number of the other semiconductor die may be 1 or more, and is preferably 1 to 10 and more preferably 1 to 4.

In such an aspect, in a case where two or more semiconductor dies are included, the semiconductor dies may be the same or different from each other.

### <Conductive Connecting Portion>

The semiconductor package according to the embodiment of the present invention further includes a conductive connecting portion on a surface of the re-distribution layer A different from a surface of the re-distribution layer A in contact with the sealing layer.

The conductive connecting portion is preferably any of a substantially spherical cap shape, a substantially columnar shape, or a bonding pad structure having an average diameter of 5 μm or less.

In addition, the semiconductor package according to the embodiment of the present invention may include a barrier layer between the re-distribution layer A and the conductive connecting portion.

In a case where the conductive connecting portion has a substantially spherical cap shape, the conductive connecting portion is preferably a solder ball, a ball grid array (BGA) ball, or a C4 bump.

FIG. 3A is a schematic cross-sectional view in a case where the conductive connecting portion has a substantially spherical cap shape.

In FIG. 3A, a conductive connecting portion 102 is connected to a conductive pattern A108 in an outermost layer of the re-distribution layer A through a conductive pad 104, and the conductive pattern A108 is formed between insulating patterns A106 in the outermost layer of the re-distribution layer A.

Here, a barrier layer may be formed between the conductive pad 104 and the conductive pattern A108.

In a case where the conductive connecting portion has a substantially spherical cap shape, a material constituting the conductive connecting portion is not particularly limited, but is preferably Sn, Pb, Ag, Cu, Ni, Bi, or an alloy containing any of these.

In a case where the conductive connecting portion has a substantially spherical cap shape, a height of the conductive connecting portion is preferably 50 μm or less, more preferably 20 to 50 μm, and still more preferably 20 to 40 μm.

In a case where the conductive connecting portion has a substantially columnar shape, the conductive connecting portion is preferably a pillar having a solder member on an upper portion.

FIG. 3B is a schematic cross-sectional view in a case where the conductive connecting portion has a substantially columnar shape.

In FIG. 3B, the conductive connecting portion 102 is a member consisting of a solder member 110 and a pillar 112.

In FIG. 3B, the solder member 110 is shown as a hemispherical shape, but the shape thereof is not particularly limited, and may be a shape having a flat upper portion such as a columnar shape.

In FIG. 3B, the conductive connecting portion 102 is connected to the conductive pattern A108, and the conductive pattern A108 is formed between the insulating patterns A106.

In a case where the conductive connecting portion has a substantially columnar shape, a material constituting the pillar is not particularly limited, but is preferably Sn, Pb, Ag, Cu, Ni, Bi, or an alloy containing any of these, and more preferably Cu.

In a case where the solder member is included, a material constituting the solder member is not particularly limited, but is preferably Sn, Pb, Ni, Bi, or an alloy containing any of these.

In a case where the conductive connecting portion has a substantially columnar shape, a height of the conductive connecting portion is preferably 20 μm or less, more preferably 10 to 20 μm, and still more preferably 10 to 15 μm.

In a case where the conductive connecting portion has a bonding pad structure having an average diameter of 5 μm or less, the conductive connecting portion is preferably formed to be substantially flat such that the conductive connecting portion and an insulating member are aligned in height with the insulating pattern A.

FIG. 3C is a schematic cross-sectional view in a case where the conductive connecting portion has a bonding pad structure having an average diameter of 5 μm or less.

In FIG. 3C, the conductive connecting portion 102 is connected to the conductive pattern A108, and the conductive pattern A108 is formed between the insulating patterns A106.

In a case where the conductive connecting portion has a bonding pad structure having an average diameter of 5 μm or less, a material constituting the bonding pad structure is not particularly limited, but is preferably Sn, Pb, Ag, Cu, Ni, Bi, or an alloy containing any of these, and more preferably Cu.

In a case where the conductive connecting portion has a bonding pad structure having an average diameter of 5 μm or less, the average diameter is 5 μm or less, preferably 1 to 5 μm and more preferably 2 to 5 μm.

The average diameter is an average diameter of an upper surface of the bonding pad structure. In a case where the upper surface of the bonding pad structure is not circular, the average diameter means an average value of equivalent circle diameters.

### <Substrate>

The semiconductor package according to the embodiment of the present invention has a substrate connected to the conductive connecting portion.

The material of the substrate is not particularly limited, and it may be a semiconductor production material such as silicon, silicon nitride, polysilicon, silicon oxide, amorphous silicon, quartz, glass, an optical film, a ceramic material, a vapor deposited film, magnetic film, a reflection film, a metal material such as Ni, Cu, Cr, or Fe, paper, a spin on glass (SOG), a thin film transistor (TFT) array material, an electrode plate of a plasma display panel (PDP), or the like, which is not particularly limited. A layer such as an adhesion layer or an oxide layer may be provided on a surface of these substrates by hexamethyldisilazane (HMDS), a sealing material (epoxy molding compound: EMC), or the like.

The substrate may have a wafer shape or a panel shape.

In the present invention, in particular, the semiconductor production material is preferable, and the silicon substrate (silicon wafer) is more preferable.

The substrate may have an electronic circuit region including an electronic circuit. In addition, the electronic circuit may have an element such as a semiconductor. In addition, it is preferable that the electronic circuit is electrically bonded to the conductive pattern A.

In addition, the substrate may further include a conductive member for connecting to another member on a surface different from a surface connected to the conductive pattern A.

### Specific Example of Semiconductor Package

Hereinafter, a specific example of an aspect of the semiconductor package according to the embodiment of the present invention will be described with reference to the drawing, but the present invention is not limited thereto.

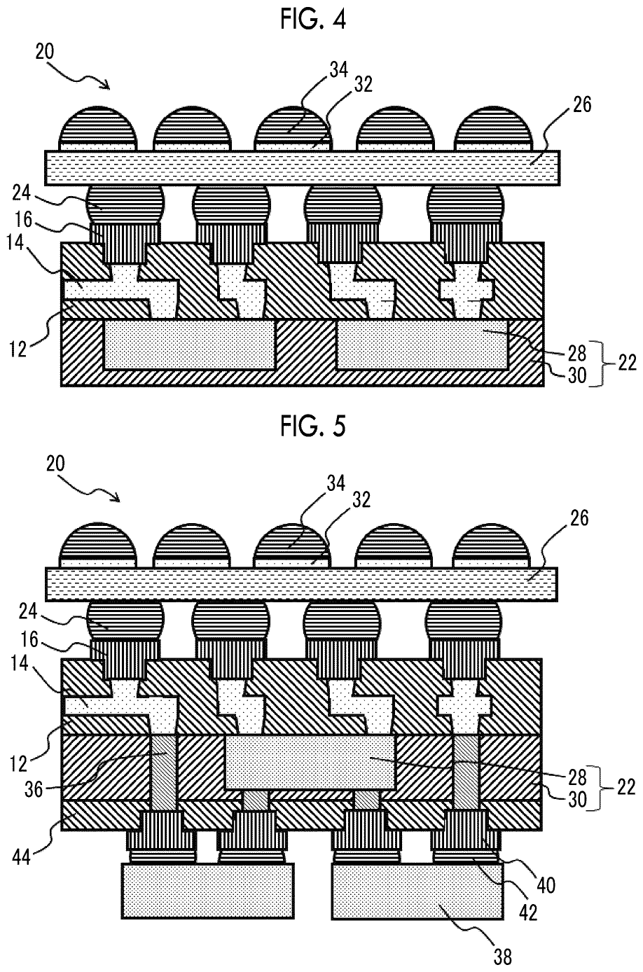

FIG. 4 is a schematic cross-sectional view showing an example of the semiconductor package according to the embodiment of the present invention.

In FIG. 4, a semiconductor package 20 includes a sealing layer 22, a re-distribution layer A including an insulating pattern A12, a conductive pattern A14, and a conductive pad 16, a conductive connecting portion 24, and a substrate 26.

In FIG. 4, the thicknesses of the layers are changed as appropriate to make it easy to check the drawings, and in reality, for example, the thickness of the re-distribution layer A is several tens to several hundredths of the thickness of the sealing layer 22. The same applies to the other drawings.

The sealing layer 22 includes two semiconductor dies 28 and a sealing material 30.

The semiconductor die 28 is connected to the conductive pattern A14 in the re-distribution layer A.

In addition, in FIG. 4, the conductive connecting portion 24 is formed on a side of the re-distribution layer A opposite to the sealing layer 22. In FIG. 4, the conductive connecting portion 24 is shown as a substantially spherical cap shape, but as described above, may have another shape such as a substantially columnar shape or a bonding pad.

In FIG. 4, the conductive connecting portion 24 is connected to the substrate 26, and an electrode 32 and other conductive connecting portions 34 for connecting to another member are disposed on a side of the substrate 26 opposite to the conductive connecting portion 24. A known underfill material may be filled in a space between the substrate 26 and the re-distribution layer A.

FIG. 5 is a schematic cross-sectional view showing another example of the semiconductor package according to the embodiment of the present invention.

Among the members to which the reference numerals are assigned in FIG. 5, the members to which the same reference numerals as in FIG. 4 are assigned are the same as the members in FIG. 4.

In the semiconductor package 20 in FIG. 5, the sealing layer 22 includes only one semiconductor die 28, and the conductive pattern A14 is connected to two other semiconductor dies 38 through a conductive through-via 36, other conductive pads 40, and other conductive connecting portions 42 formed in the sealing layer 22. Here, an insulating layer 44 is formed between the sealing layer 22 and other conductive pads 40.

Here, a known underfill material may be filled in a space between the re-distribution layer A and the substrate 26.

In addition, a known underfill material may be filled in a space between the insulating layer 44 and the sealing layer 22.

Further, the semiconductor die 38 may be sealed with a known sealing material.

### (Manufacturing Method of Semiconductor Package)

A manufacturing method of a semiconductor package according to the embodiment of the present invention includes: a sealing layer forming step of embedding a semiconductor die in a sealing material and forming a sealing layer in which a circuit of the semiconductor die is exposed on one surface and the circuit of the semiconductor die is not exposed on the other surface; a re-distribution layer A forming step of forming a re-distribution layer A by laminating layers including an insulating pattern A and a conductive pattern A existing between patterns of the insulating pattern A, on the surface of the sealing layer on which the circuit is exposed; a connecting portion forming step of forming a conductive connecting portion on a surface of the re-distribution layer A different from a surface in contact with the sealing layer; and a step of connecting the connecting portion and a substrate, in which the re-distribution layer A forming step includes forming a via structure by the insulating pattern A, and an angle formed by a side surface of the via structure and a bottom surface of the insulating pattern A is 70° to 110°.

According to the manufacturing method of a semiconductor package according to the embodiment of the present invention, the semiconductor package according to the embodiment of the present invention described above can be obtained. That is, a semiconductor package in which the occurrence of an abnormality such as a crack, peeling, and a void is suppressed in a long-term heat test and a moisture resistance test can be obtained.

### <Sealing Layer Forming Step>

The manufacturing method of a semiconductor package according to the embodiment of the present invention includes a sealing layer forming step.

By the sealing layer forming step, a sealing layer including a sealing material and a semiconductor die embedded in the sealing material is obtained, in which a circuit of the semiconductor die is exposed on one surface and a circuit of the member is not exposed on the other surface.

The sealing layer forming step can be performed, for example, by disposing the semiconductor die on a carrier wafer (temporary support), and applying and curing the above-described curable composition to embed the semiconductor die.

In addition, a known temporary adhesive layer may be formed on the carrier wafer.

The application and curing thereof can be performed with reference to known methods.

Preferred aspects of the curable composition and the semiconductor die are as described above.

In addition, in the sealing layer forming step, the surface of the sealing material may be polished after curing.

Examples of the polishing include chemical mechanical polishing (CMP) and physical polishing, but the present invention is not limited thereto.

For example, by polishing the sealing material after curing on a surface side of the semiconductor die having a circuit, the circuit of the semiconductor die can be exposed to the surface of the sealing layer.

In addition, as the sealing layer forming step, a known method in the present field can be used without particular limitation as long as the sealing layer is formed.

In addition, in the sealing layer forming step, the circuit of the semiconductor die may be exposed from the sealing layer by not polishing and simply not sealing the surface on which the circuit of the semiconductor die is disposed.

A preferred aspect of the sealing layer obtained by the sealing layer forming step is the same as the preferred aspect of the sealing layer in the semiconductor package according to the embodiment of the present invention described above.

However, in the sealing layer forming step, the above-described conductive portion may not be formed, and the above-described conductive portion may be formed after the re-distribution layer A forming step as described later.

### <Passivation Layer Forming Step>

The manufacturing method of a semiconductor package according to the embodiment of the present invention may further include a passivation layer forming step of forming a passivation layer after the sealing layer forming step.

The passivation layer forming step is preferably performed after the sealing layer forming step and before the re-distribution layer A forming step.

The passivation layer is formed by coating the surface of the semiconductor die with an inert film. By forming the passivation layer, the influence of the outside air on the semiconductor die, the adhesion of dust, and the contamination by water or metal may be suppressed.

A material of the passivation layer is not particularly limited, and examples thereof include SiO₂ and SiN. In addition, a resin such as polyimide may be used.

A known method can be used as the coating method without particular limitation. For example, in a case of coating SiN, the passivation layer forming step can be performed by chemical vapor deposition (CVD) or the like.

### <Re-Distribution Layer A Forming Step>

The manufacturing method of a semiconductor package according to the embodiment of the present invention includes a re-distribution layer A forming step of forming a re-distribution layer A including an insulating pattern A and a conductive pattern A that is present between patterns of the insulating pattern A on the surface of the sealing layer on which the circuit is exposed.

By the re-distribution layer A forming step, the re-distribution layer A is formed on the surface of the sealing material on which the circuit is exposed. A preferred aspect of the re-distribution layer A is the same as the preferred aspect of the re-distribution layer A in the semiconductor package according to the embodiment of the present invention described above.

The re-distribution layer A forming step preferably includes applying a negative-tone photosensitive resin composition onto the sealing layer to form a film (film forming step).

That is, it is preferable that the insulating pattern A in the re-distribution layer A is formed of a negative-tone photosensitive resin composition.

In addition, the re-distribution layer A forming step more preferably includes the film forming step, an exposure step of selectively exposing the film formed by the film forming step, and a development step of developing the exposed film using a developer to form a pattern.

It is particularly preferable that the re-distribution layer A forming step includes the film forming step, the exposure step, the development step, and at least one of a heating step of heating a pattern obtained by the development step or a post-development exposure step of exposing the pattern obtained by the development step.

Hereinafter, details of each step will be described. In addition, details of the negative-tone photosensitive resin composition (hereinafter, also simply referred to as a “composition”) will be described later.

### <Film Forming Step>

The re-distribution layer A forming step preferably includes a film forming step of applying the composition onto the sealing layer to form a film.

As a method of applying the composition onto the sealing layer, coating is preferable.

Specific examples of the means for application include a dip coating method, an air knife coating method, a curtain coating method, a wire bar coating method, a gravure coating method, an extrusion coating method, a spray coating method, a spin coating method, a slit coating method, and an ink jet method. From the viewpoint of the uniformity of the film thickness, a spin coating method, a slit coating method, a spray coating method, or an ink jet method is more preferable, and from the viewpoint of the uniformity of the film thickness and the viewpoint of productivity, a spin coating method or a slit coating method is more preferable. A film having a desired thickness can be obtained by adjusting the concentration of solid contents of the composition and application conditions according to the means to be applied. In addition, the coating method can be appropriately selected depending on the shape of the base material. In a case where a circular base material such as a wafer is used, a spin coating method, a spray coating method, an ink jet method, or the like is preferable, and in a case where a rectangular base material is used, a slit coating method, a spray coating method, an ink jet method, or the like is preferable. For example, the spin coating method can be applied at a rotation speed of 500 to 3,500 rpm for about 10 seconds to 3 minutes.

In addition, it is also possible to apply a method of transferring a coating film formed in advance on a temporary support by the above-described coating method, onto a sealing layer.

Regarding the transfer method, the production methods described in paragraphs 0023 and 0036 to 0051 of JP2006-023696A and paragraphs 0096 to 0108 of JP2006-047592A can also be suitably used.

In addition, a step of removing an excess film at an end part of the sealing layer may be performed. Examples of such a step include edge bead rinsing (EBR) and back rinsing.

A pre-wetting step of applying various solvents to the substrate before applying the composition to the sealing layer to improve wettability of the sealing layer and then applying the composition may be adopted.

### <Drying Step>

The above film may be subjected to a step (a drying step) of drying the film (or the layer) formed for removing the solvent, after the film forming step (the layer forming step).

That is, the re-distribution layer A forming step may include a drying step of drying the film formed by the film forming step.

It is preferable that the drying step is carried out after the film forming step and before the exposure step.

The drying temperature of the film in the drying step is preferably 50 °C to 150 °C, more preferably 70 °C to 130 °C, and still more preferably 90 °C to 110 °C. In addition, the drying may be carried out by reducing the pressure. Examples of the drying time include 30 seconds to 20 minutes, and the drying time is preferably 1 minute to 10 minutes and more preferably 2 minutes to 7 minutes.

### <Exposure Step>

The film may be subjected to an exposure step of selectively exposing the film.

The re-distribution layer A forming step may include an exposure step of selectively exposing the film formed by the film forming step.

The selective exposure means that a part of the film is exposed. In addition, by selectively exposing the film, an exposed region (an exposed portion) and an unexposed region (a non-exposed portion) are formed in the film.

An exposure amount is not particularly limited as long as the film can be cured, but is, for example, preferably 50 to 10,000 mJ/cm² and more preferably 200 to 8,000 mJ/cm² in terms of exposure energy at a wavelength of 365 nm.

The exposure wavelength can be appropriately determined in a range of 190 to 1,000 nm and preferably in a range of 240 to 550 nm.

Examples of the exposure wavelength, which are mentioned in the relationship with the light source, include (1) a semiconductor laser (wavelength: 830 nm, 532 nm, 488 nm, 405 nm, 375 nm, 355 nm, or the like); (2) a metal halide lamp; (3) a high pressure mercury lamp, a g-line (wavelength: 436 nm), an h-line (wavelength: 405 nm), an i-line (wavelength: 365 nm), or broadband light (three wavelengths of the g, h, and i-line); (4) an excimer laser, a KrF excimer laser (wavelength: 248 nm), an ArF excimer laser (wavelength: 193 nm), or an F₂ excimer laser (wavelength: 157 nm); (5) an extreme ultraviolet ray: EUV (wavelength: 13.6 nm); (6) an electron beam; and (7) a second harmonic wave of 532 nm and a third harmonic wave of 355 nm of a YAG laser. Exposure with a high-pressure mercury lamp is particularly preferable, and exposure with i-rays is more preferable from the viewpoint of exposure sensitivity.

A method of the exposure is not particularly limited, and any method in which at least a part of the film is exposed may be used, but examples thereof include exposure using a photomask and exposure by a laser direct imaging method.

Here, in the re-distribution layer A forming step, it is preferable that the photosensitive film formed of the negative-tone photosensitive resin composition is exposed using an i-line stepper.

By appropriately adjusting a numerical aperture, the exposure illuminance, the exposure amount, and the like of the i-line stepper, the taper angle can be adjusted.

A numerical aperture of the i-line stepper is preferably 0.10 to 0.60.

The numerical aperture is preferably a high value in a case of seeking high resolution, and is preferably a low value in a case of seeking a wide focus margin.

A high numerical aperture is preferably 0.40 to 0.60, more preferably 0.45 to 0.57, and still more preferably 0.47 to 0.55.

A low numerical aperture is preferably 0.10 to 0.30, more preferably 0.13 to 0.27, and still more preferably 0.15 to 0.25.

An exposure illuminance of the i-line stepper is preferably 500 to 50,000 W/m², more preferably 1,000 to 30,000 W/m², and still more preferably 3,000 to 20,000 W/m².

An exposure amount using the i-line stepper is preferably 1 to 2,000 mJ/cm², more preferably 50 to 1,500 mJ/cm², and still more preferably 100 to 700 mJ/cm².

### <Post-Exposure Heating Step>

The film may be subjected to a step of carrying out heating after the exposure (a post-exposure heating step).

That is, the re-distribution layer A forming step may include a post-exposure baking step of heating the film exposed by the exposure step.

The post-exposure heating step can be carried out after the exposure step and before the development step.

The heating temperature in the post-exposure heating step is preferably 50 °C to 140 °C and more preferably 60 °C to 120 °C.

The heating time in the post-exposure heating step is preferably 30 seconds to 300 minutes and more preferably 1 minute to 10 minutes.

In the post-exposure heating step, the temperature rising rate from the temperature at the start of heating to the maximum heating temperature is preferably 1 to 12 °C/min, more preferably 2 to 10 °C/min, and still more preferably 3 to 10 °C/min.

In addition, the temperature rising rate may be appropriately changed during heating.

The heating means in the post-exposure heating step is not particularly limited, and a publicly known hot plate, oven, infrared heater, or the like can be used.

In addition, it is also preferable to carry out the heating in an atmosphere having a low oxygen concentration by allowing an inert gas such as nitrogen, helium, argon, or the like to flow.

### <Development Step>

The exposed film may be subjected to a development step of carrying out development using a developer to form a pattern.

That is, the re-distribution layer A forming step may include a development step of developing the film exposed by the exposure step using a developer to form a pattern.

By carrying out the development, one of the exposed portion and the non-exposed portion of the film is removed, and a pattern is formed.

Here, the development in which the non-exposed portion of the film is removed by the development step is referred to as negative-tone development, and the development in which the exposed portion of the film is removed by the development step is referred to as positive-tone development.

Here, in the via structure in the insulating pattern A, it is preferable that the via structure is formed by development using a solvent as a developer.

### [Developer]

Examples of the developer that is used in the development step include a developer containing an alkaline aqueous solution or an organic solvent.

In a case where the developer is an alkaline aqueous solution, examples of the basic compound that can be contained in the alkaline aqueous solution include inorganic alkalis, primary amines, secondary amines, tertiary amines, and a quaternary ammonium salt. The basic compound is preferably tetramethylammonium hydroxide (TMAH), potassium hydroxide, sodium carbonate, sodium hydroxide, sodium silicate, sodium metasilicate, ammonia, ethylamine, n-propylamine, diethylamine, di-n-butylamine, triethylamine, methyldiethylamine, dimethylethanolamine, triethanolamine, tetraethylammonium hydroxide, tetrapropylammonium hydroxide, tetrabutylammonium hydroxide, tetrapentylammonium hydroxide, tetrahexylammonium hydroxide, tetraoctylammonium hydroxide, ethyltrimethylammonium hydroxide, butyltrimethylammonium hydroxide, methyltriamylammonium hydroxide, dibutyldipentylammonium hydroxide, dimethylbis(2-hydroxyethyl)ammonium hydroxide, trimethylphenylammonium hydroxide, trimethylbenzylammonium hydroxide, triethylbenzylammonium hydroxide, pyrrole, or piperidine, and it is more preferably TMAH. The content of the basic compound in the developer is preferably 0.01% to 10% by mass, more preferably 0.1% to 5% by mass, and still more preferably 0.3% to 3% by mass in the total mass of the developer.

In a case where the developer contains an organic solvent, the compounds described in paragraph 0387 of WO2021/112189A can be used as the organic solvent. The content thereof is incorporated in the present specification. In addition, suitable examples of the alcohols include methanol, ethanol, propanol, isopropanol, butanol, pentanol, octanol, diethylene glycol, propylene glycol, methyl isobutyl carbinol, and triethylene glycol, and suitable examples of the amides include N-methylpyrrolidone, N-ethylpyrrolidone, and dimethylformamide.

In a case where the developer contains an organic solvent, one kind of organic solvent can be used, or two or more kinds thereof can be mixedly used. In the present invention, in particular, a developer containing at least one selected from the group consisting of cyclopentanone, γ-butyrolactone, dimethyl sulfoxide, N-methyl-2-pyrrolidone, and cyclohexanone is preferable, a developer containing at least one selected from the group consisting of cyclopentanone, γ-butyrolactone, and dimethyl sulfoxide is more preferable, and a developer containing cyclopentanone is particularly preferable.

In a case where the developer contains an organic solvent, the content of the organic solvent with respect to the total mass of the developer is preferably 50% by mass or more, more preferably 70% by mass or more, still more preferably 80% by mass or more, and particularly preferably 90% by mass or more. In addition, the above content may be 100% by mass.

In a case where the developer contains an organic solvent, the developer may further contain at least one of a basic compound or a base generator. In a case where at least one of the basic compound or the base generator in the developer permeates into the pattern, the performance such as the breaking elongation of the pattern may be improved.

The basic compound is preferably an organic base from the viewpoint of the reliability in a case of being remained in the cured film (the adhesiveness to the base material in a case where the cured substance is further heated).

The basic compound is preferably a basic compound having an amino group and preferably a primary amine, a secondary amine, a tertiary amine, an ammonium salt, a tertiary amide, or the like. However, in order to accelerate the imidization reaction, it is preferably a primary amine, a secondary amine, a tertiary amine, or an ammonium salt, more preferably a secondary amine, a tertiary amine, or an ammonium salt, still more preferably a secondary amine or a tertiary amine, and particularly preferably a tertiary amine.

From the viewpoint of mechanical characteristics (the breaking elongation) of the cured substance, it is preferable that the basic compound hardly remains in the cured film (the obtained cured substance), and from the viewpoint of accelerating cyclization, it is preferable that the residual amount of the basic compound hardly decreases due to vaporization or the like before heating.

Therefore, the boiling point of the basic compound is preferably 30 °C to 350 °C, more preferably 80 °C to 270 °C, and still more preferably 100 °C to 230 °C at normal pressure (101,325 Pa).

The boiling point of the basic compound is preferably higher than the temperature obtained by subtracting 20 °C from the boiling point of the organic solvent contained in the developer, and it is more preferably higher than the boiling point of the organic solvent contained in the developer.

For example, in a case where the boiling point of the organic solvent is 100 °C, the basic compound to be used preferably has a boiling point of 80 °C or higher and more preferably a boiling point of 100 °C or higher.

The developer may contain only one kind of basic compound having an amide group or may contain two or more kinds thereof.

Specific examples of the basic compound include ethanolamine, diethanolamine, triethanolamine, ethylamine, diethylamine, triethylamine, hexylamine, dodecylamine, cyclohexylamine, cyclohexylmethylamine, cyclohexyldimethylamine, aniline, N-methylaniline, N,N-dimethylaniline, diphenylamine, pyridine, butylamine, isobutylamine, dibutylamine, tributylamine, dicyclohexylamine, diazabicycloundecene (DBU), 1,4-diazabicyclo[2.2.2]octane (DABCO), N,N-diisopropylethylamine, tetramethylammonium hydroxide, tetrabutylammonium hydroxide, ethylenediamine, butanediamine, 1,5-diaminopentane, N-methylhexylamine, N-methyldicyclohexylamine, trioctylamine, N-ethylethylenediamine, N,N-diethylethylenediamine, N,N,N′,N′-tetrabutyl-1,6-hexanediamine, spermidine, diaminocyclohexane, bis(2-methoxyethyl)amine, piperidine, methylpiperidine, dimethylpiperidine, piperazine, tropane, N-phenylbenzylamine, 1,2-dianilinoethane, 2-aminoethanol, toluidine, aminophenol, hexylaniline, phenylene diamine, phenylethylamine, dibenzylamine, pyrrole, N-methylpyrrole, N,N,N,N-tetramethylethylenediamine, and N,N,N,N-tetramethyl-1,3-propanediamine.

A preferred aspect of the base generator is the same as the preferred aspect of the base generator contained in the above-described composition. In particular, the base generator is preferably a thermal-base generator.

In a case where the developer contains at least one of a basic compound or a base generator, the content of the basic compound or the base generator is preferably 10% by mass or less, and more preferably 5% by mass or less with respect to the total mass of the developer.

The lower limit of the content is not particularly limited; however, it is, for example, preferably 0.1% by mass or more.

In a case where the basic compound or the base generator is a solid in an environment where the developer is used, the content of the basic compound or the base generator is also preferably 70% to 100% by mass with respect to the total solid content of the developer.

The developer may contain only one kind of at least one of the basic compound or base generator or may contain two or more kinds thereof. In a case where at least one of the basic compound or the base generator is two or more kinds, the total thereof is preferably within the above-described range.

The developer may further contain another component.

Examples of the other component include a publicly known surfactant and a publicly known anti-foaming agent.

### [Method of Supplying Developer]

The method of supplying a developer is not particularly limited as long as a desired pattern can be formed, and it includes a method of immersing a base material on which a film has been formed in a developer, puddle development of supplying a developer to a film formed on a base material using a nozzle, and a method of continuously supplying a developer.

The kind of nozzle is not particularly limited, and examples thereof include a straight nozzle, a shower nozzle, and a spray nozzle.

From the viewpoint of the permeability of the developer, the removability of the non-image area, and the manufacturing efficiency, a method of supplying a developer with a straight nozzle or a method of continuously supplying a developer with a spray nozzle is preferable, and from the viewpoint of the permeability of the developer into the image area, a method of supplying a developer with a spray nozzle is more preferable.

In addition, after the continuous supply by a straight nozzle, the base material is spun to remove the developer from the base material, and then the developer is continuously supplied by the straight nozzle again after the spin drying, a step of spinning the base material to remove the developer from the base material may be adopted, and this step may be repeated a plurality of times.

Examples of the method of supplying a developer in the development step include a step of continuously supplying a developer to a base material, a step of keeping a developer in a substantially stationary state on a base material, a step of vibrating a developer on a base material by ultrasonic waves or the like, and a step obtained by combining these steps.

The development time is preferably 3 seconds to 10 minutes and more preferably 5 seconds to 5 minutes. The temperature of the developer during development is not particularly determined; however, it is preferably 10 °C to 45 °C and more preferably 18 °C to 30 °C.

In the development step, washing (rinsing) of the pattern with a rinsing liquid may be further carried out after the treatment with the developer. In addition, a method such as supplying a rinsing liquid before the developer which is in contact with the pattern is completely dried may be adopted.

### [Rinsing Liquid]

In a case where the developer is an alkaline aqueous solution, it is possible to use, for example, water as the rinsing liquid. In a case where the developer is a developer containing an organic solvent, it is possible to use as the rinsing liquid, for example, a solvent (for example, water, an organic solvent different from the organic solvent contained in the developer) different from the solvent contained in the developer.

Examples of the organic solvent in a case where the rinsing liquid contains an organic solvent include the same organic solvents as the organic solvents exemplified in the above-described case where the developer contains an organic solvent.

The organic solvent contained in the rinsing liquid is preferably an organic solvent different from the organic solvent contained in the developer, and it is more preferably an organic solvent having a solubility of the pattern, which is lower than that of the organic solvent contained in the developer.

In a case where the rinsing liquid contains an organic solvent, one kind of organic solvent can be used, or two or more kinds thereof can be mixedly used. The organic solvent is preferably cyclopentanone, γ-butyrolactone, dimethyl sulfoxide, N-methylpyrrolidone, cyclohexanone, PGMEA, or PGME, more preferably cyclopentanone, γ-butyrolactone, dimethyl sulfoxide, PGMEA, or PGME, and still more preferably cyclohexanone or PGMEA.

In a case where the rinsing liquid contains an organic solvent, the organic solvent is preferably 50% by mass or more, more preferably 70% by mass or more, and still more preferably 90% by mass or more with respect to the total mass of the rinsing liquid. In addition, the organic solvent may be 100% by mass with respect to the total mass of the rinsing liquid.

The rinsing liquid may contain at least one of a basic compound or a base generator.

Although not particularly limited, in a case where the developer contains an organic solvent, an aspect in which the rinsing liquid contains at least one of an organic solvent, a basic compound, or a base generator is also one of the preferred aspects of the present invention.

Examples of the basic compound and the base generator which are contained in the rinsing liquid include the compounds exemplified as the basic compound and the base generator which may be contained in a case where the developer contains an organic solvent, and the same applies to the preferred aspects thereof.

The basic compound and the base generator, which are contained in the rinsing liquid, may be selected in consideration of the solubility in the solvent in the rinsing liquid.

In a case where the rinsing liquid contains at least one of a basic compound or a base generator, the content of the basic compound or the base generator is preferably 10% by mass or less, and more preferably 5% by mass or less with respect to the total mass of the rinsing liquid. The lower limit of the content is not particularly limited; however, it is, for example, preferably 0.1% by mass or more.

In a case where the basic compound or the base generator is a solid in an environment where the rinsing liquid is used, the content of the basic compound or the base generator is also preferably 70% to 100% by mass with respect to the total solid content of the rinsing liquid.

In a case where the rinsing liquid contains at least one of a basic compound or a base generator, the rinsing liquid may contain only one kind of at least one of the basic compound or base generator or may contain two or more kinds thereof. In a case where at least one of the basic compound or the base generator is two or more kinds, the total thereof is preferably within the above-described range.

The rinsing liquid may further contain another component.

Examples of the other component include a publicly known surfactant and a publicly known anti-foaming agent.

### [Method of Supplying Rinsing Liquid]

The method of supplying a rinsing liquid is not particularly limited as long as a desired pattern can be formed and includes a method of immersing a base material in a rinsing liquid, a method of supplying a rinsing liquid to a base material by liquid filling, a method of supplying a rinsing liquid to a base material with a shower, and a method of continuously supplying a rinsing liquid to a base material by means such as a straight nozzle.

From the viewpoint of the permeability of the rinsing liquid, the removability of non-image area, and the manufacturing efficiency, there is a method of supplying a rinsing liquid with a shower nozzle, a straight nozzle, a spray nozzle, or the like, and a method of continuously supplying a rinsing liquid with a spray nozzle is preferable. From the viewpoint of the permeability of the rinsing liquid into the image area, a method of supplying a rinsing liquid with a spray nozzle is more preferable. The kind of nozzle is not particularly limited, and examples thereof include a straight nozzle, a shower nozzle, and a spray nozzle.

That is, the rinsing step is preferably a step of supplying, with a straight nozzle, or continuously supplying a rinsing liquid to the exposed film, and it is more preferably a step of supplying a rinsing liquid with a spray nozzle.

In the method of supplying a rinsing liquid in the rinsing step, a step of continuously supplying a rinsing liquid to a base material, a step of keeping a rinsing liquid in a substantially stationary state on a base material, a step of vibrating a rinsing liquid on the base material by ultrasonic waves or the like, and a step obtained by combining these steps can be adopted.

The rinsing time is preferably 10 seconds to 10 minutes and more preferably 20 seconds to 5 minutes. The temperature of the rinsing liquid during rinsing is not particularly determined; however, it is preferably 10 °C to 45 °C and more preferably 18 °C to 30 °C.

The development step may include a step of bringing the treatment liquid into contact with the pattern after the treatment using the developer or after the pattern is washed with the rinsing liquid. In addition, such a method of supplying a treatment liquid before the developer or rinsing liquid which is in contact with the pattern is completely dried may be adopted.

Examples of the treatment liquid include a treatment liquid containing at least one of water or an organic solvent and at least one of a basic compound or a base generator.

Preferred aspects of the organic solvent and at least one of the basic compound or the base generator are the same as the preferred aspects of the organic solvent and at least one of the basic compound or the base generator, which are used in the above-described rinsing liquid.

As a method of supplying the treatment liquid to the pattern, the same method as the above-described method of supplying the rinsing liquid can be used, and the same applies to the preferred aspect thereof.

The content of the basic compound or the base generator in the treatment liquid is preferably 10% by mass or less and more preferably 5% by mass or less with respect to the total mass of the treatment liquid. The lower limit of the content is not particularly limited; however, it is, for example, preferably 0.1% by mass or more.

In addition, in a case where the basic compound or the base generator is a solid in an environment where the treatment liquid is used, the content of the basic compound or the base generator is also preferably 70% to 100% by mass with respect to the total solid content of the treatment liquid.

In a case where the treatment liquid contains at least one of a basic compound or a base generator, the treatment liquid may contain only one kind of at least one of the basic compound or the base generator, or may contain two or more kinds thereof. In a case where at least one of the basic compound or the base generator is two or more kinds, the total thereof is preferably within the above-described range.

### <Heating Step>

The pattern obtained by the development step (a pattern after the rinsing in a case where the rinsing step is carried out) may be subjected to a heating step of heating the pattern obtained by the development.

That is, the re-distribution layer A forming step may include a heating step of heating the pattern obtained by the development step.

In the heating step, the resin such as the polyimide precursor is cyclized to be a resin such as polyimide.

In addition, the crosslinking of unreacted crosslinkable groups in the specific resin or a crosslinking agent other than the specific resin also proceeds.

The heating temperature (the maximum heating temperature) in the heating step is preferably 50 °C to 450 °C, more preferably 150 °C to 350 °C, still more preferably 150 °C to 250 °C, even still more preferably 160 °C to 250 °C, and particularly preferably 160 °C to 230 °C.

The heating step is preferably a step of accelerating the cyclization reaction of the polyimide precursor in the pattern under the action of the base or the like generated from the base generator by heating.

The heating in the heating step is preferably carried out at a temperature rising rate of 1 to 12 °C/min from the temperature at the start of heating to the maximum heating temperature. The temperature rising rate is more preferably 2 to 10 °C/min and still more preferably 3 to 10 °C/min. In a case where the above temperature rising rate is set to 1 °C/min or higher, the excessive volatilization of the acid or solvent can be prevented while securing productivity, and in a case where the above temperature rising rate is set to 12 °C/min or lower, the residual stress of the cured substance can be relaxed.

In addition, in a case of an oven that enables rapid heating, the heating is preferably carried out at a temperature rising rate of 1 to 8 °C/sec from the temperature at the start of heating to the maximum heating temperature, more preferably 2 to 7 °C/sec, and still more preferably 3 to 6 °C/sec.

The temperature at the start of heating is preferably 20 °C to 150 °C, more preferably 20 °C to 130 °C, and still more preferably 25 °C to 120 °C. The temperature at the start of heating refers to a temperature at which the step of heating to the maximum heating temperature is started. For example, in a case where the composition is applied on a base material and then dried, the temperature at the start of heating is the temperature of the film (the layer) after drying, and for example, it is preferable to raise the temperature from a temperature lower by 30 °C to 200 °C than the boiling point of the solvent contained in the composition.

The heating time (the heating time at the maximum heating temperature) is preferably 5 to 360 minutes, more preferably 10 to 300 minutes, and still more preferably 15 to 240 minutes.

In particular, in a case of forming a multilayered laminate, the heating temperature is preferably 30 °C or higher, more preferably 80 °C or higher, still more preferably 100 °C or higher, and particularly preferably 120 °C or higher, from the viewpoint of adhesiveness between layers.

The upper limit of the heating temperature is preferably 350 °C or lower, more preferably 250 °C or lower, and still more preferably 240 °C or lower.

The heating may be carried out stepwise. For example, a step in which the temperature is raised from 25 °C to 120 °C at 3 °C/min, held at 120 °C for 60 minutes, raised from 120 °C to 180 °C at 2 °C/min, and held at 180 °C for 120 minutes, may be carried out. In addition, it is also preferable to carry out the treatment while carrying out irradiation with ultraviolet rays as described in U.S. Pat. No. 9,159,547B. By such a pretreatment step, it is possible to improve the properties of the film. The pretreatment step may be carried out for a short time of about 10 seconds to 2 hours and more preferably 15 seconds to 30 minutes. The pretreatment step may be carried out as a step of two or more stages, for example, a first stage pretreatment step may be carried out in a range of 100 °C to 150 °C, and then a second stage pretreatment step may be carried out in a range of 150 °C to 200 °C.

Further, cooling may be carried out after heating, and the cooling rate, in this case, is preferably 1 to 5 °C/min.

From the viewpoint of preventing the decomposition of the specific resin, it is preferable that the heating step is carried out in an atmosphere of a low oxygen concentration, for example, by allowing an inert gas such as nitrogen, helium, argon, or the like to flow, or carrying out heating under reduced pressure. The oxygen concentration is preferably 50 ppm (volume ratio) or lower, and more preferably 20 ppm (volume ratio) or lower.

The heating means in the heating step is not particularly limited; however, examples thereof include a hot plate, an infrared furnace, an electric heating oven, a hot air oven, and an infrared oven.

### <Post-Development Exposure Step>

The pattern obtained by the development step (a pattern after the rinsing in a case where the rinsing step is carried out) may be subjected to a post-development exposure step of exposing the pattern after the development step, instead of the heating step or in addition to the heating step.

That is, the re-distribution layer A forming step may include an after-development exposure step of exposing the pattern obtained by the development step. The re-distribution layer A forming step may include the heating step and the after-development exposure step, or may include only one of the heating step or the after-development exposure step.

In the post-development exposure step, it is possible to accelerate, for example, a reaction in which the cyclization of a polyimide precursor or the like proceeds by photosensitization of a photobase generator, a reaction in which the elimination of an acid-decomposable group proceeds by photosensitization of a photoacid generator.

In the post-development exposure step, it is sufficient that at least a part of the pattern obtained in the development step is exposed; however, it is preferable that the whole of the above pattern is exposed.

The exposure amount in the post-development exposure step is preferably 50 to 20,000 mJ/cm² and more preferably 100 to 15,000 mJ/cm² in terms of conversion of exposure energy at the wavelength at which the photosensitive compound has a sensitivity.

The post-development exposure step can be carried out using, for example, the light source in the above-described exposure step, and it is preferable to use broadband light.

### <Metal Layer Forming Step>

The pattern (preferably a pattern that has been subjected to at least one of the heating step or the post-development exposure step) obtained by the development step may be subjected to a metal layer forming step of forming a metal layer on the pattern.

The metal layer formed by the metal layer forming step corresponds to the conductive pattern A in the insulating pattern A of the pattern obtained by the development step.

That is, it is preferable that the re-distribution layer A forming step includes a metal layer forming step of forming a metal layer on the pattern (preferably the pattern supplied to at least one of the heating step or the after-development exposure step) obtained by the development step.

For the metal layer, existing metal kinds can be used without particular limitations. Examples thereof include copper, aluminum, nickel, vanadium, titanium, chromium, cobalt, gold, tungsten, tin, silver, and an alloy including these metals, where copper or aluminum is more preferable, and copper is still more preferable.

The forming method for the metal layer is not particularly limited, and the existing method can be applied. For example, the methods described in JP2007-157879A, JP2001-521288A, JP2004-214501A, JP2004-101850A, U.S. Pat. No. 7,888,181B2, and U.S. Pat. No. 9,177,926B2 can be used. For example, photolithography, physical vapor deposition method (PVD), chemical vapor phase growth method (CVD), lift-off, electrolytic plating, electroless plating, etching, printing, and a method obtained by combining these may be conceivable. More specific examples of the forming method for the metal layer include a patterning method obtained by combining sputtering, photolithography, and etching, and a patterning method combining photolithography and electrolytic plating. Examples of the preferred aspect of the plating include electrolytic plating using a copper sulfate plating liquid or a copper cyanide plating liquid.

In addition, it is also preferable that the metal layer forming step includes forming a barrier layer on the formed metal layer after the metal layer is formed. As a method of forming the barrier layer, a known method in the related art can be used without particular limitation.

The thickness of the metal layer at the thickest portion is preferably 0.01 to 50 μm and more preferably 1 to 10 km.

### <Resist Layer Forming Step, Resist Layer Peeling Step>

Here, the re-distribution layer A forming step may include a resist layer forming step before the step of forming a metal layer.

Furthermore, the re-distribution layer A forming step may include a resist layer peeling step after the metal layer forming step.

These steps can be performed by a known method.

By performing these steps, a line-and-space pattern or the like can also be formed as the conductive pattern A.

### <Polishing Step>

The re-distribution layer A forming step may further include a polishing step of polishing the surface of the re-distribution layer A after the metal layer forming step.

Examples of the polishing method include chemical mechanical polishing (CMP) and physical polishing, but the present invention is not limited thereto, and a known method can be used without particular limitation.

### <Laminating Step>

The re-distribution layer A forming step according to the embodiment of the present invention includes a laminating step.

The laminating step is a series of steps including carrying out again, in the following order on the surface of the pattern (the resin layer) or the metal layer, at least one of (a) the film forming step (the layer forming step), (b) the exposure step, (c) the development step, or (d) the heating step and the post-development exposure step. However, the aspect thereof may be such that at least one of (a) the film forming step or (d) the heating step and the post-development exposure step is repeated. In addition, (e) the metal layer forming step may be included after at least one of the heating step or the post-development exposure step of (d). It is needless to say that the laminating step may further include appropriately the above-described drying step or the like.

In a case where another laminating step is further carried out after the laminating step, a surface activation treatment step may be further carried out after the exposure step, the heating step, or the metal layer forming step. Examples of the surface activation treatment include plasma treatment. Details of the surface activation treatment will be described later.

The laminating step is preferably carried out 2 to 20 times and more preferably 2 to 9 times.

For example, a configuration having resin layers of 2 or more layers and 20 or fewer layers, such as a resin layer/a metal layer/a resin layer/a metal layer/a resin layer/a metal layer, is preferable, and a configuration having resin layers of 2 or more layers and 9 or fewer layers is still more preferable.

In the above layers, the compositions, shapes, film thicknesses, and the like may be the same or may be different from each other.

In the re-distribution layer A forming step, it is particularly preferable to form the cured substance (resin layer) of the composition to cover the metal layer after the metal layer is provided. Specific examples thereof include an aspect in which (a) the film forming step, (b) the exposure step, (c) the development step, (d) at least one of the heating step or the post-development exposure step, (e) the metal layer forming step are repeated in this order, and an aspect in which (a) the film forming step, (d) at least one of the heating step or the post-development exposure step, and (e) the metal layer forming step are repeated in order. By alternately carrying out the laminating step of laminating the composition layer (the resin layer) and the metal layer forming step, the composition layer (the resin layer) according to the embodiment of the present invention and the metal layer can be alternately laminated.

### <Step of Surface Activation Treatment>

The re-distribution layer A forming step preferably includes an activation treatment step of performing the surface activation treatment on at least a part of the metal layer and the composition layer.

The surface activation treatment step is usually carried out after the metal layer forming step (preferably, after at least one of the heating step or the post-development exposure step). However, after the development step, the metal layer forming step may be carried out after the composition layer is subjected to the surface activation treatment step.

Only at least a part of the metal layer may be subjected to the surface activation treatment, only at least a part of the composition layer after the exposure may be subjected to the surface activation treatment, or both at least a part of the metal layer and at least a part of the composition layer after the exposure may be subjected to the surface activation treatment. It is preferable to carry out the surface activation treatment on at least a part of the metal layer, and it is preferable to carry out the surface activation treatment on a part or whole of the region of the metal layer having a surface on which the composition layer is formed. In a case where a surface of the metal layer is subjected to the surface activation treatment in this manner, it is possible to improve the adhesiveness to the composition layer (film) to be provided on the surface thereof.

It is preferable that the surface activation treatment is carried out on a part or whole of the composition layer (the resin layer) after the exposure. In a case where a surface of the composition layer is subjected to the surface activation treatment in this manner, it is possible to improve the adhesiveness to a metal layer or a resin layer to be provided on the surface that has been subjected to the surface activation treatment. In particular, in a case where the composition layer is cured, such as in a case where negative-tone development is carried out, it is less likely to be damaged by the surface treatment, and thus the adhesiveness is likely to be improved.

The surface activation treatment can be carried out, for example, according to the method described in paragraph 0415 of WO2021/112189A. The content thereof is incorporated in the present specification.

### <Connection Pad Forming Step>

The re-distribution layer A forming step may further include a connection pad forming step after the laminating step. A preferred aspect of the connection pad to be formed is as described above.

In the connection pad forming step, a known method in the present field can be used without particular limitation, and examples thereof include a method of forming a resist layer as necessary, forming a connection pad by plating or the like, and peeling off the resist layer.

### <Carrier Wafer Bonding Step, Carrier Wafer Peeling Step>

The manufacturing method of a semiconductor package according to the embodiment of the present invention can include a carrier wafer bonding step of bonding a carrier wafer to the semiconductor package during the manufacturing, and a carrier wafer peeling step of peeling off the bonded carrier wafer.

For example, in a case where the carrier wafer is bonded to the semiconductor die in the sealing layer forming step to form the sealing layer on the carrier wafer, and the re-distribution layer A is formed on the sealing layer by the re-distribution layer A forming step, the carrier wafer is peeled off from the sealing layer to bond a new carrier wafer to the surface of the re-distribution layer A as necessary in order to bond the other semiconductor die, and thus the surface on which the carrier wafer is present can be reversed.

The carrier wafer peeling step and the carrier wafer bonding step can be performed by a known method.

In addition, a known carrier wafer can be used without particular limitation.

### <Conductive Portion Forming Step>

The manufacturing method of a semiconductor die according to the embodiment of the present invention may further include a conductive portion forming step of forming the above-described conductive portion.

The conductive portion forming step may be performed, for example, between the sealing layer forming step and the re-distribution layer A forming step, or after the re-distribution layer A forming step.

The conductive portion forming step is performed, for example, by forming a hole in the sealing layer by a laser or the like and filling the hole with a conductor by plating or the like.

The above-described hole may be a through-hole or a non-through-hole.

In addition, in the formation of the above-described hole, residues of the sealing layer or the like generated during the processing may be removed by a known desmear treatment or the like.

As a method of the conductive portion forming step, a known method in the present field can be used without particular limitation.

### <Inspection Step>

After the re-distribution layer A forming step, an inspection step of inspecting the surface shape, the conductivity, the insulating properties, the presence or absence of voids, and the like of the formed re-distribution layer A may be further included.

As a method of the inspection step, a known method in the present field can be used without particular limitation.

### <Connecting Portion Forming Step>

The manufacturing method of a semiconductor package according to the embodiment of the present invention further includes a connecting portion forming step of forming a conductive connecting portion on a surface of the re-distribution layer A different from a surface of the re-distribution layer A in contact with the sealing layer.

A preferred aspect of the conductive connecting portion is the same as the preferred aspect of the conductive connecting portion of the semiconductor package according to the embodiment of the present invention.

As a method of forming the conductive connecting portion, a known method in the present field can be used without particular limitation.

### <Other Semiconductor Die Bonding Step>

The manufacturing method of a semiconductor package according to the embodiment of the present invention may further include a step of bonding the other semiconductor die to the surface of the re-distribution layer A different from the surface of the re-distribution layer A in contact with the sealing layer.

It is preferable that the other semiconductor die is connected to the re-distribution layer A through the above-described conductive portion formed in the sealing layer.

A preferred aspect of the other semiconductor die is the same as the preferred aspect of the other semiconductor die of the semiconductor package according to the embodiment of the present invention.

At the time of bonding the other semiconductor die, at least one of heating or pressurization may be performed. As a bonding method of the other semiconductor die, a known method in the present field can be used without particular limitation.

### <Substrate Bonding Step>

The manufacturing method of a semiconductor package according to the embodiment of the present invention includes a step of bonding the conductive connecting portion and the substrate.

It is preferable that the substrate is connected to the re-distribution layer A through the conductive connecting portion.

A preferred aspect of the substrate is the same as the preferred aspect of the substrate of the semiconductor die according to the embodiment of the present invention.

At the time of bonding the substrate, at least one of heating or pressurization may be performed. As a bonding method of the substrate, a known method in the present field can be used without particular limitation.

### <Other Steps>

The manufacturing method of a semiconductor package according to the embodiment of the present invention may further include other steps.

Examples of the other steps include a step of washing the member as necessary after each step, a step of forming another re-distribution layer on a side of the sealing layer opposite to the re-distribution layer A, and a step of forming another connecting portion on a side of the sealing layer opposite to the re-distribution layer A.

The step of forming another re-distribution layer is not particularly limited, and a known step of forming a re-distribution layer can be used, but for example, the step can be performed by the same method as the above-described re-distribution layer A forming step, except that the taper angle is not limited.

The step of forming another connecting portion is not particularly limited, and a known step of forming a connecting portion can be used, but for example, the step can be performed by the same method as the above-described connecting portion forming step.

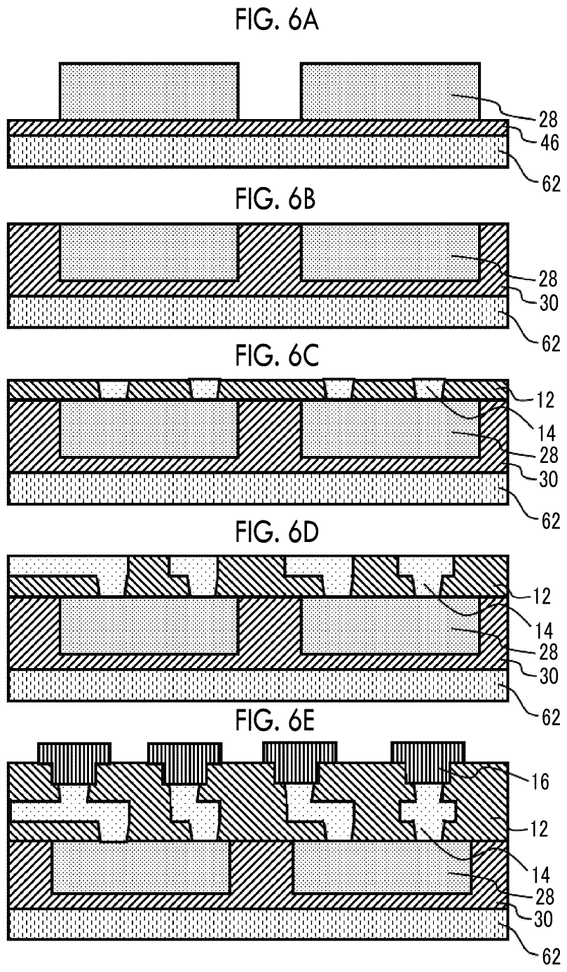

FIGS. 6A to 6E are schematic cross-sectional views showing an example of the manufacturing method of a semiconductor package according to the embodiment of the present invention.

In FIG. 6A, a layer 46 formed of a curable resin composition is formed on a carrier wafer 62, and two semiconductor dies 28 are disposed on the layer 46 formed of the curable resin composition. Details of the curable resin composition are as described above. Here, the layer 46 formed of the curable resin composition may be cured or may not be cured.

FIG. 6B shows a state in which the semiconductor die 28 is embedded in the sealing material 30 with respect to the laminate shown in FIG. 6A. The surface of the semiconductor die 28 is exposed. The sealing material 30 is formed, for example, by applying the above-described curable resin composition to embed the semiconductor die and curing the composition. Here, the surface of the semiconductor die 28 may be exposed by the polishing step, or the sealing material 30 may be filled to expose the surface.

FIG. 6C is a schematic cross-sectional view of a state in which one layer including the insulating pattern A12 and the conductive pattern A14 is formed on the laminate shown in FIG. 6B.

For example, first, the laminate shown in FIG. 6C is obtained by forming the insulating pattern A12 by the above-described film forming step, the exposure step, the development step, and the heating step, and then forming the conductive pattern A14 by the above-described step of forming a metal layer.

Here, the insulating pattern A12 includes a via structure, and the conductive pattern A14 is included as a via pattern.

In the present invention, by appropriately setting the composition of the negative-tone photosensitive resin composition for forming the insulating pattern A12, the exposure illuminance, the exposure amount, a numerical aperture of the stepper, the development conditions in the development step, the developer, and the like in the exposure step, the taper angle in the via structure of the insulating pattern A12 can be adjusted to 70° to 110°.

FIG. 6D is a schematic cross-sectional view of a state in which one layer including the insulating pattern A12 and the conductive pattern A14 is further formed on the laminate shown in FIG. 6C.

For example, for the laminate shown in FIG. 6C, the laminate shown in FIG. 6D is obtained by forming the insulating pattern A12 by the above-described film forming step, the exposure step, the development step, and the heating step, and then forming the conductive pattern A14 by the above-described step of forming a metal layer. Here, the conductive pattern A14 newly formed in FIG. 6D can be, for example, a pattern including a line and space pattern.

FIG. 6E is a schematic cross-sectional view of a state in which one layer including the insulating pattern A12 and the conductive pattern A14 is further formed on the laminate shown in FIG. 6D, and the conductive pad 16 is formed.

In this way, the insulating pattern A12 and the conductive pattern A14 are laminated, and the conductive pad 16 is formed as necessary to form the re-distribution layer A.

Thereafter, the connecting portion forming step and the substrate bonding step are performed on the laminate shown in FIG. 6E, and the carrier wafer 62 is peeled off to obtain the semiconductor package shown in FIG. 4.

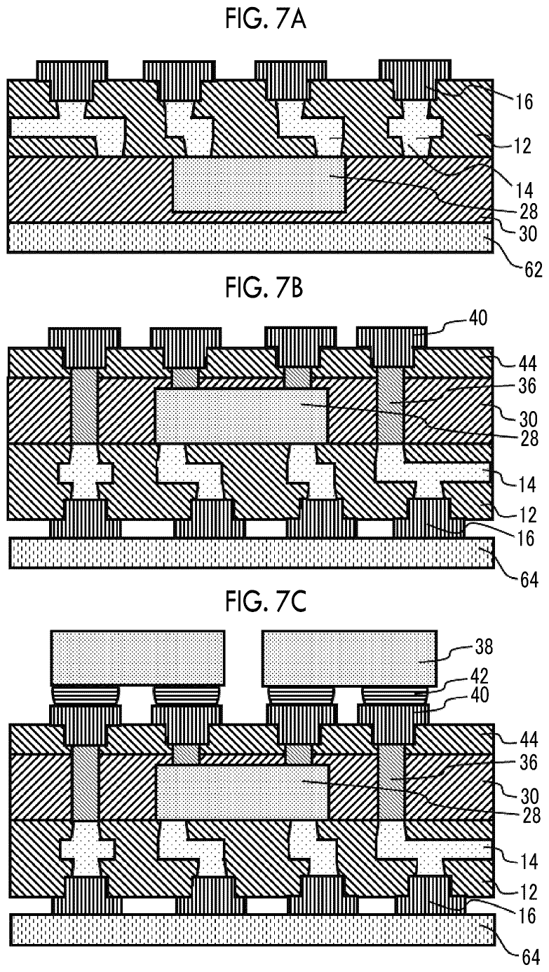

FIGS. 7A to 7C are schematic cross-sectional views showing an example of the manufacturing method of a semiconductor package according to the embodiment of the present invention.

In FIG. 7A, a sealing layer comprising the semiconductor die 28 embedded in the sealing material 30 is formed on the carrier wafer 62, and a re-distribution layer A including the insulating pattern A12, the conductive pattern A14, and the conductive pad 16 is formed on a surface of the sealing layer on which the semiconductor die 28 is exposed.

The laminate shown in FIG. 7A can be obtained by the same method as the manufacturing method of the laminate shown in FIGS. 6A to 6E described above.

FIG. 7B is a schematic cross-sectional view of a state in which the conductive through-via 36, the insulating layer 44, and other conductive pads 40 are formed in the laminate shown in FIG. 7A.

The laminate shown in FIG. 7B is obtained by bonding a second carrier wafer 64 to a surface of the re-distribution layer A on a side opposite to the sealing layer, peeling off the carrier wafer 62, forming the insulating layer 44 on a surface of the sealing layer on a side opposite to the surface on which the re-distribution layer A is formed, forming the conductive through-via 36 by the conductive portion forming step, and forming other conductive pads 40.

FIG. 7C is a schematic cross-sectional view of a state in which other conductive pads 40 are formed and other semiconductor dies 38 are bonded to the laminate shown in FIG. 7B.

Thereafter, the second carrier wafer 64 is peeled off from the laminate shown in FIG. 7C, the third carrier wafer is bonded to other semiconductor dies 38 as necessary, the connecting portion forming step and the substrate bonding step are performed on the re-distribution layer A, and the third carrier wafer is peeled off as necessary to obtain the semiconductor package shown in FIG. 5.

Hereinafter, details of the negative-tone photosensitive resin composition (composition) will be described.

As the composition, a known composition used for forming an insulating pattern can be used without particular limitation, but the composition preferably includes at least one resin selected from the group consisting of a heterocyclic ring-containing polymer and a precursor thereof (hereinafter, also referred to as a “specific resin”), and more preferably includes a polyimide or a polyimide precursor.

An imidization rate of the polyimide precursor is preferably less than 50%.

An imidization rate of the polyimide is preferably 50% or more.

Details of the imidization rate will be described later.

### <Specific Resin>

The heterocyclic ring-containing polymer is preferably a resin including an imide ring structure or an oxazole ring structure in a main chain structure.

In the present invention, the term “main chain” represents the relatively longest bonding chain in a resin molecule, and the term “side chain” refers to other bonding chains other than the main chain.

Examples of the heterocyclic ring-containing polymer include polyimide, polybenzoxazole, and polyamideimide.

The precursor of the heterocyclic ring-containing polymer refers to a resin in which a change in a chemical structure occurs due to an external stimulus to form a heterocyclic ring-containing polymer, and a resin in which a change in a chemical structure occurs due to heat to form a heterocyclic ring-containing polymer is preferable, and a resin in which a ring structure is formed by a ring closure reaction due to heat to form a heterocyclic ring-containing polymer is more preferable.

Examples of the precursor of the heterocyclic ring-containing polymer include a polyimide precursor, a polybenzoxazole precursor, and a polyamideimide precursor.

That is, the composition preferably contains, as the specific resin, at least one resin selected from the group consisting of a polyimide, a polyimide precursor, a polybenzoxazole, a polybenzoxazole precursor, a polyamideimide, and a polyamideimide precursor.

The composition preferably includes a polyimide or a polyimide precursor as the specific resin.

The specific resin preferably has a polymerizable group and more preferably contains a radically polymerizable group.

In a case where the specific resin has a radically polymerizable group, the resin composition preferably contains a radical polymerization initiator, and it more preferably contains a radical polymerization initiator and a radical crosslinking agent. Further, a sensitizing agent can be contained as necessary. From such a composition, for example, a negative type photosensitive film is formed.

Examples of the polymerizable group include a group having an ethylenically unsaturated bond, an epoxy group, an oxetanyl group, and a benzoxazolyl group, and a group having an ethylenically unsaturated bond is preferable.

Examples of the group having an ethylenically unsaturated bond include a vinyl group, an allyl group, a vinylphenyl group, a (meth)acryloyl group, a maleimide group, and a (meth)acrylamide group.

Among these, a (meth)acryloxy group, a (meth)acrylamide group, a vinylphenyl group, or a maleimide group is preferable, and from the viewpoint of reactivity, a (meth)acryloyl group is more preferable. In addition, from the viewpoint of reducing the dielectric loss tangent or the like, a vinylphenyl group or a maleimide group is preferable.

In addition, the specific resin may have a polarity converting group such as an acid-decomposable group.

In a case where the specific resin has an acid-decomposable group, it is preferable that the composition contains a photoacid generator. From such a composition, for example, a positive-tone photosensitive film or a negative-tone photosensitive film, which is a chemical amplification type photosensitive film, is formed.

In addition, it is preferable that the specific resin is a resin having at least one repeating unit selected from the group consisting of a repeating unit represented by Formula (4-1) and a repeating unit represented by Formula (4-2).

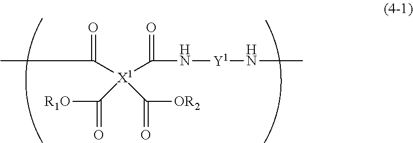

In Formula (4-1), X¹ represents a tetravalent organic group, Y¹ is a divalent organic group, and R¹ and R² each independently represent a hydrogen atom or a monovalent organic group.

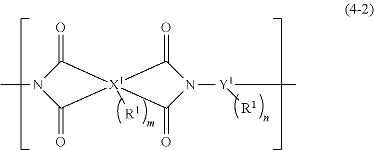

In Formula (4-2), X¹ represents an organic group having 4 or more carbon atoms, Y¹ represents an organic group having 4 or more carbon atoms, R¹'s each independently represent a structure including a polymerizable group, and n and m each independently represent an integer of 0 to 4.

### —X¹—

The number of carbon atoms in X¹ is 4 or more, and is preferably 4 to 50 and more preferably 4 to 40.

In Formula (4-1), X¹ preferably represents an organic group including a structure obtained by removing two or more hydrogen atoms from a structure represented by any of Formulae (V-1) to (V-4).

By the fact that X¹ is an organic group including a structure in which two or more hydrogen atoms are removed from a structure represented by any one of Formulae (V-1) to (V-4), the chemical resistance and the flatness of the cured substance are improved.

In addition, by the fact that X¹ is an organic group including a structure in which two or more hydrogen atoms are removed from a structure represented by any one of Formulae (V-1) to (V-4), the effect of suppressing the generation of development residues, the effect of reducing the dielectric constant of the cured substance, the effect of reducing the coefficient of thermal expansion, and the like are also obtained.

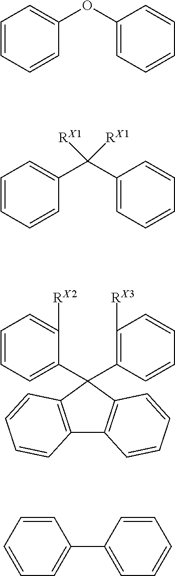

In Formula (V-2), R^{X1}'s each independently represent a hydrogen atom, an alkyl group, or a halogenated alkyl group.

In Formula (V-3), R^{X2} and R^{X3} each independently represent a hydrogen atom or a substituent, and R^{X2} and R^{X3} may be bonded to each other to form a ring structure.

In Formula (V-2), R^{X1}'s are each independently preferably an alkyl group or a halogenated alkyl group, more preferably an alkyl group having 1 to 4 carbon atoms or a halogenated alkyl group having 1 to 4 carbon atoms, and still more preferably a methyl group or a trifluoromethyl group. The halogenated alkyl group refers to a group in which at least one hydrogen atom of an alkyl group is substituted with a halogen atom. As the halogen atom, F or Cl is preferable, and F is more preferable.

In Formula (V-3), R^{X2} and R^{X3} are each independently preferably a hydrogen atom.

In a case where R^{X2} and R^{X3} are bonded to each other to form a ring structure, the structure formed by the bonding of R^{X2} and R^{X3} is preferably a single bond, —O—, or —C(R)₂—, more preferably —O— or —C(R)₂—, and still more preferably —O—. R represents a hydrogen atom or a monovalent organic group, preferably a hydrogen atom, an alkyl group, or an aryl group, and more preferably a hydrogen atom.

In a case where X¹ is a group including a structure obtained by removing two or more hydrogen atoms from a structure represented by Formula (V-1), X¹ is preferably a group represented by Formula (V-1-1). In the following Formula, * represents a bonding site to four carbonyl groups to which X¹ in Formula (4-1) is bonded, and n1 represents an integer of 0 to 5, and it is also preferable that n1 is an integer of 1 to 5. In addition, the hydrogen atom in the following structure may be further substituted with a known substituent such as a hydrocarbon group.

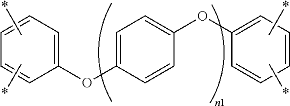

In a case where X¹ is a group including a structure obtained by removing two or more hydrogen atoms from a structure represented by Formula (V-2), X¹ is preferably a group represented by Formula (V-2-1) or Formula (V-2-2), and from the viewpoint of reducing the amine value in the resin, X¹ is preferably a group represented by Formula (V-2-2). In the present specification, a bond that intersects with a side of a ring structure means that any hydrogen atom in the ring structure is substituted. In the following Formula, L^{X1} represents a single bond or —O—, and * represents a bonding site to four carbonyl groups to which X¹ in Formula (4-1) is bonded. In addition, the definition and preferred aspect of R^{X1} are as described above. In addition, the hydrogen atom in these structures may be further substituted with a known substituent such as a hydrocarbon group.

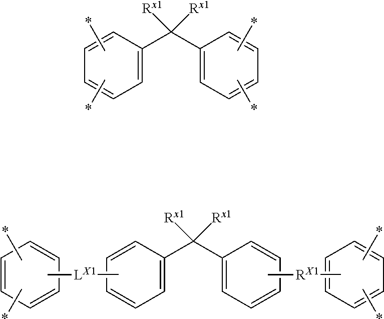

In a case where X¹ is a group including a structure obtained by removing two or more hydrogen atoms from a structure represented by Formula (V-3), X¹ is preferably a group represented by Formula (V-3-1) or Formula (V-3-2), and from the viewpoint of reducing the dielectric constant of the cured substance or the like, X¹ is preferably a group represented by Formula (V-3-2). In the following Formula, * represents a bonding site to four carbonyl groups to which X¹ in Formula (4-1) is bonded. In addition, the definitions and preferred aspects of R^{X2} and R^{X3} are as described above. In addition, the hydrogen atom in these structures may be further substituted with a known substituent such as a hydrocarbon group.

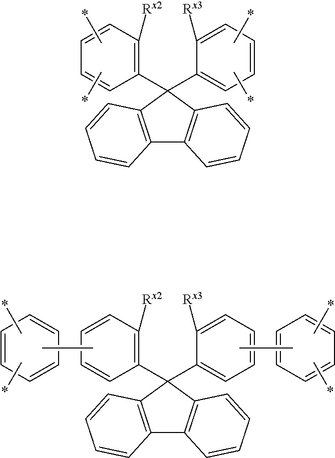

In a case where X¹ is a group including a structure obtained by removing two or more hydrogen atoms from a structure represented by Formula (V-4), X¹ is preferably a group represented by Formula (V-4-1). In the following Formula, * represents a bonding site to four carbonyl groups to which X¹ in Formula (4-1) is bonded, and n1 represents an integer of 0 to 5. In addition, the hydrogen atom in the following structure may be further substituted with a known substituent such as a hydrocarbon group. However, it is also preferable that none of the hydrogen atoms in the structure represented by (V-4-1) are substituted.

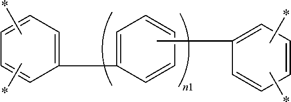

In addition, X¹ may be a tetracarboxylic acid residue remaining after the removal of the anhydride group from the tetracarboxylic acid dianhydride described in paragraphs 0055 to 0057 of JP2023-003421A.

In addition, it is preferable that X¹ does not contain an imide bond in the structure.

In addition, it is preferable that X¹ does not contain a urethane bond, a urea bond, and an amide bond in the structure.

In the present invention, the urethane bond is a bond represented by *—O—C(═O)—NR^{N}—*, where R^{N} represents a hydrogen atom or a monovalent organic group, and *'s each represent a bonding site to a carbon atom. R^{N} is preferably a hydrogen atom or a hydrocarbon group, more preferably a hydrogen atom or an alkyl group, and still more preferably a hydrogen atom.

In the present invention, the urea bond is a bond represented by *—NR^{N}—C(═O)—NR^{N}—*, where R^{N}'s each independently represent a hydrogen atom or a monovalent organic group, and *'s each represent a bonding site to a carbon atom. The preferred aspect of R^{N} is as described above.

Furthermore, it is preferable that X¹ does not contain an ester bond in the structure.

In the present invention, the ester bond is a bond represented by *—O—C(═O)—*.

Among these, it is preferable that X¹ does not contain an imide bond, a urethane bond, a urea bond, and an amide bond, and it is preferable that X¹ does not contain an imide bond, a urethane bond, a urea bond, an amide bond, and an ester bond.

In addition, X¹ may be a structure represented by Formula (X-2) or a structure in which a hydrogen atom of a group represented by X² or a hydrogen atom of a group represented by L³ in the structure represented by (X-2) is substituted with a group represented by R¹ in Formula (4-1).

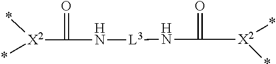

In Formula (X-2), X²'s each independently represent a trivalent linking group, L³ represents a divalent linking group, and * represents a bonding site to another structure.

In Formula (X-2), examples of X² include a linear or branched aliphatic group, a cyclic aliphatic group, an aromatic group, and a group obtained by linking two or more of these groups through a single bond or a linking group, where X² is preferably a linear aliphatic group having 2 to 20 carbon atoms, a branched aliphatic group having 3 to 20 carbon atoms, a cyclic aliphatic group having 3 to 20 carbon atoms, an aromatic group having 6 to 20 carbon atoms, or a group obtained by combining two or more of these groups through a single bond or a linking group, and X² is more preferably an aromatic group having 6 to 20 carbon atoms or a group obtained by combining two or more aromatic groups having 6 to 20 carbon atoms through a single bond or a linking group.

The linking group is preferably —O—, —S—, —C(═O)—, —S(═O)₂—, an alkylene group, a halogenated alkylene group, an arylene group, or a linking group obtained by bonding two or more these, and it is more preferably —O—, —S—, an alkylene group, a halogenated alkylene group, an arylene group, or a linking group obtained by bonding two or more these.

The alkylene group is preferably an alkylene group having 1 to 20 carbon atoms, more preferably an alkylene group having 1 to 10 carbon atoms, and still more preferably an alkylene group having 1 to 4 carbon atoms.

The halogenated alkylene group is preferably a halogenated alkylene group having 1 to 20 carbon atoms, more preferably a halogenated alkylene group having 1 to 10 carbon atoms, and still more preferably a halogenated alkylene group having 1 to 4 carbon atoms. In addition, examples of the halogen atom in the halogenated alkylene group include a fluorine atom, a chlorine atom, a bromine atom, and an iodine atom, where a fluorine atom is preferable. The halogenated alkylene group may have a hydrogen atom, or all hydrogen atoms in the halogenated alkylene group may be substituted with a halogen atom. However, it is preferable that all hydrogen atoms are substituted with a halogen atom. Examples of the preferred halogenated alkylene group include a (ditrifluoromethyl)methylene group.

The arylene group is preferably a phenylene group or a naphthylene group, more preferably a phenylene group, and still more preferably a 1,3-phenylene group or a 1,4-phenylene group.

In addition, X² is preferably derived from a tricarboxylic acid compound in which at least one carboxy group may be subjected to halogenation. Here, the halogenation is preferably chlorination.

In the present invention, a compound having three carboxy groups is referred to as a tricarboxylic acid compound.

Two carboxy groups of the three carboxy groups of the tricarboxylic acid compound may be subjected to acid anhydrization.

Examples of the tricarboxylic acid compound which may be halogenated include a branched aliphatic, cyclic aliphatic, or aromatic tricarboxylic acid compound.

One kind of these tricarboxylic acid compounds may be used alone, or two or more kinds thereof may be used.

In addition, it is preferable that X² does not contain an imide structure in the structure.

In addition, it is preferable that X² does not contain a urethane bond, a urea bond, and an amide bond in the structure.

Furthermore, it is preferable that X² does not contain an ester bond in the structure.

Among these, it is preferable that X² does not contain an imide structure, a urethane bond, a urea bond, and an amide bond, and it is preferable that X² does not contain an imide structure, a urethane bond, a urea bond, an amide bond, and an ester bond.

Specifically, the tricarboxylic acid compound is preferably a tricarboxylic acid compound containing a linear aliphatic group having 2 to 20 carbon atoms, a branched aliphatic group having 3 to 20 carbon atoms, a cyclic aliphatic group having 3 to 20 carbon atoms, an aromatic group having 6 to 20 carbon atoms, or a group obtained by combining two or more of these groups through a single bond or a linking group, and more preferably a tricarboxylic acid compound containing an aromatic group having 6 to 20 carbon atoms or a group obtained by combining two or more aromatic groups having 6 to 20 carbon atoms through a single bond or a linking group.

Specific examples of the tricarboxylic acid compound include 1,2,3-propanetricarboxylic acid, 1,3,5-pentanetricarboxylic acid, citric acid, trimellitic acid, 2,3,6-naphthalenetricarboxylic acid, and a compound in which phthalic acid (or phthalic anhydride) and benzoic acid are linked through a single bond, —O—, —CH₂—, —C(CH₃)₂—, —C(CF₃)₂—, —SO₂—, or a phenylene group.

These compounds may be a compound (for example, a trimellitic acid anhydride) in which two carboxy groups have been subjected to anhydrization or may be a compound (for example, trimellitic anhydride chloride) in which at least one carboxy group has been halogenated.

In Formula (X-2), examples of L³ include a linear or branched aliphatic group, a cyclic aliphatic group, an aromatic group, and a group obtained by linking two or more of these groups through a single bond or a linking group, where L³ is preferably a linear aliphatic group having 2 to 20 carbon atoms, a branched aliphatic group having 3 to 20 carbon atoms, a cyclic aliphatic group having 3 to 20 carbon atoms, an aromatic group having 6 to 20 carbon atoms, or a group obtained by combining two or more of these groups through a single bond or a linking group, and L³ is more preferably an aromatic group having 6 to 20 carbon atoms or a group obtained by combining two or more aromatic groups having 6 to 20 carbon atoms through a single bond or a linking group.

The linking group is preferably —O—, —S—, —C(═O)—, —S(═O)₂—, an alkylene group, a halogenated alkylene group, an arylene group, or a linking group obtained by bonding two or more these, and it is more preferably —O—, —S—, an alkylene group, a halogenated alkylene group, an arylene group, or a linking group obtained by bonding two or more these.

The alkylene group is preferably an alkylene group having 1 to 20 carbon atoms, more preferably an alkylene group having 1 to 10 carbon atoms, and still more preferably an alkylene group having 1 to 4 carbon atoms.

The halogenated alkylene group is preferably a halogenated alkylene group having 1 to 20 carbon atoms, more preferably a halogenated alkylene group having 1 to 10 carbon atoms, and still more preferably a halogenated alkylene group having 1 to 4 carbon atoms. In addition, examples of the halogen atom in the halogenated alkylene group include a fluorine atom, a chlorine atom, a bromine atom, and an iodine atom, where a fluorine atom is preferable. The halogenated alkylene group may have a hydrogen atom, or all hydrogen atoms in the halogenated alkylene group may be substituted with a halogen atom. However, it is preferable that all hydrogen atoms are substituted with a halogen atom. Examples of the preferred halogenated alkylene group include a (ditrifluoromethyl)methylene group.

The arylene group is preferably a phenylene group or a naphthylene group, more preferably a phenylene group, and still more preferably a 1,3-phenylene group or a 1,4-phenylene group.

In addition, X¹ may be a structure represented by Formula (X-3) or a structure in which a hydrogen atom of a group represented by X² or a hydrogen atom of a group represented by L³ in the structure represented by (X-3) is substituted with a group represented by R¹ in Formula (4-1)

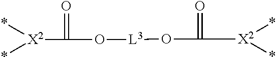

In Formula (X-3), X²'s each independently represent a trivalent linking group, L³ represents a divalent linking group, and * represents a bonding site to another structure.

In Formula (X-3), preferred aspects of X² and L³ are the same as the preferred aspects of X² and L³ in Formula (X-2).

### —Y¹—

The number of carbon atoms in Y¹ is 4 or more, and is preferably 4 to 50 and more preferably 4 to 40.

In Formula (4-1), Y¹ may be a group including a structure obtained by removing two or more hydrogen atoms from the structure represented by any of Formula (V-1) to Formula (V-4) described above.

By the fact that Y¹ is an organic group including a structure in which two or more hydrogen atoms are removed from a structure represented by any one of Formulae (V-1) to (V-4), the chemical resistance and the flatness of the cured substance are improved.

In a case where Y¹ is a group including a structure obtained by removing two or more hydrogen atoms from a structure represented by Formula (V-1), Y¹ is preferably a group represented by Formula (V-1-2). In the following Formula, * represents a bonding site to two nitrogen atoms to which Y¹ in Formula (4-1) is bonded, and n1 represents an integer of 1 to 5. In addition, the hydrogen atom in the following structure may be further substituted with a known substituent such as a hydrocarbon group.

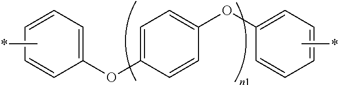

In a case where Y¹ is a group including a structure obtained by removing two or more hydrogen atoms from a structure represented by Formula (V-2), Y¹ is preferably a group represented by Formula (V-2-3) or Formula (V-2-4), and from the viewpoint of reducing the dielectric constant of the cured substance or the like, Y¹ is preferably a group represented by Formula (V-2-4). In the following Formula, L^{X1} represents a single bond or —O—, and * represents a bonding site to two nitrogen atoms to which Y¹ in Formula (4-1) is bonded. In addition, the preferred aspect of R^{X1} is as described above. In addition, the hydrogen atom in these structures may be further substituted with a known substituent such as a hydrocarbon group.

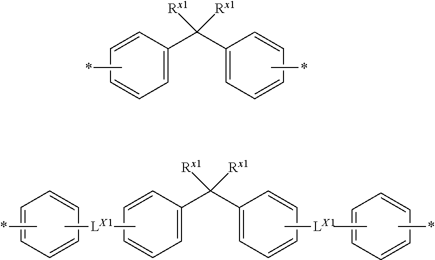

In a case where Y¹ is a group including a structure obtained by removing two or more hydrogen atoms from a structure represented by Formula (V-3), Y¹ is preferably a group represented by Formula (V-3-3) or Formula (V-3-4), and from the viewpoint of reducing the dielectric constant of the cured substance or the like, Y¹ is preferably a group represented by Formula (V-3-3). In the following Formula, * represents a bonding site to two nitrogen atoms to which Y¹ in Formula (4-1) is bonded. In addition, the hydrogen atom in these structures may be further substituted with a known substituent such as a hydrocarbon group.

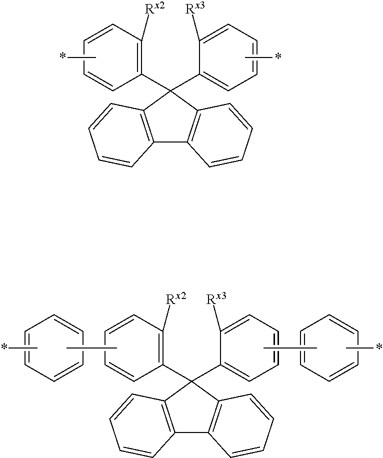

In a case where Y¹ is a group including a structure in which two or more hydrogen atoms are removed from a structure represented by Formula (V-4), Y¹ is preferably a group represented by Formula (V-4-2) or (V-4-3). In the following Formula, * represents a bonding site to two nitrogen atoms to which Y¹ in Formula (4-1) is bonded, and n1 represents an integer of 0 to 5. In addition, an aspect in which n1 is 0 is also one of the preferred aspects of the present invention. In addition, the hydrogen atom in the following structure may be further substituted with a known substituent such as a hydrocarbon group.

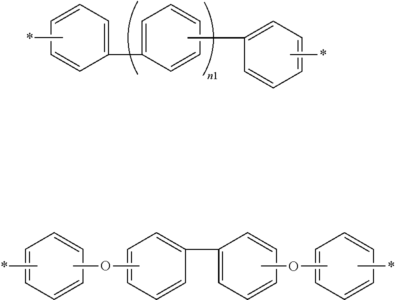

In addition, Y¹ may be a group described in paragraphs 0042 to 0053 of JP2023-003421A.

In addition, it is preferable that Y¹ does not contain an imide bond in the structure.

In addition, it is preferable that Y¹ does not contain a urethane bond, a urea bond, and an amide bond in the structure.

Furthermore, it is preferable that Y¹ does not contain an ester bond in the structure.

Among these, it is preferable that Y¹ does not contain an imide bond, a urethane bond, a urea bond, and an amide bond, and it is preferable that Y¹ does not contain an imide bond, a urethane bond, a urea bond, an amide bond, and an ester bond.

Among these, it is preferable that X¹ and Y¹ in Formula (4-1) are each an organic group including a structure obtained by removing two or more hydrogen atoms from a structure represented by any one of Formulae (V-1) to (V-4). Preferred aspects of these groups are as described above.

R¹ and R² in Formula (4-1) each independently represent a hydrogen atom or a monovalent organic group. The monovalent organic group preferably includes a linear or branched alkyl group, a cyclic alkyl group, an aromatic group, or a polyalkyleneoxy group. In addition, at least one of R¹ or R² preferably contains a polymerizable group, and more preferably both of them contain a polymerizable group. It is also preferable that at least one of R¹ or R² contains two or more polymerizable groups. The polymerizable group is preferably a group capable of undergoing a crosslinking reaction under the action of heat, a radical, or the like, where the group is a radically polymerizable group. Specific examples of the polymerizable group include a group having an ethylenically unsaturated bond, an alkoxymethyl group, a hydroxymethyl group, an acyloxymethyl group, an epoxy group, an oxetanyl group, a benzoxazolyl group, a blocked isocyanate group, and an amino group. The radically polymerizable group contained in the polyimide precursor is preferably a group having an ethylenically unsaturated bond.

Examples of the group having an ethylenically unsaturated bond include a vinyl group, an allyl group, an isoallyl group, a 2-methylallyl group, a group (for example, a vinylphenyl group) having an aromatic ring that is directly bonded to a vinyl group, a (meth)acrylamide group, a (meth)acryloyloxy group, and a group represented by Formula (III), where a group represented by Formula (III) is preferable.

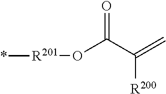

In Formula (III), R²⁰⁰ represents a hydrogen atom, a methyl group, an ethyl group, or a methylol group, where a hydrogen atom or a methyl group is preferable.

In Formula (III), * represents a bonding site to another structure.

In Formula (III), R²⁰¹ represents an alkylene group having 2 to 12 carbon atoms, —CH₂CH(OH)CH₂—, a cycloalkylene group, or a polyalkyleneoxy group.

Suitable examples of R²⁰¹ include an alkylene group such as an ethylene group, a propylene group, a trimethylene group, a tetramethylene group, a pentamethylene group, a hexamethylene group, an octamethylene group, or a dodecamethylene group, a 1,2-butanediyl group, a 1,3-butanediyl group, —CH₂CH(OH)CH₂—, and a polyalkyleneoxy group, where an alkylene group such as an ethylene group or a propylene group, —CH₂CH(OH)CH₂—, a cyclohexyl group, or a polyalkyleneoxy group is more preferable, and an alkylene group such as an ethylene group or a propylene group, or a polyalkyleneoxy group is still more preferable.

In the present invention, the polyalkyleneoxy group refers to a group to which two or more alkyleneoxy groups are directly bonded. The alkylene group in the plurality of alkyleneoxy groups contained in the polyalkyleneoxy group may be the same or different from each other.

In a case where the polyalkyleneoxy group contains a plurality of kinds of alkyleneoxy groups having different alkylene groups, the sequence of the alkyleneoxy groups in the polyalkyleneoxy group may be a randomly arranged sequence, may be a sequence arranged to have a block, or may be a sequence arranged to have an alternating pattern or the like.

The number of carbon atoms of the alkylene group (including the number of carbon atoms of the substituent in a case where the alkylene group has a substituent) is preferably 2 or more, more preferably 2 to 10, still more preferably 2 to 6, even more preferably 2 to 5, even still more preferably 2 to 4, even further still more preferably 2 or 3, and particularly preferably 2.

In addition, the alkylene group may have a substituent. Examples of the preferred substituent include an alkyl group, an aryl group, and a halogen atom.

In addition, the number of alkyleneoxy groups contained in the polyalkyleneoxy group (the number of repetitions of the polyalkyleneoxy group) is preferably 2 to 20, more preferably 2 to 10, and still more preferably 2 to 6.

The polyalkyleneoxy group is preferably a polyethyleneoxy group, a polypropyleneoxy group, a polytrimethyleneoxy group, a polytetramethyleneoxy group, or a group obtained by bonding a plurality of ethyleneoxy groups with a plurality of propyleneoxy groups, more preferably a polyethyleneoxy group or a polypropyleneoxy group, and still more preferably a polyethyleneoxy group, from the viewpoint of solubility in a solvent and solvent resistance. In the group obtained by bonding a plurality of ethyleneoxy groups with a plurality of propyleneoxy groups, the ethyleneoxy groups and the propyleneoxy groups may be randomly arranged, may be arranged by forming a block, or may be arranged in an alternately patterned manner or the like. The preferred aspect of the number of repetitions of the ethyleneoxy group and the like in these groups is as described above.

In Formula (4-1), in a case where R¹ is a hydrogen atom, or in a case where R² is a hydrogen atom, the polyimide precursor may form a conjugate salt together with a tertiary amine compound having an ethylenically unsaturated bond. Examples of the tertiary amine compound having such an ethylenically unsaturated bond include N,N-dimethylaminopropyl methacrylate.

In Formula (4-1), at least one of R¹ or R² may be a polarity converting group such as an acid-decomposable group. The acid-decomposable group is not particularly limited as long as it decomposes by the action of the acid to generate an alkali-soluble group such as a phenolic hydroxy group or a carboxy group; however, it is preferably an acetal group, a ketal group, a silyl group, or a silyl ether group, a tertiary alkyl ester group, or the like, and from the viewpoint of exposure sensitivity, it is more preferably an acetal group or a ketal group.

Specific examples of the acid-decomposable group include a tert-butoxycarbonyl group, an isopropoxycarbonyl group, a tetrahydropyranyl group, a tetrahydrofuranyl group, an ethoxyethyl group, a methoxyethyl group, an ethoxymethyl group, a trimethylsilyl group, a tert-butoxycarbonylmethyl group, and a trimethylsilyl ether group. From the viewpoint of exposure sensitivity, an ethoxyethyl group or a tetrahydrofuranyl group is preferable.

The polyimide precursor preferably has a fluorine atom in the structure thereof. The content of fluorine atoms in the polyimide precursor is preferably 10% by mass or more, and it is preferably 20% by mass or less.

In addition, for the purpose of improving adhesiveness to a substrate, the polyimide precursor may be copolymerized with an aliphatic group having a siloxane structure. Specifically, an aspect in which bis(3-aminopropyl)tetramethyldisiloxane, bis(p-aminophenyl)octamethylpentasiloxane, or the like is used as the diamine can be mentioned.

In Formula (4-2), preferred aspects of X¹ and Y¹ are the same as the preferred aspects of X¹ and Y¹ in Formula (4-1).

In Formula (4-2), a preferred aspect of the polymerizable group in R¹ is as described above for the preferred aspect of the polymerizable group in the resin.

In Formula (4-2), R¹ is preferably a group represented by Formula (R-1).

*-L¹-(-A¹)ₐ₁ (R-1)

In Formula (R-1), L¹ represents an (a1+1)-valent linking group, A¹ represents a polymerizable group, a1 represents an integer of 1 or more, and * represents a bonding site to X¹ or Y¹ in Formula (1-1).

In Formula (R-1), L¹ is preferably a group represented by Formula (L-2).

*—Z²-L^{X}-(-#)ₐ₁ (L-2)

In Formula (L-2), Z² represents —O—, —NRN—, —C(═O)O—, or —C(═O)NR^{N}—, R^{N} represents a hydrogen atom or a monovalent organic group, L^{X} represents a single bond or a divalent linking group in a case where a1 is 1, L^{X} represents an (a1+1)-valent linking group in a case where a1 is 2 or more, a1 represents an integer of 1 or more, * represents a bonding site to another structure in X¹ or Y¹ in Formula (1-1), and #represents a bonding site to A¹ in Formula (R-1).

In Formula (L-2), Z² is preferably —O— or —C(═O)O—. In addition, in a case where Z² is —RN—, R^{N} is preferably a hydrogen atom or a hydrocarbon group, more preferably a hydrogen atom, an alkyl group, or a phenyl group, and still more preferably a hydrogen atom.

In Formula (L-2), in a case where a1 is 1, L^{X} is preferably an alkylene group, more preferably an alkylene group having 1 to 10 carbon atoms, still more preferably an alkylene group having 1 to 4 carbon atoms, and particularly preferably a methylene group.

In Formula (L-2), in a case where a1 is 2 or more, L^{X} is preferably a group represented by a hydrocarbon group, a heterocyclic group, or a combination thereof, more preferably a saturated aliphatic hydrocarbon group having 2 to 20 carbon atoms, and still more preferably a saturated aliphatic hydrocarbon group having 3 to 15 carbon atoms.

In Formula (L-2), a1 has the same meaning as a1 in Formula (R-1).

In Formula (R-1), A¹ represents a polymerizable group. A preferred aspect of the polymerizable group is as described above for the preferred aspect of the polymerizable group in the resin.

Here, A¹ is preferably a (meth)acryloxy group, a maleimide group, or a vinylphenyl group, and from the viewpoint of reducing the dielectric loss tangent of the cured substance or the like, it is more preferably a maleimide group or a vinylphenyl group. In addition, from the viewpoint of reactivity and the like, a (meth)acryloxy group is more preferable.

Among these, it is preferable that A¹ in Formula (R-1) is a vinylphenyl group and L¹ is a group represented by Formula (L-2-1).

*—O-L^{X2}-(-#)ₐ₁ (L-2-1)

In Formula (L-2-1), L^{X2} represents a hydrocarbon group, and a1 represents an integer of 1 or more.

In Formula (L-2-1), L^{X2} is preferably an aliphatic saturated hydrocarbon group.

In a case where a1 is 1, L^{X2} is preferably an alkylene group, more preferably an alkylene group having 1 to 10 carbon atoms, still more preferably an alkylene group having 1 to 4 carbon atoms, and particularly preferably a methylene group.

In Formula (L-2-1), a1 has the same meaning as a1 in Formula (R-1).

In addition, it is preferable that A¹ in Formula (R-1) is a maleimide group, L¹ is a group represented by Formula (L-2), and L^{X} is an aromatic group or an aliphatic saturated hydrocarbon group having 4 or more carbon atoms.

The aromatic group may be any of an aromatic hydrocarbon group or an aromatic heterocyclic group, but is preferably an aromatic hydrocarbon group.

The aromatic hydrocarbon group is preferably an aromatic hydrocarbon group having 6 to 10 carbon atoms, and more preferably an aromatic hydrocarbon group having 6 carbon atoms.

Examples of the heteroatom in the aromatic heterocyclic group include an oxygen atom, a nitrogen atom, and a sulfur atom. The number of heteroatoms in the aromatic heterocyclic group is preferably 1 or 2. In addition, as the aromatic heterocyclic group, a 5-membered ring or a 6-membered ring including the above-described heteroatom is preferable. Furthermore, the aromatic heterocyclic group may be fused with another aromatic heterocyclic group or another aromatic hydrocarbon ring group.

The aliphatic saturated hydrocarbon group having 4 or more carbon atoms may have any of a linear structure, a branched structure, a cyclic structure, or a structure represented by a combination thereof.

The number of carbon atoms in the aliphatic saturated hydrocarbon group having 4 or more carbon atoms is preferably 4 to 20 and more preferably 5 to 10.

In Formula (R-1), a1 is preferably an integer of 1 to 4 and more preferably an integer of 1 or 2. In addition, an aspect in which a1 is 1 is also one of the preferred aspects of the present invention.

In addition, the number of ester bonds included in Formula (R-1) is preferably 1 or 0.

—n and m —

In Formula (4-2), m is preferably an integer of 0 to 2, and more preferably 0 or 1. In addition, an aspect in which m is 0 is also one of the preferred aspects of the present invention.

In Formula (4-2), n is preferably 1 or 2, and more preferably 2.

### [Polyimide Precursor]

The kind and the like of the polyimide precursor used in the present invention are not particularly limited, but it is preferable that the polyimide precursor contains a repeating unit represented by Formula (4-1).

The polyimide precursor may contain one kind of repeating unit represented by Formula (4-1) or may contain two or more kinds thereof. In addition, the polyimide precursor may contain structural isomers of the repeating unit represented by Formula (4-1). The polyimide precursor may also contain another kind of repeating unit in addition to the above repeating unit represented by Formula (4-1).

One embodiment of the polyimide precursor in the present invention includes an aspect in which the content of the repeating unit represented by Formula (4-1) is 50% by mole or more of all the repeating units. The above-described total content is more preferably 70% by mole or more, still more preferably 90% by mole or more, and particularly preferably more than 90% by mole. The upper limit of the total content is not particularly limited, and all the repeating units in the polyimide precursor excluding the terminal may be the repeating unit represented by Formula (4-1).

### —Cyclization Rate (Imidization Rate) —

From the viewpoint of film hardness, insulating properties, and the like of the organic film to be obtained, the cyclization rate (imidization rate) of the polyimide precursor is preferably less than 50%, more preferably 40% or less, still more preferably 30% or less, and even more preferably 20% or less.

The lower limit of the cyclization rate is not particularly limited, and may be 0%.

The cyclization rate is measured by, for example, the following method.

The infrared absorption spectrum of the polyimide precursor is measured, and a peak intensity P1 in the vicinity of 1,377 cm⁻¹, which is the absorption peak derived from the imide structure, is obtained. Next, the polyimide precursor is subjected to a heat treatment at 350 °C for 1 hour, and then the infrared absorption spectrum is measured again to obtain a peak intensity P2 in the vicinity of 1,377 cm⁻¹. Using the obtained peak intensities P1 and P2, the cyclization rate of the polyimide precursor can be determined based on the following expression.

Cyclization rate (%)=(peak intensity P1/peak intensity P2)×100

The weight-average molecular weight (Mw) of the polyimide precursor is preferably 5,000 to 100,000, more preferably 10,000 to 50,000, and still more preferably 15,000 to 40,000. The number-average molecular weight (Mn) of the polyimide precursor is preferably 2,000 to 40,000, more preferably 3,000 to 30,000, and still more preferably 4,000 to 20,000.

The dispersivity of the molecular weight of the polyimide precursor is preferably 1.5 or more, more preferably 1.8 or more, and still more preferably 2.0 or more. The upper limit value of the dispersivity of the molecular weight of the polyimide precursor is not particularly limited; however, it is, for example, preferably 7.0 or less, more preferably 6.5 or less, and still more preferably 6.0 or less.

In the present specification, the dispersity of the molecular weight is a value obtained by calculating “weight-average molecular weight/number-average molecular weight”.

In a case where the composition contains a plurality of kinds of polyimide precursors as the specific resin, it is preferable that the weight-average molecular weight, the number-average molecular weight, and the dispersity of at least one kind of polyimide precursor are in the above ranges. Further, it is also preferable that the weight-average molecular weight, the number-average molecular weight, and the dispersity, calculated by using the plurality of kinds of polyimide precursors as one resin, are within the above ranges.

### [Polyimide]

The polyimide that is used in the present invention may be an alkali-soluble polyimide or may be a polyimide soluble in a developer containing an organic solvent as a main component.

In the present specification, the alkali-soluble polyimide refers to a polyimide, 0.1 g or more of which is dissolved in 100 g of an aqueous solution of 2.38% by mass of tetramethylammonium at 23 °C, and from the viewpoint of pattern formation properties, it is preferably a polyimide, 0.5 g or more of which is dissolved therein and still more preferably a polyimide, 1.0 g or more of which is dissolved therein. The upper limit of the dissolution amount is not particularly limited; however, it is preferably 100 g or less.

The polyimide is preferably a polyimide having a plurality of imide structures in the main chain from the viewpoint of the film hardness and the insulating properties of the organic film to be obtained.

### —Fluorine Atom —

From the viewpoint of the film hardness of the organic film to be obtained, the polyimide preferably has a fluorine atom.

The fluorine atom is preferably included in, for example, R¹³² in the repeating unit represented by Formula (4-2) or R¹³¹ in the repeating unit represented by Formula (4-2), and more preferably included as a fluorinated alkyl group in R¹³² in the repeating unit represented by Formula (4) or R¹³¹ in the repeating unit represented by Formula (4-2).

The amount of fluorine atoms with respect to the total mass of the polyimide is preferably 5% by mass or more, and it is preferably 20% by mass or less.

### —Silicon Atom —

From the viewpoint of the film hardness of the organic film to be obtained, it is also preferable that the polyimide has a silicon atom.

The silicon atom is preferably contained in, for example, Y¹ in a repeating unit represented by Formula (4-2) described later, and more preferably contained in Y¹ in a repeating unit represented by Formula (4-1) described later as an organically modified (poly)siloxane structure.

The silicon atom or the organically modified (poly)siloxane structure may be contained in the side chain of the polyimide; however, it is preferably contained in the main chain of the polyimide.

The amount of silicon atoms with respect to the total mass of the polyimide is preferably 1% by mass or more, and it is preferably 20% by mass or less.

### —Ethylenically Unsaturated Bond —

From the viewpoint of the film hardness of the organic film to be obtained, the polyimide preferably has an ethylenically unsaturated bond.

The polyimide may have an ethylenically unsaturated bond at the terminal of the main chain or the side chain; however, it preferably has an ethylenically unsaturated bond at the side chain.

The ethylenically unsaturated bond preferably has radical polymerizability.

The ethylenically unsaturated bond is preferably included in X¹ or Y¹ in the repeating unit represented by Formula (4-2), and more preferably included in X¹ or RY¹ as a group having an ethylenically unsaturated bond.

The amount of the ethylenically unsaturated bond with respect to the total mass of the polyimide is preferably 0.0001 to 0.1 mol/g and more preferably 0.0005 to 0.05 mol/g.

—Polymerizable Group Other than Group Having Ethylenically Unsaturated Bond —

The polyimide may have a polymerizable group other than the group having an ethylenically unsaturated bond.

Examples of the polymerizable group other than the group having an ethylenically unsaturated bond include a cyclic ether group such as an epoxy group or an oxetanyl group, an alkoxymethyl group such as a methoxymethyl group, and a methylol group.

The polymerizable group other than the group having an ethylenically unsaturated bond is preferably contained in, for example, R¹³¹ in a repeating unit represented by Formula (4) described later.

The amount of the polymerizable group other than the group having an ethylenically unsaturated bond with respect to the total mass of the polyimide is preferably 0.0001 to 0.1 mol/g and more preferably 0.001 to 0.05 mol/g.

### —Polarity Converting Group —

The polyimide may have a polarity converting group such as an acid-decomposable group. The acid-decomposable group in the polyimide is the same as the acid-decomposable group described in R¹ and R² in Formula (4-1) described above, and the same applies to the preferred aspect thereof.

The polarity converting group is contained, for example, in R¹ or R² in the repeating unit represented by Formula (4-2) described later, or a terminal of the polyimide.

### —Acid Value —

In a case where the polyimide is subjected to alkaline development, the acid value of the polyimide is preferably 30 mgKOH/g or more, more preferably 50 mgKOH/g or more, and still more preferably 70 mgKOH/g or more, from the viewpoint of improving developability.

The acid value thereof is preferably 500 mgKOH/g or less, more preferably 400 mgKOH/g or less, and still more preferably 200 mgKOH/g or less.

In a case where the polyimide is subjected to the development (for example, the “solvent development”) using a developer containing an organic solvent as a main component, the acid value of the polyimide is preferably 1 to 35 mgKOH/g, more preferably 2 to 30 mgKOH/g, and still more preferably 5 to 20 mgKOH/g.

The acid value is measured by a known method, for example, by the method described in JIS K0070: 1992.

The acid group contained in the polyimide is preferably an acid group having a pKa of 0 to 10 and more preferably an acid group having a pKa of 3 to 8 from the viewpoint of achieving both storage stability and developability.

The “pKa” is represented by the negative common logarithm pKa of the equilibrium constant Ka of a dissociation reaction, in a case of assuming that hydrogen ions are released from the acid in the dissociation reaction. In the present specification, unless otherwise specified, pKa is defined as a calculated value according to ACD/ChemSketch (registered trademark). pKa may refer to the values published in “Handbook of Chemistry, Pure Chemistry, 5th Edition” edited by the Chemical Society of Japan.

In a case where the acid group is a polyvalent acid such as phosphoric acid, the pKa is the first dissociation constant.

As such an acid group, the polyimide preferably contains at least one selected from the group consisting of a carboxy group and a phenolic hydroxy group and more preferably contains a phenolic hydroxy group.

### —Phenolic Hydroxy Group —

From the viewpoint of allowing the speed of development with an alkaline developer to be proper, the polyimide preferably has a phenolic hydroxy group.

The polyimide may have a phenolic hydroxy group at the terminal of the main chain or the side chain.

The phenolic hydroxy group is preferably included in, for example, R¹³² or R¹³¹ in the repeating unit represented by Formula (4-2).

The amount of the phenolic hydroxy group with respect to the total mass of the polyimide is preferably 0.1 to 30 mol/g and more preferably 1 to 20 mol/g.

The polyimide that is used in the present invention is not particularly limited as long as it is a polymer compound having an imide structure; however, it is preferable that the polyimide contains a repeating unit represented by Formula (4-2).

It is also preferable that the polyimide has a fluorine atom in the structure. The content of fluorine atoms in the polyimide is preferably 10% by mass or more, and it is more preferably 20% by mass or less.

For the intended purpose of improving adhesiveness to a substrate, an aliphatic group having a siloxane structure may be copolymerized with the polyimide. Specific examples of the diamine component include bis(3-aminopropyl)tetramethyldisiloxane, and bis(p-aminophenyl)octamethyl pentasiloxane.

In order to improve the storage stability of the composition, the terminal of the main chain of the polyimide is preferably blocked with a terminal blocking agent such as a monoamine, an acid anhydride, a monocarboxylic acid, a monoacid chloride compound, or a monoactive ester compound. Among these, it is more preferable to use a monoamine. Examples of the preferred monoamine compound include aniline, 2-ethynyl aniline, 3-ethynyl aniline, 4-ethynyl aniline, 5-amino-8-hydroxyquinoline, 1-hydroxy-7-aminonaphthalene, 1-hydroxy-6-aminonaphthalene, 1-hydroxy-5-aminonaphthalene, 1-hydroxy-4-aminonaphthalene, 2-hydroxy-7-aminonaphthalene, 2-hydroxy-6-aminonaphthalene, 2-hydroxy-5-aminonaphthalene, 1-carboxy-7-aminonaphthalene, 1-carboxy-6-aminonaphthalene, 1-carboxy-5-aminonaphthalene, 2-carboxy-7-aminonaphthalene, 2-carboxy-6-aminonaphthalene, 2-carboxy-5-aminonaphthalene, 2-aminobenzoic acid, 3-aminobenzoic acid, 4-aminobenzoic acid, 4-aminosalicylic acid, 5-aminosalicylic acid, 6-aminosalicylic acid, 2-aminobenzenesulfonic acid, 3-aminobenzenesulfonic acid, 4-aminobenzenesulfonic acid, 3-amino-4,6-dihydroxypyrimidine, 2-aminophenol, 3-aminophenol, 4-aminophenol, 2-aminothiophenol, 3-aminothiophenol, and 4-aminothiophenol. Two or more of these may be used, and a plurality of different terminal groups may be introduced by reacting a plurality of terminal blocking agents.

### —Imidization Rate (Ring Closure Rate) —

The imidization rate (also referred to as the “ring closure rate”) of the polyimide is preferably 50% or more, more preferably 70% or more, and still more preferably 90% or more, from the viewpoint of the film hardness, the insulating properties, or the like of the organic film to be obtained.

The upper limit of the imidization rate is not particularly limited, and it may be any imidization rate of 100% or less.

The imidization rate is measured according to the method described above.

The polyimide may include the repeating unit represented by Formula (4-2) in which the combinations of R¹ and R² in all the repeating units are the same, or may include the repeating unit represented by Formula (4-2) including two or more different combinations of R¹ and R². The polyimide may contain another kind of repeating unit in addition to the above repeating unit represented by Formula (4-2). Examples of the other kind of repeating unit include the repeating unit represented by Formula (4-1) described above.

The polyimide can be synthesized by utilizing, for example, a method in which a tetracarboxylic acid dianhydride is reacted with a diamine (a part thereof is substituted with a terminal blocking agent which is a monoamine) at a low temperature, a method in which a tetracarboxylic acid dianhydride (a part thereof is substituted with a terminal blocking agent which is an acid anhydride, a monoacid chloride compound, or a monoactive ester compound) is reacted with a diamine at a low temperature, a method in which a diester is obtained from a tetracarboxylic acid dianhydride and alcohol and then reacted with a diamine (a part thereof is substituted with a terminal blocking agent which is a monoamine) in the presence of a condensing agent, a method in which a polyimide precursor is obtained, for example, by using a method in which a diester is obtained from a tetracarboxylic acid dianhydride and an alcohol, the remaining dicarboxylic acid is subjected to acid chloride modification and reacted with a diamine (a part thereof is substituted with a terminal blocking agent which is a monoamine), and the polyimide precursor is subjected to full imidization using a known imidization reaction method, or, a method in which the imidization reaction is stopped in the middle of the reaction and the imide structure is partially introduced, or furthermore a method in which a fully imidized polymer is blended with the polyimide precursor, whereby the imide structure is partially introduced. In addition, another known method for synthesizing polyimide can also be applied.

The weight-average molecular weight (Mw) of the polyimide is preferably 5,000 to 100,000, more preferably 10,000 to 50,000, and still more preferably 15,000 to 40,000. In a case where the weight-average molecular weight is set to 5,000 or more, it is possible to improve the breakage resistance of the film after curing. In order to obtain an organic film having excellent mechanical properties (for example, breaking elongation), the weight-average molecular weight is particularly preferably 15,000 or more.

The number-average molecular weight (Mn) of the polyimide is preferably 2,000 to 40,000, more preferably 3,000 to 30,000, and still more preferably 4,000 to 20,000.

The dispersivity of the molecular weight of the polyimide is preferably 1.5 or more, more preferably 1.8 or more, and still more preferably 2.0 or more. The upper limit value of the dispersivity of the molecular weight of the polyimide is not particularly limited; however, it is, for example, preferably 7.0 or less, more preferably 6.5 or less, and still more preferably 6.0 or less.

In a case where the composition contains a plurality of kinds of polyimides as the specific resin, it is preferable that the weight-average molecular weight, the number-average molecular weight, and the dispersity of at least one kind of polyimide are in the above ranges. It is also preferable that the weight-average molecular weight, the number-average molecular weight, and the dispersity, calculated by using the plurality of kinds of polyimides as one resin, are within the above ranges.

### [Polybenzoxazole Precursor]

Examples of the polybenzoxazole precursor include the compounds described in paragraphs 0073 to 0095 of WO2022/145355A. The above description is incorporated in the present specification.

### [Polybenzoxazole]

Examples of the polybenzoxazole include the compounds described in paragraphs 0101 to 0108 of WO2022/145355A. The above description is incorporated in the present specification.

### [Polyamideimide Precursor]

Examples of the polyamideimide precursor include the compounds described in paragraphs 0104 to 0119 of WO2022/145355A. The above description is incorporated in the present specification.

### [Polyamideimide]

Examples of the polyamideimide include compounds described in paragraphs 0125 to 0138 of WO2022/145355A. The above description is incorporated in the present specification.

### [Production Method for Polyimide Precursor and Like]

The polyimide precursor and the like are produced, for example, by the method described in paragraphs 0134 to 0136 of WO2022/145355A. The above description is incorporated in the present specification.

### [Content]

The content of the specific resin in the composition is preferably 20% by mass or more, more preferably 30% by mass or more, still more preferably 40% by mass or more, and even still more preferably 50% by mass or more, with respect to the total solid content of the composition. In addition, the content of the resin in the composition is preferably 99.5% by mass or less, more preferably 99% by mass or less, still more preferably 98% by mass or less, still more preferably 97% by mass or less, and even still more preferably 95% by mass or less, with respect to the total solid content of the composition.

The composition may include only one kind of the specific resin or may include two or more kinds thereof. In a case where two or more kinds thereof are contained, the total amount thereof is preferably within the above range.

The composition preferably includes at least two kinds of resins.

Specifically, the composition may contain in total two or more kinds of the specific resins and other resins described later or may contain two or more kinds of the specific resins; however, it is preferable to include two or more kinds of the specific resins.

In a case where the composition includes two or more kinds of the specific resins, for example, it is preferable to include two or more kinds of polyimide precursors having different structures derived from a dianhydride (X¹ in Formula (4-1) described above).

### <Another Resin>

The composition may include the above-described specific resin and another resin different from the specific resin (hereinafter, also simply referred to as “another resin”).

Examples of the other resin include a phenol resin, polyamide, an epoxy resin, polysiloxane, a resin containing a siloxane structure, a (meth)acrylic resin, a (meth)acrylamide resin, a urethane resin, a butyral resin, a styryl resin, a polyether resin, and a polyester resin.

For example, in a case where a (meth)acrylic resin is further added, it is possible to obtain a composition having excellent coatability, and it is possible to obtain a pattern (a cured substance) having excellent solvent resistance.

For example, in a case where a (meth)acrylic resin having a high polymerizable group value and having a weight-average molecular weight of 20,000 or less (for example, a molar content amount of a polymerizable group in 1 g of a resin is 1×10⁻³ mol/g or more) is added to the composition instead of a polymerizable compound described later or in addition to a polymerizable compound described later, it is possible to improve the coatability of the composition, the solvent resistance of the pattern (the cured substance).

In a case where the composition contains the other resin, the content of the other resin is preferably 0.01% by mass or more, more preferably 0.05% by mass or more, still more preferably 1% by mass or more, even still more preferably 2% by mass or more, even still more preferably 5% by mass or more, and even further still more preferably 10% by mass or more, with respect to the total solid content of the composition.

In a case where the composition contains the other resin, the content of the other resin is preferably 80% by mass or less, more preferably 75% by mass or less, still more preferably 70% by mass or less, even still more preferably 60% by mass or less, and even further still more preferably 50% by mass or less, with respect to the total solid content of the composition.

As a preferred aspect of the composition, an aspect in which the content of the other resin is a low content can also be adopted. In the above aspect, the content of the other resin is preferably 20% by mass or less, more preferably 15% by mass or less, still more preferably 10% by mass or less, even still more preferably 5% by mass or less, and even further still more preferably 1% by mass or less, with respect to the total solid content of the composition. The lower limit of the content is not particularly limited, and it may be any content of 0% by mass or more.

The composition may include only one kind of the other resin or may include two or more kinds thereof. In a case where two or more kinds thereof are contained, the total amount thereof is preferably within the above range.

<Polymerizable Compound>

It is preferable that the composition further contains a polymerizable compound.

Examples of the polymerizable compound include a radical crosslinking agent and another crosslinking agent.

### [Radical Crosslinking Agent]

The composition preferably includes a radical crosslinking agent.

The radical crosslinking agent is a compound having a radically polymerizable group. The radically polymerizable group is preferably a group containing an ethylenically unsaturated bond. Examples of the group containing an ethylenically unsaturated bond include a vinyl group, an allyl group, a vinylphenyl group, a (meth)acryloyl group, a maleimide group, and a (meth)acrylamide group.

Among these, a (meth)acryloyl group, a (meth)acrylamide group, or a vinylphenyl group is preferable, and from the viewpoint of reactivity, a (meth)acryloyl group is more preferable.

The radical crosslinking agent is preferably a compound having one or more ethylenically unsaturated bonds; however, a compound having two or more ethylenically unsaturated bonds is more preferably contained. The radical crosslinking agent may have three or more ethylenically unsaturated bonds.

The compound having 2 or more ethylenically unsaturated bonds is preferably a compound having 2 to 15 ethylenically unsaturated bonds, more preferably a compound having 2 to 10 ethylenically unsaturated bonds, and still more preferably a compound having 2 to 6 ethylenically unsaturated bonds.

From the viewpoint of the film hardness of the pattern (cured substance) to be obtained, the composition preferably contains a compound having two ethylenically unsaturated bonds and a compound having three or more ethylenically unsaturated bonds.

The molecular weight of the radical crosslinking agent is preferably 2,000 or less, more preferably 1,500 or less, and still more preferably 900 or less. The lower limit of the molecular weight of the radical crosslinking agent is preferably 100 or more.

Specific examples of the radical crosslinking agent include unsaturated carboxylic acids (for example, acrylic acid, methacrylic acid, itaconic acid, crotonic acid, isocrotonic acid, and maleic acid), and esters and amides thereof, where esters between unsaturated carboxylic acids and polyhydric alcohol compounds or amides between unsaturated carboxylic acids and polyvalent amine compounds are preferable. In addition, addition reaction products produced by reacting unsaturated carboxylic acid esters or amides, having a nucleophilic substituent such as a hydroxy group, an amino group, or a sulfanyl group, with monofunctional or polyfunctional isocyanates or epoxies, dehydration condensation reaction products produced by reacting the above esters or amides with a monofunctional or polyfunctional carboxylic acid, or the like are also suitably used. In addition, an addition reaction product produced by reacting unsaturated carboxylic acid esters or amides, having an electrophilic substituent such as an isocyanate group or an epoxy group, with monofunctional or polyfunctional alcohols, amines, or thiols, and further, a substitution reaction product produced by reacting unsaturated carboxylic acid esters or amides, having an eliminable substituent such as a halogeno group or a tosyloxy group, with monofunctional or polyfunctional alcohols, amines, or thiols is also suitable. In addition, as other examples, it is also possible to use a group of compounds in which the unsaturated carboxylic acid described above is replaced with an unsaturated phosphonic acid, a vinylbenzene derivative such as styrene, a vinyl ether, an allyl ether, or the like. Regarding the specific examples thereof, reference can be made to the description of paragraphs 0113 to 0122 of JP2016-027357A, the content of which is incorporated in the present specification.

The radical crosslinking agent is also preferably a compound having a boiling point of 100 °C or higher under normal pressure. Examples of the compound having a boiling point of 100 °C or higher under normal pressure include the compounds described in paragraph 0203 of WO2021/112189A. The content thereof is incorporated in the present specification.

Examples of the preferred radical crosslinking agent other than those described above include the radically polymerizable compounds described in paragraphs 0204 to 0208 of WO2021/112189A. The content thereof is incorporated in the present specification.

As the radical crosslinking agent, dipentaerythritol triacrylate (as a commercially available product, KAYARAD D-330 (manufactured by Nippon Kayaku Co., Ltd.)), dipentaerythritol tetraacrylate (as a commercially available product, KAYARAD D-320 (manufactured by Nippon Kayaku Co., Ltd.)), A-TMMT (manufactured by Shin-Nakamura Chemical Co., Ltd.), dipentaerythritol penta(meth)acrylate (as a commercially available product, KAYARAD D-310 (manufactured by Nippon Kayaku Co., Ltd.)), dipentaerythritol hexa(meth)acrylate (as a commercially available product, KAYARAD DPHA (manufactured by Nippon Kayaku Co., Ltd.)), A-DPH (manufactured by Shin-Nakamura Chemical Co., Ltd.), or a structure in which a (meth)acryloyl group thereof is bonded through an ethylene glycol residue or a propylene glycol residue is preferable. Oligomer types thereof can also be used.

Examples of the commercially available product of the radical crosslinking agent include SR-494 which is a tetrafunctional acrylate having four ethyleneoxy chains, SR-209, 231, and 239 which are a difunctional methacrylate having four ethyleneoxy chains (all of which are manufactured by Sartomer Company Inc.), DPCA-60 which is a hexafunctional acrylate having six pentyleneoxy chains and TPA-330 which is a trifunctional acrylate having three isobutylene oxy chains (all of which are manufactured by Nippon Kayaku Co., Ltd.), UAS-10 and UAB-140 which are a urethane oligomer (all of which are manufactured by Nippon Paper Industries Co., Ltd.), NK Ester M-40G, NK Ester 4G, NK Ester M-9300, NK Ester A-9300, and UA-7200 (all of which are manufactured by Shin-Nakamura Chemical Co., Ltd.), DPHA-40H (manufactured by Nippon Kayaku Co., Ltd.), UA-306H, UA-306T, UA-306I, AH-600, T-600, and AI-600 (all of which are manufactured by KYOEISHA CHEMICAL Co., Ltd.), and Brenmer PME400 (manufactured by NOF Corporation).

As the radical crosslinking agent, the urethane acrylates as described in JP1973-041708B (JP-S48-041708B), JP1976-037193A (JP-S51-037193A), JP1990-032293B (JP-H02-032293B), and JP1990-016765B (JP-H02-016765B), and the urethane compounds having an ethylene oxide-based skeleton described in JP1983-049860B (JP-S58-049860B), JP1981-017654B (JP-S56-017654B), JP1987-039417B (JP-S62-039417B), and JP1987-039418B (JP-S62-039418B) are also suitable. As the radical crosslinking agent, the compounds having an amino structure or a sulfide structure in the molecule as described in JP1988-277653A (JP-S63-277653A), JP1988-260909A (JP-S63-260909A), and JP1989-105238A (JP-H01-105238A) can also be used.

The radical crosslinking agent may be a radical crosslinking agent having an acid group such as a carboxy group or a phosphoric acid group. The radical crosslinking agent having an acid group is preferably an ester between an aliphatic polyhydroxy compound and an unsaturated carboxylic acid and more preferably a radical crosslinking agent obtained by reacting an unreacted hydroxy group of an aliphatic polyhydroxy compound with a non-aromatic carboxylic acid anhydride to have an acid group. The radical crosslinking agent is particularly preferably a compound in which an aliphatic polyhydroxy compound is pentaerythritol or dipentaerythritol in a radical crosslinking agent having an acid group obtained by reacting an unreacted hydroxy group of the aliphatic polyhydroxy compound with a non-aromatic carboxylic acid anhydride. Examples of the commercially available product thereof include M-510 and M-520 as polybasic acid-modified acrylic oligomers which are manufactured by Toagosei Co., Ltd.

An acid value of the radical crosslinking agent having an acid group is preferably 0.1 to 300 mgKOH/g and more preferably 1 to 100 mgKOH/g. In a case where the acid value of the radical crosslinking agent is within the above-described range, excellent manufacturing handleability is exhibited, and excellent developability is exhibited. In addition, good polymerization properties are exhibited. The acid value is measured in accordance with the description of JIS K 0070: 1992.

The radical crosslinking agent is also preferably a radical crosslinking agent having at least one selected from the group consisting of a urea bond and a urethane bond (hereinafter, also referred to as a “crosslinking agent U”).

In the present invention, the urea bond is a bond represented by *—NR^{N}—C(═O)—NR^{N}—*, where R^{N}'s each independently represent a hydrogen atom or a monovalent organic group, and *'s each represent a bonding site to a carbon atom.

In the present invention, the urethane bond is a bond represented by *—O—C(═O)—NR^{N}—*, where R^{N} represents a hydrogen atom or a monovalent organic group, and *'s each represent a bonding site to a carbon atom.

In a case where the composition contains a crosslinking agent U, chemical resistance, resolution, and the like may be improved.

The crosslinking agent U may have only one urea bond or urethane bond, may have one or more urea bonds and one or more urethane bonds, may have two or more urea bonds without having a urethane bond, or may have two or more urethane bonds without having a urea bond.

The total number of urea bonds and urethane bonds in the crosslinking agent U is 1 or more, and it is preferably 1 to 10, more preferably 1 to 4, and still more preferably 1 or 2.

In a case where the crosslinking agent U does not have a urethane bond, the number of urea bonds in the crosslinking agent U is 1 or more, and it is preferably 1 to 10, more preferably 1 to 4, and still more preferably 1 or 2.

In a case where the crosslinking agent U does not have a urea bond, the number of urethane bonds in the crosslinking agent U is 1 or more, and it is preferably 1 to 10, more preferably 1 to 4, and still more preferably 1 or 2.

The radically polymerizable group in the crosslinking agent U is not particularly limited; however, examples thereof include a vinyl group, an allyl group, a (meth)acryloyl group, a (meth)acryloxy group, a (meth)acrylamide group, a vinylphenyl group, and a maleimide group, where a (meth)acryloxy group, a (meth)acrylamide group, a vinylphenyl group, or a maleimide group is preferable, and a (meth)acryloxy group is more preferable.

In a case where the crosslinking agent U has two or more radically polymerizable groups, the structures of the respective radically polymerizable groups may be the same or different from each other.

The number of radically polymerizable groups in the crosslinking agent U may be only one or may be two or more, and it is preferably 1 to 10, more preferably 1 to 6, and particularly preferably 1 to 4.

The radically polymerizable group value (the mass of the compound per 1 mol of the radically polymerizable group) in the crosslinking agent U is preferably 150 to 400 g/mol.

From the viewpoint of the chemical resistance of the cured substance, the lower limit of the above-described radically polymerizable group value is more preferably 200 g/mol or more, still more preferably 210 g/mol or more, even more preferably 220 g/mol or more, even still more preferably 230 g/mol or more, even still more preferably 240 g/mol or more, and particularly preferably 250 g/mol or more.

From the viewpoint of developability, the upper limit of the above-described radically polymerizable group value is more preferably 350 g/mol or less, still more preferably 330 g/mol or less, and particularly preferably 300 g/mol or less.

Among the above, the polymerizable group value of the crosslinking agent U is preferably 210 to 400 g/mol and more preferably 220 to 400 g/mol.

The crosslinking agent U has preferably, for example, a structure represented by Formula (U-1).

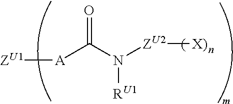

In Formula (U-1), R^{U1} is a hydrogen atom or a monovalent organic group, A is —O—, or —NR^{N}—, R^{N} is a hydrogen atom or a monovalent organic group, Z^{U1} is an m-valent organic group, Z^{U2} is an (n+1)-valent organic group, X is a radically polymerizable group, n is an integer of 1 or more, and m is an integer of 1 or more.

R^{U1} is preferably a hydrogen atom, an alkyl group, or an aromatic hydrocarbon group, and more preferably a hydrogen atom.

R^{N} is preferably a hydrogen atom, an alkyl group, or an aromatic hydrocarbon group, and more preferably a hydrogen atom.

Z^{U1} is preferably a hydrocarbon group, —O—, —C(═O)—, —S—, —S(═O)₂—, —NR^{N}—, or a group in which two or more of these are bonded, and more preferably a hydrocarbon group or a group in which a hydrocarbon group is bonded to at least one group selected from the group consisting of —O—, —C(═O)—, —S—, —S(═O)₂—, and —NR^{N}—.

As the above-described hydrocarbon group, a hydrocarbon group having 20 or less carbon atoms is preferable, a hydrocarbon group having 18 or less carbon atoms is more preferable, and a hydrocarbon group having 16 or less carbon atoms is still more preferable. Examples of the above-described hydrocarbon group include a saturated aliphatic hydrocarbon group, an aromatic hydrocarbon group, and a group represented by bonding of these groups. R^{N} represents a hydrogen atom or a monovalent organic group, and it is preferably a hydrogen atom or a hydrocarbon group, more preferably a hydrogen atom or an alkyl group, and still more preferably a hydrogen atom or a methyl group.

Z^{U2} is preferably a hydrocarbon group, —O—, —C(═O)—, —S—, —S(═O)₂—, —NR^{N}—, or a group in which two or more of these are bonded, and more preferably a hydrocarbon group or a group in which a hydrocarbon group is bonded to at least one group selected from the group consisting of —O—, —C(═O)—, —S—, —S(═O)₂—, and —NR^{N}—.

Examples of the hydrocarbon group include the same ones as those exemplified as Z^{U1}, and the same applies to the preferred aspect thereof.

X is not particularly limited; however, examples thereof include a vinyl group, an allyl group, a (meth)acryloyl group, a (meth)acryloxy group, a (meth)acrylamide group, a vinylphenyl group, and a maleimide group, where a (meth)acryloxy group, a (meth)acrylamide group, a vinylphenyl group, or a maleimide group is preferable, and a (meth)acryloxy group is more preferable.

n is preferably an integer of 1 to 10, more preferably an integer of 1 to 4, still more preferably 1 or 2, and particularly preferably 1.

m is preferably an integer of 1 to 10, more preferably an integer of 1 to 4, and still more preferably 1 or 2.

It is also preferable that the crosslinking agent U has at least one of a hydroxy group, an alkyleneoxy group, an amide group, or a cyano group.

From the viewpoint of the chemical resistance of the cured film to be obtained, the hydroxy group may be an alcoholic hydroxy group or a phenolic hydroxy group; however, it is preferably an alcoholic hydroxy group.

From the viewpoint of the chemical resistance of the cured film to be obtained, the alkyleneoxy group is preferably an alkyleneoxy group having 2 to 20 carbon atoms, more preferably an alkyleneoxy group having 2 to 10 carbon atoms, still more preferably an alkyleneoxy group having 2 to 4 carbon atoms, even still more preferably an ethyleneoxy group or a propyleneoxy group, and particularly preferably an ethylene group.

The alkyleneoxy group may be contained in the crosslinking agent U as a polyalkyleneoxy group. The number of repetitions of the alkyleneoxy group in this case is preferably 2 to 10 and more preferably 2 to 6.

The amide group refers to a bond represented by —C(═O)—NR^{N}—. R^{N} is as described above. In a case where the crosslinking agent U has an amide group, the crosslinking agent U can include, for example, a group represented by R—C(═O)—NR^{N}—* or a group represented by *—C(═O)—NR^{N}—R. R represents a hydrogen atom or a monovalent substituent, and it is preferably a hydrogen atom or a hydrocarbon group and more preferably a hydrogen atom, an alkyl group, or an aromatic hydrocarbon group.

The crosslinking agent U may have, in the molecule, two or more structures selected from the group consisting of a hydroxy group, an alkyleneoxy group (however, a polyalkyleneoxy group in a case of constituting a polyalkyleneoxy group), an amide group, and a cyano group; however, an aspect in which only one structure is contained in the molecule is also preferable.

The hydroxy group, the alkyleneoxy group, the amide group, and the cyano group may be present at any position of the crosslinking agent U. However, from the viewpoint of chemical resistance, it is also preferable that the crosslinking agent U is such that at least one selected from the group consisting of the hydroxy group, the alkyleneoxy group, the amide group, and the cyano group, and at least one radically polymerizable group contained in the crosslinking agent U are linked by a linking group (hereinafter, also referred to as a “linking group L2-1”) containing a urea bond or a urethane bond.

In particular, in a case where the crosslinking agent U contains only one radically polymerizable group, it is preferable that the radically polymerizable group contained in the crosslinking agent U and at least one selected from the group consisting of a hydroxy group, an alkyleneoxy group, an amide group, and a cyano group are linked by a linking group including a urea bond or a urethane bond (hereinafter, also referred to as a “linking group L2-2”).

In a case where the crosslinking agent U contains an alkyleneoxy group (however, a polyalkyleneoxy group in a case of constituting a polyalkyleneoxy group) and has the above-described linking group L2-1 or the above-described linking group L2-2, a structure that is bonded to a side of the alkyleneoxy group (however, a polyalkyleneoxy group in a case of constituting a polyalkyleneoxy group) opposite to the linking group L2-1 or the linking group L2-2 is not particularly limited; however, it is preferably a hydrocarbon group, a radically polymerizable group, or a group represented by a combination thereof. As the above-described hydrocarbon group, a hydrocarbon group having 20 or less carbon atoms is preferable, a hydrocarbon group having 18 or less carbon atoms is more preferable, and a hydrocarbon group having 16 or less carbon atoms is still more preferable. Examples of the above-described hydrocarbon group include a saturated aliphatic hydrocarbon group, an aromatic hydrocarbon group, and a group represented by bonding of these groups. In addition, the preferred aspect of the radically polymerizable group is the same as the preferred aspect of the radically polymerizable group in the above-described crosslinking agent U.

In a case where the crosslinking agent U contains an amide group and has the linking group L2-1 or the linking group L2-2, a structure that is bonded to a side of the amide group opposite to the linking group L2-1 or the linking group L2-2 is not particularly limited; however, it is preferably a hydrocarbon group, a radically polymerizable group, or a group represented by a combination thereof. As the above-described hydrocarbon group, a hydrocarbon group having 20 or less carbon atoms is preferable, a hydrocarbon group having 18 or less carbon atoms is more preferable, and a hydrocarbon group having 16 or less carbon atoms is still more preferable. In addition, examples of the above-described hydrocarbon group include a saturated aliphatic hydrocarbon group, an aromatic hydrocarbon group, and a group represented by bonding of these groups. The preferred aspect of the radically polymerizable group is the same as the preferred aspect of the radically polymerizable group in the above-described crosslinking agent U. In addition, in the above aspect, a carbon atom side of the amide group may be bonded to the linking group L2-1 or the linking group L2-2, or a nitrogen atom side of the amide group may be bonded to the linking group L2-1 or the linking group L2-2.

Among these, from the viewpoint of the adhesiveness to the base material, the chemical resistance, and the Cu void suppression, the crosslinking agent U preferably has a hydroxy group.

From the viewpoint of compatibility with the heterocyclic ring-containing polymer and the like, the crosslinking agent U preferably includes an aromatic group.

The aromatic group is preferably directly bonded to a urea bond or a urethane bond contained in the crosslinking agent U. In a case where the crosslinking agent U contains two or more urea bonds or two or more urethane bonds, it is preferable that one of the urea bonds or urethane bonds is directly bonded to the aromatic group.

The aromatic group may be an aromatic hydrocarbon group or an aromatic heterocyclic group and may have a structure in which these groups form a fused ring; however, an aromatic hydrocarbon group is preferable.

The aromatic hydrocarbon group is preferably an aromatic hydrocarbon group having 6 to 30 carbon atoms, more preferably an aromatic hydrocarbon group having 6 to 20 carbon atoms, and still more preferably a group obtained by removing two or more hydrogen atoms from a benzene ring structure.

The aromatic heterocyclic group is preferably a 5-membered or 6-membered aromatic heterocyclic group. Examples of the aromatic heterocyclic ring in such an aromatic heterocyclic group include pyrrole, imidazole, triazole, tetrazole, pyrazole, furan, thiophene, oxazole, isoxazole, thiazole, pyridine, pyrazine, pyrimidine, pyridazine, and triazine. These rings may be further fused with another ring, for example, as in the case of indole or benzimidazole.

The heteroatom contained in the aromatic heterocyclic group is preferably a nitrogen atom, an oxygen atom, or a sulfur atom.

It is preferable that the aromatic group is included in, for example, a linking group that links two or more radically polymerizable groups and links a linking group having a urea bond or a urethane bond, or at least one selected from the group consisting of a hydroxy group, an alkyleneoxy group, an amide group, and a cyano group, to at least one radically polymerizable group contained in the crosslinking agent U.

The number of atoms (linking chain length) between the urea bond or urethane bond and the radically polymerizable group in the crosslinking agent U is not particularly limited; however, it is preferably 30 or less, more preferably 2 to 20, and still more preferably 2 to 10.

In a case where the crosslinking agent U contains two or more urea bonds or urethane bonds in total, the minimum number of atoms (linking chain length) between the urea bond or urethane bond and the radically polymerizable group is sufficient to be within the above-described range in a case where the crosslinking agent U contains two or more radically polymerizable groups, or in a case where the crosslinking agent U contains two or more urea bonds or two or more urethane bonds and two or more radically polymerizable groups,

In the present specification, the phrase “number of atoms (linking chain length) between the urea bond or urethane bond and the polymerizable group” refers to the smallest number of atoms (minimum number of atoms) for linking targets among the number of atoms for atomic chains on a path that links two atoms or atomic groups between the linking targets. For example, in a structure represented by the following Formula, the number of atoms (linking chain length) between the urea bond and the radically polymerizable group (methacryloyloxy group) is 2.

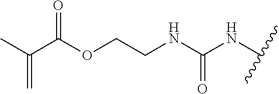 [SMILES: *NC(=O)NCCOC(=O)C(=C)C]

### [Symmetry Axis]

It is also preferable that the crosslinking agent U is a compound having a structure which does not have a symmetry axis.

The fact that the crosslinking agent U does not have a symmetry axis refers to that the crosslinking agent U is a left-right asymmetric compound which does not have an axis that generates the same molecule as the original molecule in a case where the entire compound is rotated. In addition, in a case where the structural formula of the crosslinking agent U is shown on the paper surface, the fact that the crosslinking agent U does not have a symmetry axis refers to that the structural formula of the crosslinking agent U cannot be shown in a form having a symmetry axis.

It is considered that the aggregation of the crosslinking agents U is suppressed in the composition film in a case where the crosslinking agent U does not have a symmetry axis.

### [Molecular Weight]

The molecular weight of the crosslinking agent U is preferably 100 to 2,000, more preferably 150 to 1,500, and still more preferably 200 to 900.

A manufacturing method for the crosslinking agent U is not particularly limited; however, the crosslinking agent U can be obtained, for example, by reacting a radically polymerizable compound with a compound having an isocyanate group and a compound having at least one of a hydroxy group or an amino group.

Specific examples of the crosslinking agent U are shown below; however, the crosslinking agent U is not limited thereto.

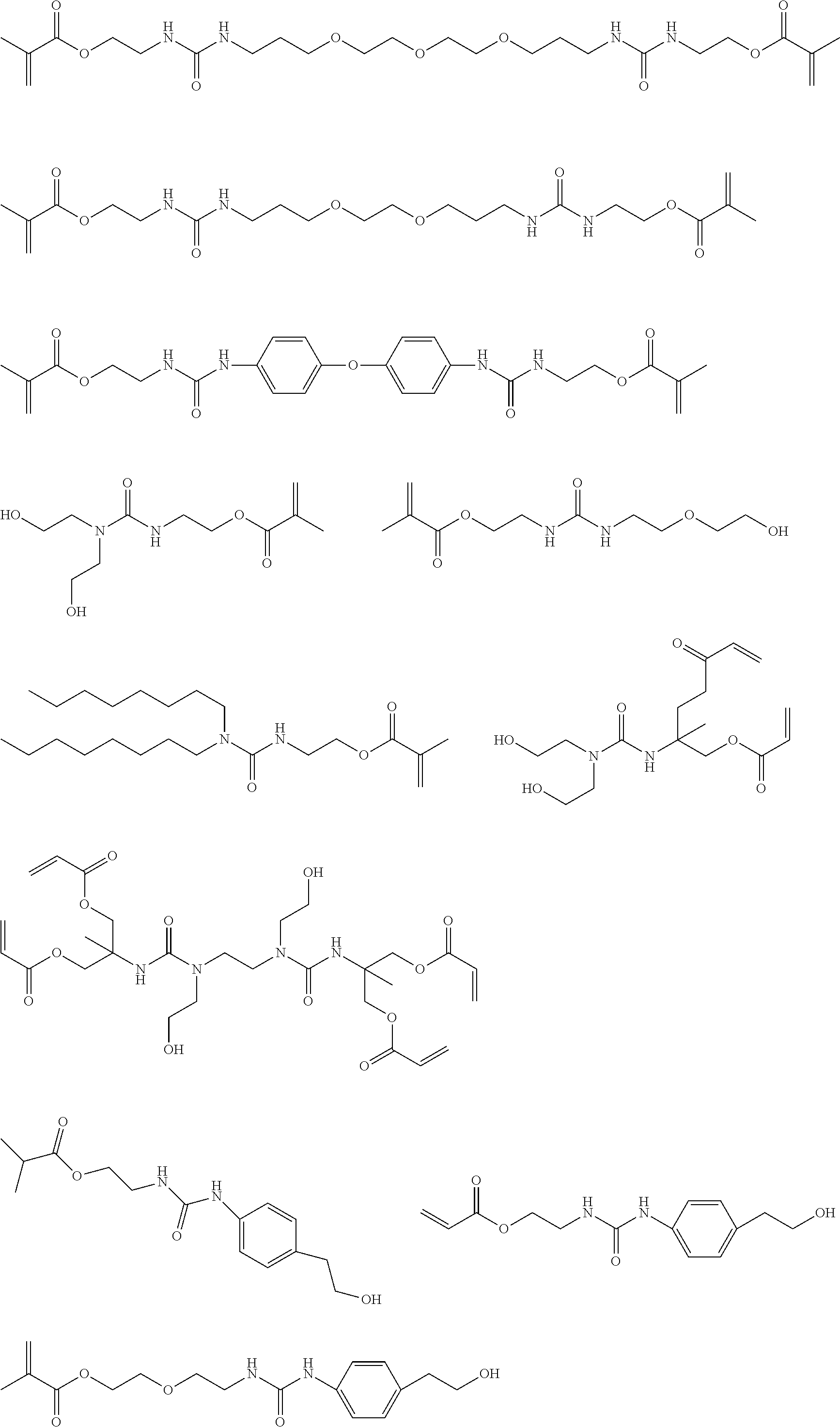

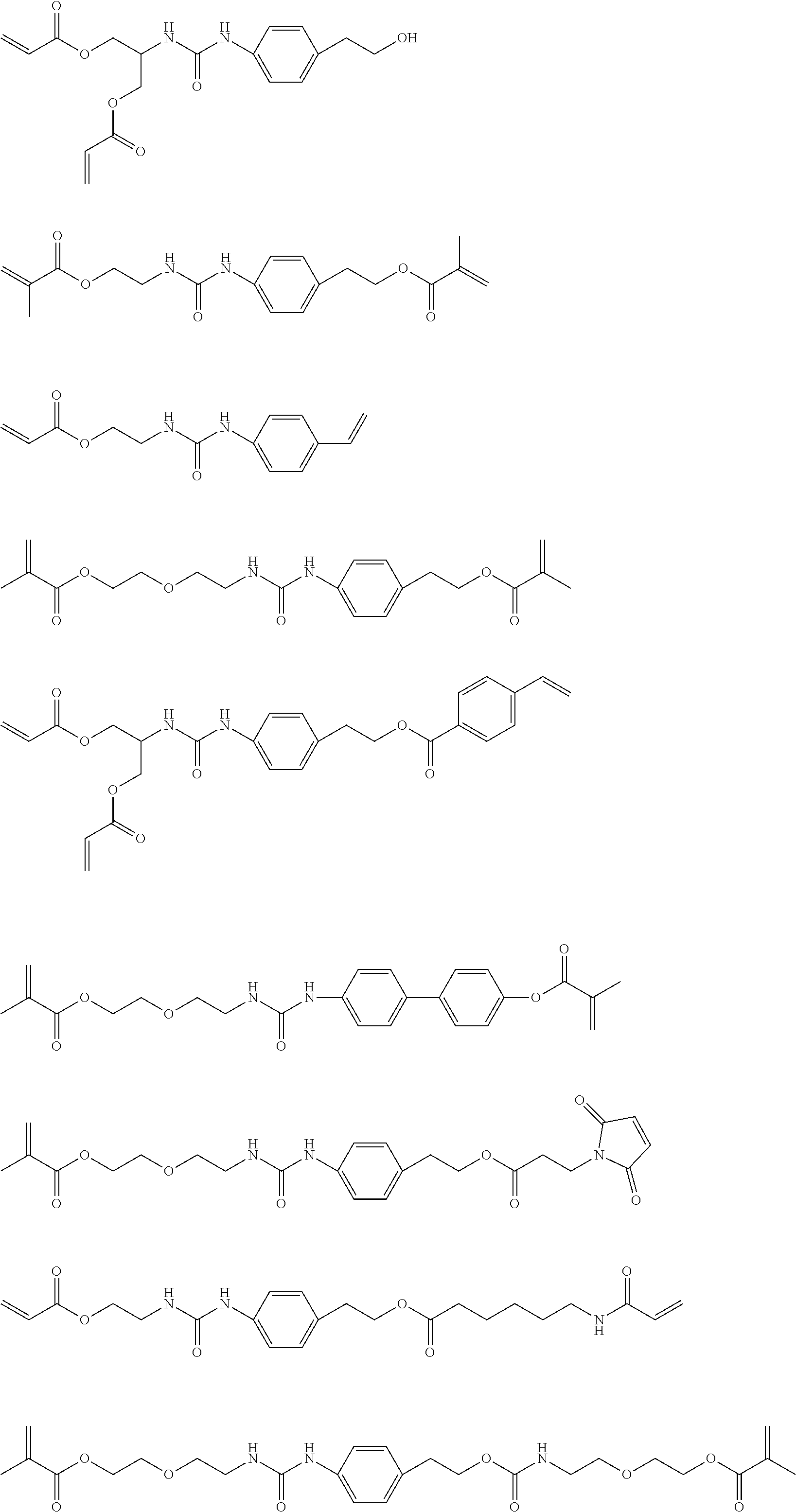

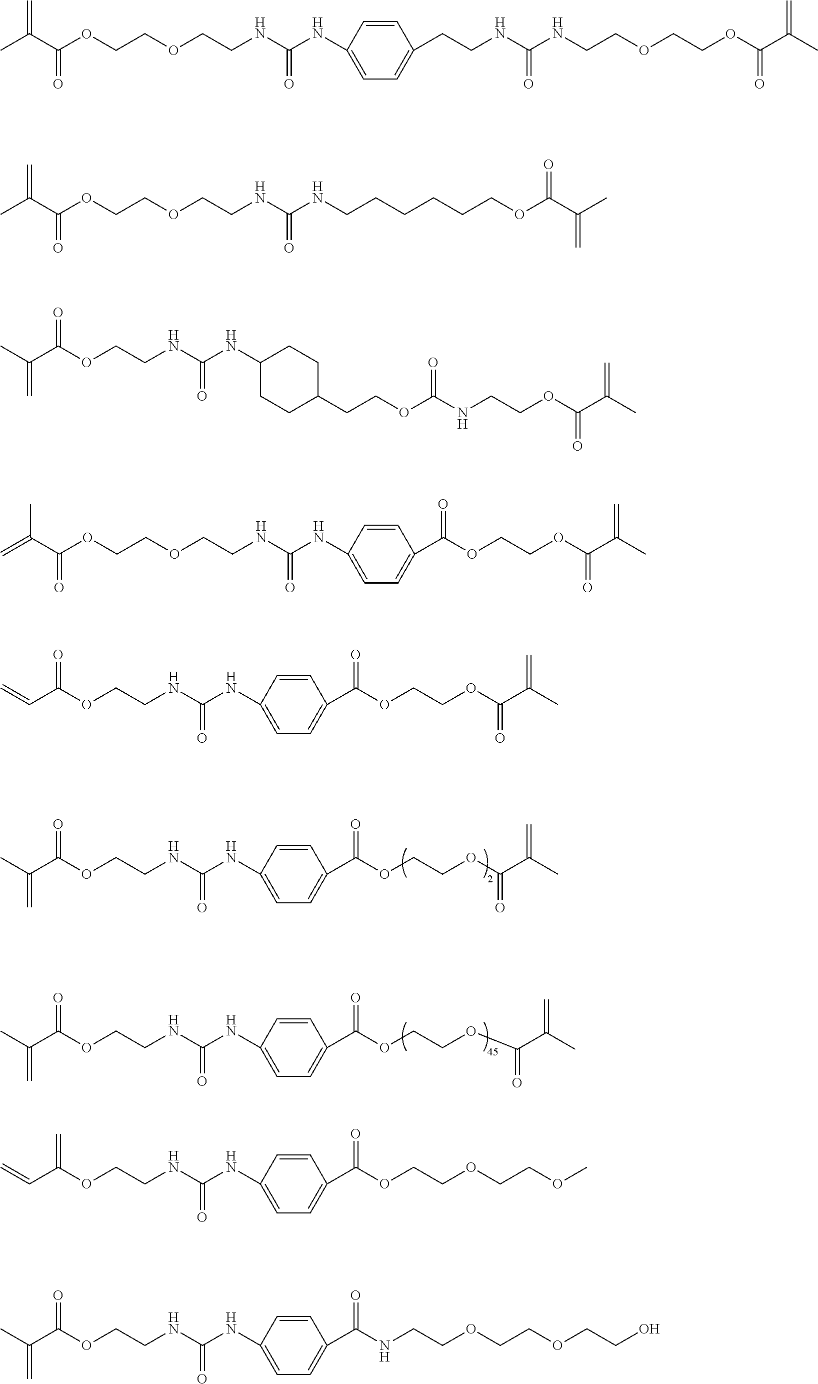

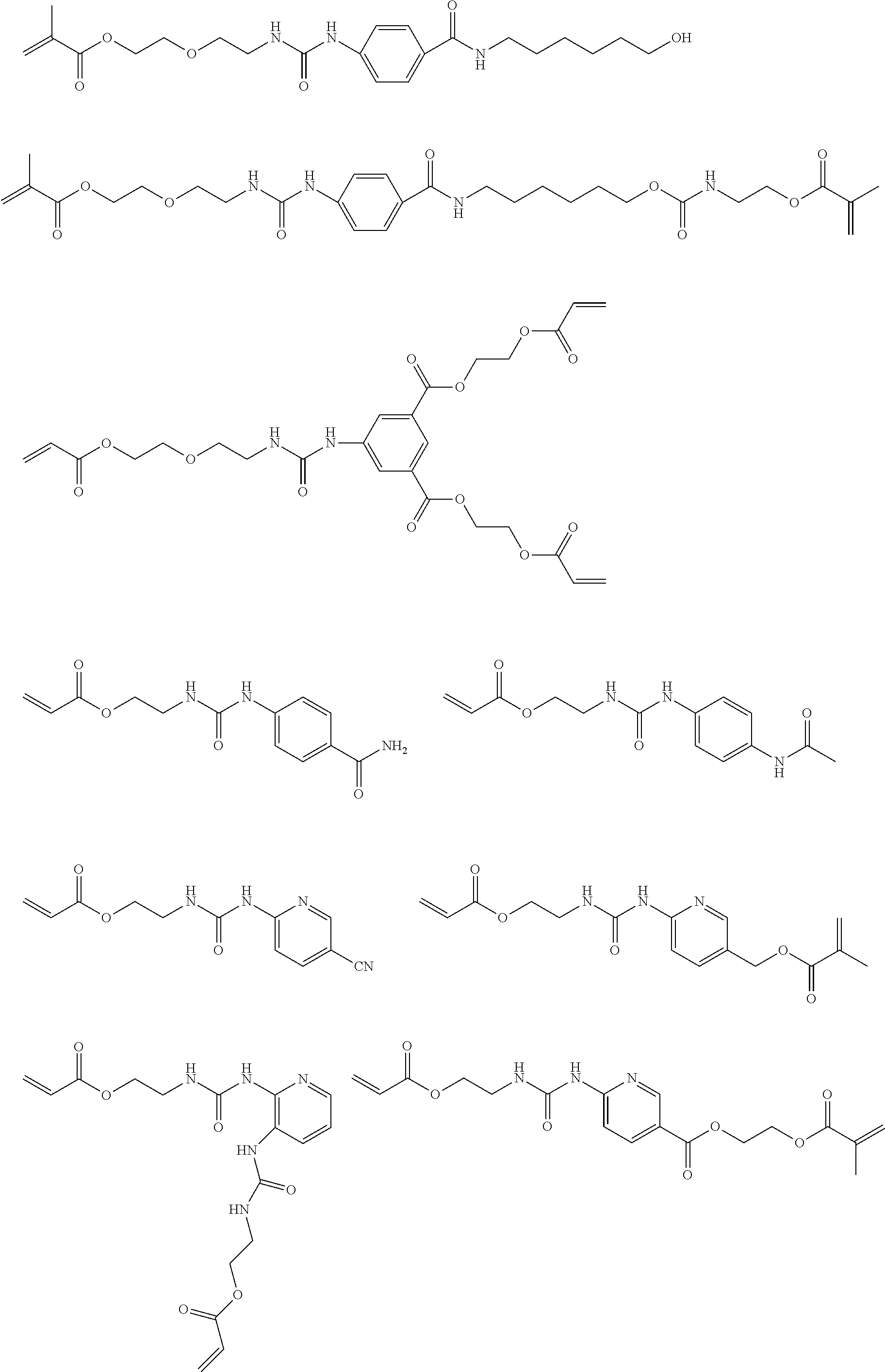

In the composition, it is preferable to use difunctional methacrylate or acrylate from the viewpoint of pattern resolution and film elasticity.

As the specific compound, the following compound can be used; triethylene glycol diacrylate, triethylene glycol dimethacrylate, tetraethylene glycol dimethacrylate, tetraethylene glycol diacrylate, polyethylene glycol (PEG) 200 diacrylate, PEG 200 dimethacrylate, PEG 600 diacrylate, PEG 600 dimethacrylate, polytetraethylene glycol diacrylate, polytetraethylene glycol dimethacrylate, dipropylene glycol diacrylate, tripropylene glycol diacrylate, neopentyl glycol diacrylate, neopentyl glycol dimethacrylate, 3-methyl-1,5-pentanediol diacrylate, 1,6-hexanediol diacrylate, 1,6-hexanediol dimethacrylate, dimethylol-tricyclodecanediacrylate, dimethylol-tricyclodecanedimethacrylate, a diacrylate of an ethylene oxide (EO) adduct of bisphenol A, a dimethacrylate of an EO adduct of bisphenol A, a diacrylate of a propylene oxide (PO) adduct of bisphenol A, a dimethacrylate of a PO adduct of bisphenol A, 2-hydroxy-3-acryloyloxypropyl methacrylate, isocyanuric acid EO-modified diacrylate, isocyanuric acid EO-modified dimethacrylate, another difunctional acrylate having a urethane bond, and difunctional methacrylate having a urethane bond. As necessary, two or more of these can be mixedly used.

It is noted that, for example, the PEG 200 diacrylate refers to a polyethylene glycol diacrylate having a polyethylene glycol chain Formula weight of about 200.

From the viewpoint of suppressing warping of the pattern (cured substance), the composition can preferably use a monofunctional radical crosslinking agent as the radical crosslinking agent. As the monofunctional radical crosslinking agent, (meth)acrylic acid derivatives such as n-butyl (meth)acrylate, 2-ethylhexyl (meth)acrylate, 2-hydroxyethyl (meth)acrylate; butoxyethyl (meth)acrylate, carbitol (meth)acrylate, cyclohexyl (meth)acrylate, benzyl (meth)acrylate, phenoxyethyl (meth)acrylate, N-methylol (meth)acrylamide, glycidyl (meth)acrylate, polyethylene glycol mono(meth)acrylate, and polypropylene glycol mono(meth)acrylate, N-vinyl compounds such as N-vinylpyrrolidone and N-vinylcaprolactam, allyl glycidyl ethers, and the like are preferably used. As the monofunctional radical crosslinking agent, a compound having a boiling point of 100 °C or higher under normal pressure is also preferable in order to suppress volatilization before exposure.

In addition, examples of the bi- or higher functional radical crosslinking agent include allyl compounds such as diallyl phthalate and triallyl trimellitate.

In a case where a radical crosslinking agent is contained, the content of the radical crosslinking agent is preferably more than 0% by mass and 60% by mass or less with respect to the total solid content of the composition. The lower limit thereof is more preferably 5% by mass or more. The upper limit thereof is more preferably 50% by mass or less and still more preferably 30% by mass or less.

One kind of radical crosslinking agent may be used alone, or two or more kinds thereof may be mixedly used. In a case where two or more kinds thereof are used in combination, the total amount thereof is preferably in the above range.

### [Another Crosslinking Agent]

The composition preferably includes a crosslinking agent different from the above-described radical crosslinking agent.

The other crosslinking agent refers to a crosslinking agent other than the above-described radical crosslinking agent, where it is preferably a compound having a plurality of groups, in the molecule, which accelerates a reaction of forming a covalent bond between other compounds in the composition or reaction products thereof, by the photosensitization of the above-described photoacid generator or photobase generator, and more preferably a compound having a plurality of groups, in the molecule, which accelerates a reaction of forming a covalent bond between other compounds in the composition or reaction products thereof, by the action of the acid or the base.

The acid or the base is preferably an acid or a base, which is generated from a photoacid generator or a photobase generator in the exposure step.

Examples of the other crosslinking agent include the compounds described in paragraphs 0179 to 0207 of WO2022/145355A. The above description is incorporated in the present specification.

### [Polymerization Initiator]

The composition preferably contains a polymerization initiator.

The polymerization initiator may be a thermal polymerization initiator or a photopolymerization initiator; however, it is particularly preferable to contain a photopolymerization initiator.

The photopolymerization initiator is preferably a photoradical polymerization initiator. The photoradical polymerization initiator is not particularly limited and can be appropriately selected from publicly known photoradical polymerization initiators. For example, a photoradical polymerization initiator having photosensitivity to rays ranging from the ultraviolet ray range to the visible light range is preferable. In addition, it may be an activator that acts with a sensitizing agent to generate an active radical.

The photoradical polymerization initiator preferably contains at least one compound having a molar absorption coefficient of at least about 50 L mol⁻¹ cm⁻¹ within a range of a wavelength of about 240 to 800 nm (preferably 330 to 500 nm). The molar absorption coefficient of a compound can be measured using a well-publicly known method. For example, it is preferable to carry out a measurement at a concentration of 0.01 g/L using an ethyl acetate solvent with an ultraviolet-visible spectrophotometer (Cary-5 spectrophotometer manufactured by Varian Medical Systems, Inc.).

As a photoradical polymerization initiator, well-known compounds can be optionally used. Examples thereof include a halogenated hydrocarbon derivative (for example, a compound having a triazine skeleton, a compound having an oxadiazole skeleton, or a compound having a trihalomethyl group), an acylphosphine compound such as an acylphosphine oxide, hexaarylbiimidazole, an oxime compound such as an oxime derivative, an organic peroxide, a thio compound, a ketone compound, an aromatic onium salt, a keto oxime ether, an α-amino ketone compound such as aminoacetophenone, an α-hydroxy ketone compound such as hydroxyacetophenone, an azo-based compound, an azide compound, a metallocene compound, an organic boron compound, and an iron arene complex. With regard to details thereof, reference can be made to the description of paragraphs 0165 to 0182 of JP2016-027357A and paragraphs 0138 to 0151 of WO2015/199219A, the contents of which are incorporated in the present specification. In addition, examples thereof include the compounds described in paragraphs 0065 to 0111 of JP2014-130173A and JP6301489B, the peroxide-based photopolymerization initiator described in MATERIAL STAGE 37 to 60 p, vol. 19, No. 3, 2019, the photopolymerization initiator described in WO2018/221177A, the photopolymerization initiator described in WO2018/110179A, the photopolymerization initiator described in JP2019-043864A, the photopolymerization initiator described in JP2019-044030A, and the peroxide-based initiator described in JP2019-167313A, the contents of which are incorporated in the present specification.

Examples of the ketone compound include compounds described in paragraph 0087 of JP2015-087611A, the content of which is incorporated in the present specification. As a commercially available product thereof, KAYACURE DETX-S (manufactured by Nippon Kayaku Co., Ltd.) is also suitably used.

In one embodiment of the present invention, a hydroxyacetophenone compound, an aminoacetophenone compound, and an acylphosphine compound can be suitably used as the photoradical polymerization initiator. More specifically, for example, the aminoacetophenone-based initiator described in JP1998-291969A (JP-H10-291969A) and the acylphosphine oxide-based initiator described in JP4225898B can be used, the contents of which are incorporated in the present specification.

As the α-hydroxy ketone-based initiator, Omnirad 184, Omnirad 1173, Omnirad 2959, Omnirad 127 (all of which are manufactured by IGM Resins B.V.), IRGACURE 184 (IRGACURE is a registered trademark), DAROCUR 1173, IRGACURE 500, IRGACURE-2959, and IRGACURE 127 (all of which are manufactured by BASF SE) can be used.

As the α-amino ketone-based initiator, Omnirad 907, Omnirad 369, Omnirad 369E, Omnirad 379EG (all of which are manufactured by IGM Resins B.V.), IRGACURE 907, IRGACURE 369, and IRGACURE 379 (all of which are manufactured by BASF SE) can be used.

As the aminoacetophenone-based initiator, the acylphosphine oxide-based initiator, and the metallocene compound, it is also possible to suitably use, for example, the compounds described in paragraphs 0161 to 0163 of WO2021/112189A. The content thereof is incorporated in the present specification.

Examples of the more preferred photoradical polymerization initiator include an oxime compound. In a case where an oxime compound is used, exposure latitude can be more effectively improved. The oxime compound is particularly preferable since the oxime compound has a wide exposure latitude (a wide exposure margin) and also works as a photocuring accelerator.

Specific examples of the oxime compound include the compounds described in JP2001-233842A, the compounds described in JP2000-080068A, the compounds described in JP2006-342166A, the compounds described in J. C. S. Perkin II (1979, pp. 1653-1660), the compounds described in J. C. S. Perkin II (1979, pp. 156-162), the compounds described in Journal of Photopolymer Science and Technology (1995, pp. 202-232), the compounds described in JP2000-066385A, the compounds described in JP2004-534797A, the compounds described in JP2017-019766A, the compounds described in JP6065596B, the compounds described in WO2015/152153A, the compounds described in WO2017/051680A, the compounds described in JP2017-198865A, the compounds described in paragraph Nos. 0025 to 0038 of WO2017/164127A, and the compounds described in WO2013/167515A, the content of which is incorporated in the present specification.

Examples of the preferred oxime compound include compounds having the following structures, 3-(benzoyloxy(imino))butan-2-one, 3-(acetoxy(imino))butan-2-one, 3-(propionyloxy(imino))butan-2-one, 2-(acetoxy(imino))pentan-3-one, 2-(acetoxy(imino))-1-phenylpropan-1-one, 2-(benzoyloxy(imino))-1-phenylpropan-1-one, 3-((4-toluenesulfonyloxy)imino)butan-2-one, and 2-(ethoxycarbonyloxy(imino))-1-phenylpropan-1-one. In the composition, it is preferable to use an oxime compound, particularly as a photoradical polymerization initiator. The oxime compound as a photoradical polymerization initiator has a linking group of >C═N—O—C(═O)— in the molecule.

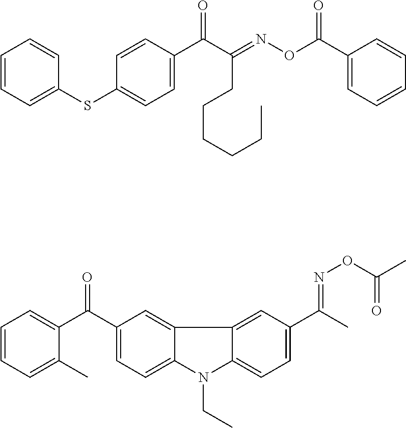 [SMILES: CCCCCC/C(=N\OC(=O)c1ccccc1)C(=O)c1ccc(Sc2ccccc2)cc1 ; CCn1c2ccc(C(=O)c3ccccc3C)cc2c2cc(/C(C)=N/OC(C)=O)ccc21]

Examples of the commercially available product of the oxime compound include IRGACURE OXE 01, IRGACURE OXE 02, IRGACURE OXE 03, and IRGACURE OXE 04 (all of which are manufactured by BASF SE), ADEKA OPTOMER N-1919 (manufactured by ADEKA Corporation, the photoradical polymerization initiator 2 described in JP2012-014052A), TR-PBG-304 and TR-PBG-305 (all of which are manufactured by Changzhou Tronly New Electronic Materials Co., Ltd.), ADEKA ARKLS NCI-730, NCI-831, and ADEKA ARKLS NCI-930 (all of which are manufactured by ADEKA Corporation), DFI-091 (manufactured by DAITO CHEMIX Co., Ltd.), and SpeedCure PDO (manufactured by SARTOMER ARKEMA). In addition, oxime compounds having the following structures can also be used.

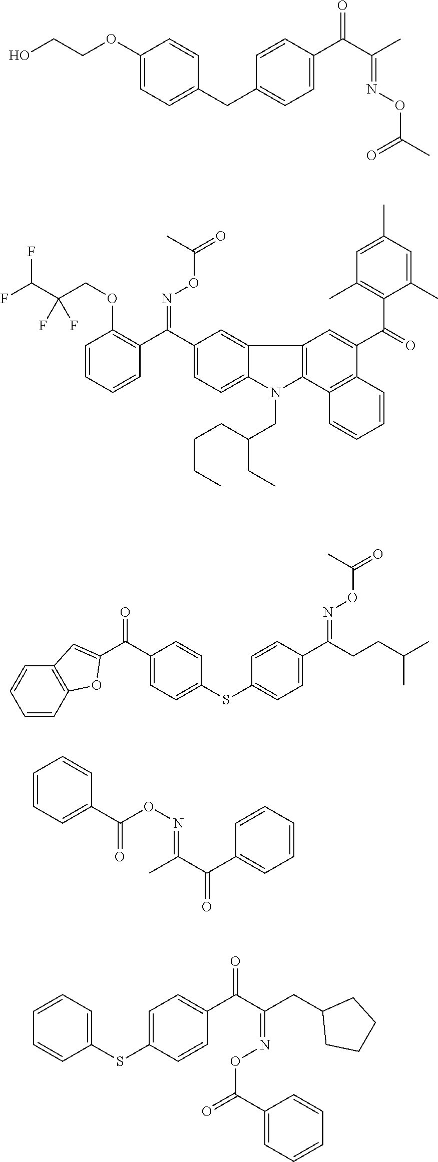

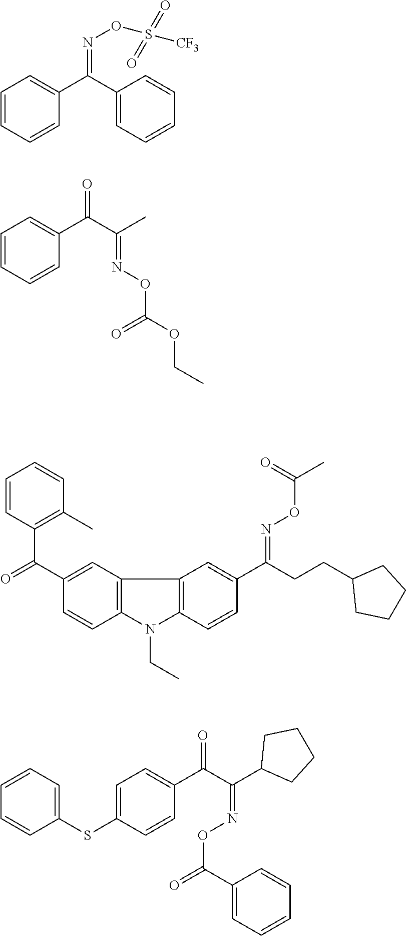 [SMILES: O=S(=O)(ON=C(c1ccccc1)c1ccccc1)C(F)(F)F ; CCOC(=O)O/N=C(\C)C(=O)c1ccccc1 ; CCn1c2ccc(C(=O)c3ccccc3C)cc2c2cc(/C(CCC3CCCC3)=N/OC(C)=O)ccc21 ; O=C(O/N=C(\C(=O)c1ccc(Sc2ccccc2)cc1)C1CCCC1)c1ccccc1]

As the photoradical polymerization initiator, it is also possible to use, for example, the oxime compounds having a fluorene ring, which are described in paragraphs 0169 to 0171 of WO2021/112189A, an oxime compound having a skeleton in which at least one benzene ring of a carbazole ring is a naphthalene ring, or an oxime compound having a fluorine atom.

In addition, it is also possible to use the oxime compounds having a nitro group, which are described in paragraphs 0208 to 0210 of WO2021/020359A, an oxime compound having a benzofuran skeleton, or an oxime compound in which a substituent having a hydroxy group is bonded to a carbazole skeleton. The content thereof is incorporated in the present specification.

In addition, as the photopolymerization initiator, compounds described in paragraphs 0113 to 0117 of JP2023-058585A can also be used. This description is incorporated in the present specification.

In a case where the composition contains a photopolymerization initiator, the content thereof is preferably 0.1% to 30% by mass, more preferably 0.1% to 20% by mass, still more preferably 0.5% to 15% by mass, and even still more preferably 1.0% to 10% by mass with respect to the total solid content of the composition. Only one kind of photopolymerization initiator may be contained, or two or more kinds thereof may be contained. In a case where two or more kinds of photopolymerization initiators are contained, the total amount thereof is preferably within the above-described range.

It is noted that since the photopolymerization initiator may also function as a thermal polymerization initiator, crosslinking with the photopolymerization initiator may be further allowed to proceed by heating an oven, a hot plate, or the like.

### [Sensitizing Agent]

The composition may include a sensitizer. The sensitizing agent absorbs a specific radioactive ray to be in an electronically excited state. The sensitizing agent in the electronically excited state is brought into contact with a thermal radical polymerization initiator, a photoradical polymerization initiator, or the like, to cause actions such as electron migration, energy transfer, and heat generation. As a result, the thermal radical polymerization and the photoradical polymerization initiator undergo a chemical change and decompose to generate a radical, an acid, or a base.

In addition, as a usable sensitizing agent, a benzophenone-based, a Michler's ketone-based, a coumarin-based, a pyrazole azo-based, an anilino azo-based, a triphenylmethane-based, an anthraquinone-based, an anthracene-based, an anthrapylidene-based, a benzylidene-based, an oxonol-based, a pyrazolotriazole azo-based, a pyridone azo-based, a cyanine-based, a phenothiazine-based, a pyrrolopyrazole azomethine-based, a xanthene-based, a phthalocyanine-based, a benzopyran-based, and an indigo-based compound can be used.

Examples of the sensitizing agent include, Michler's ketone, 4,4′-bis(diethylamino)benzophenone, 2,5-bis(4′-diethylaminobenzal)cyclopentane, 2,6-bis(4′-diethylaminobenzal)cyclohexanone, 2,6-bis(4′-diethylaminobenzal)-4-methylcyclohexanone, 4,4′-bis(dimethylamino)chalcone, 4,4′-bis(diethylamino)chalcone, p-dimethylaminocinnamylidene indanone, p-dimethylamino benzylidene indanone, 2-(p-dimethylaminophenylbiphenylene)-benzothiazole, 2-(p-dimethylaminophenylvinylene)benzothiazole, 2-(p-dimethylaminophenylvinylene)isonaphtothiazole, 1,3-bis(4′-dimethylaminobenzal)acetone, 1,3-bis(4′-diethylaminobenzal)acetone, 3,3′-carbonyl-bis(7-diethylaminocoumarin), 3-acetyl-7-dimethylaminocoumarin, 3-ethoxycarbonyl-7-dimethylaminocoumarin, 3-benzyloxycarbonyl-7-dimethylaminocoumarin, 3-methoxycarbonyl-7-diethylaminocoumarin, 3-ethoxycarbonyl-7-diethylaminocoumarin (ethyl 7-(diethylamino)coumarin-3-carboxylate), N-phenyl-N′-ethylethanolamine, N-phenyldiethanolamine, N-p-tolyldiethanolamine, N-phenylethanolamine, 4-morpholinobenzophenone, isoamyl dimethylaminobenzoate, isoamyl diethylaminobenzoate, 2-mercaptobenzimidazole, 1-phenyl-5-mercaptotetrazole, 2-mercaptobenzothiazole, 2-(p-dimethylaminostyryl)benzoxazole, 2-(p-dimethylaminostyryl)benzothiazole, 2-(p-dimethylaminostyryl)naphtho (1,2-d)thiazole, 2-(p-dimethylaminobenzoyl)styrene, diphenylacetamide, benzanilide, N-methylacetanilide, and 3′,4′-dimethylacetanilide.

In addition, other sensitizing dyes may be used.

For details of the sensitizing dye, reference can be made to the description in paragraphs 0161 to 0163 of JP2016-027357A, the content of which is incorporated in the present specification.

In a case where the composition contains a sensitizing agent, the content of the sensitizing agent is preferably 0.01% to 20% by mass, more preferably 0.1% to 15% by mass, and still more preferably 0.5% to 10% by mass with respect to the total solid content of the composition. One kind of sensitizing agent may be used alone, or two or more kinds thereof may be used in combination.

### [Chain Transfer Agent]

The composition may contain a chain transfer agent. The chain transfer agent is defined, for example, in Polymer Dictionary, 3rd Edition, pp. 683 to 684 (edited by The Society of Polymer Science, 2005). As the chain transfer agent, for example, the following compound is used; a group of compounds having —S—S—, —SO₂—S—, —N—O—, SH, PH, SiH, or GeH in the molecule, or a dithiobenzoate compound, a trithiocarbonate compound, dithiocarbamate, or a xanthate compound, which has a thiocarbonylthio group that is used for the reversible addition fragmentation chain transfer (RAFT) polymerization. These can donate hydrogen to a low active radical to generate a radical or can be oxidized and then deprotonated to generate a radical. In particular, a thiol compound can be preferably used.

In addition, as the chain transfer agent, the compounds described in paragraphs 0152 and 0153 of WO2015/199219A can also be used, the content of which is incorporated in the present specification.

In a case where the composition has a chain transfer agent, the content of the chain transfer agent is preferably 0.01 to 20 parts by mass, more preferably 0.1 to 10 parts by mass, and still more preferably 0.5 to 5 parts by mass, with respect to 100 parts by mass of the total solid content of the composition. Only one kind of chain transfer agent may be used alone, or two or more kinds thereof may be used. In a case where two or more kinds of chain transfer agents are used, the total thereof is preferably within the above-described range.

In addition, an aspect in which the composition includes two or more polymerization initiators as the polymerization initiator is also one of the preferred aspects of the present invention.

Specifically, the composition preferably includes a photopolymerization initiator and a thermal polymerization initiator described later, or includes the above-described photoradical polymerization initiator and the above-described photo-acid generator.

By containing the photopolymerization initiator and the thermal polymerization initiator described later, pattern formation by exposure is possible, and radical polymerization is also likely to proceed during curing in the heating step described later, and thus the performance such as chemical resistance may be improved.

In the content ratio in a case where the photopolymerization initiator and the thermal polymerization initiator described later are contained, the content of the thermal polymerization initiator is preferably 20% to 70% by mass and more preferably 30% to 60% by mass with respect to the total content of the photopolymerization initiator and the thermal polymerization initiator.

The performance such as resolution may be improved by containing a photoradical polymerization initiator and a photoacid generator.

In the content ratio in a case where the photopolymerization initiator and the photoacid generator are contained, the content of the photoacid generator is preferably 20% to 70% by mass, and more preferably 30% to 60% by mass with respect to the total content of the photopolymerization initiator and the photoacid generator.

### [Thermal Polymerization Initiator]

Examples of the thermal polymerization initiator include a thermal radical polymerization initiator. The thermal radical polymerization initiator is a compound that generates a radical by heat energy and initiates or accelerates a polymerization reaction of a compound having polymerization properties. In a case where a thermal radical polymerization initiator is added, the polymerization reaction of the resin and the polymerizable compound can be allowed to proceed, and thus the solvent resistance can be further improved.

Specific examples of thermal radical polymerization initiator include compounds described in paragraphs 0074 to 0118 of JP2008-063554A, the content of which is incorporated in the present specification.

In a case where a thermal polymerization initiator is contained, the content thereof is preferably 0.1% to 30% by mass, more preferably 0.1% to 20% by mass, and still more preferably 0.5% to 15% by mass with respect to the total solid content of the composition.

The composition may contain only one kind of thermal polymerization initiator, or may contain two or more kinds thereof. In a case where two or more kinds of thermal polymerization initiators are contained, the total amount thereof is preferably within the above-described range.

### <Base Generator>

The composition may include a base generator. Here, the base generator is a compound that is capable of generating a base under a physical or chemical action.

Examples of the preferred base generator include a thermal-base generator and a photobase generator.

In particular, in a case where the composition includes a heterocyclic ring-containing polymer precursor, the composition preferably includes a base generator. In a case where the composition contains a thermal-base generator, it is possible to, for example, accelerate the cyclization reaction of the precursor by heating, whereby the mechanical properties and chemical resistance of the cured substance are improved and for example, the performance as an interlayer insulating film for a re-distribution layer, included in a semiconductor package, is improved.

The base generator may be an ionic base generator or may be a nonionic base generator. Examples of the base that is generated from the base generator include a secondary amine and a tertiary amine.

The base generator is not particularly limited, and a publicly known base generator can be used. Examples of the publicly known base generator include a carbamoyloxime compound, a carbamoylhydroxylamine compound, a carbamic acid compound, a formamide compound, an acetamide compound, a carbamate compound, a benzylcarbamate compound, a nitrobenzylcarbamate compound, a sulfonamide compound, an imidazole derivative compound, an aminimide compound, a pyridine derivative compound, an α-aminoacetophenone derivative compound, a quaternary ammonium salt derivative compound, an iminium salt, a pyridinium salt, an α-lactone ring derivative compound, a phthalimide derivative compound, and an acyloxyimino compound.

Specific examples of the nonionic base generator include the compounds described in paragraphs 0249 to 0275 of WO2022/145355A. The above description is incorporated in the present specification.

Examples of the base generator include the following compounds; however, the base generator is not limited thereto.

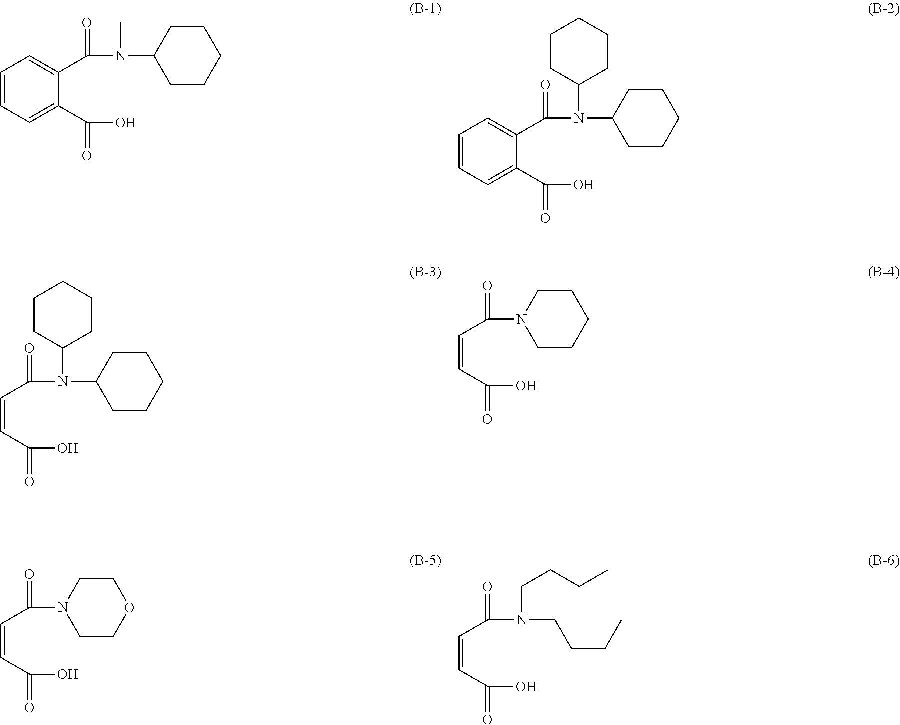 [SMILES: CN(C(=O)c1ccccc1C(=O)O)C1CCCCC1 ; O=C(O)c1ccccc1C(=O)N(C1CCCCC1)C1CCCCC1 ; O=C(O)/C=C\C(=O)N(C1CCCCC1)C1CCCCC1 ; O=C(O)/C=C\C(=O)N1CCCCC1 ; O=C(O)/C=C\C(=O)N1CCOCC1 ; CCCCN(CCCC)C(=O)/C=C\C(=O)O]

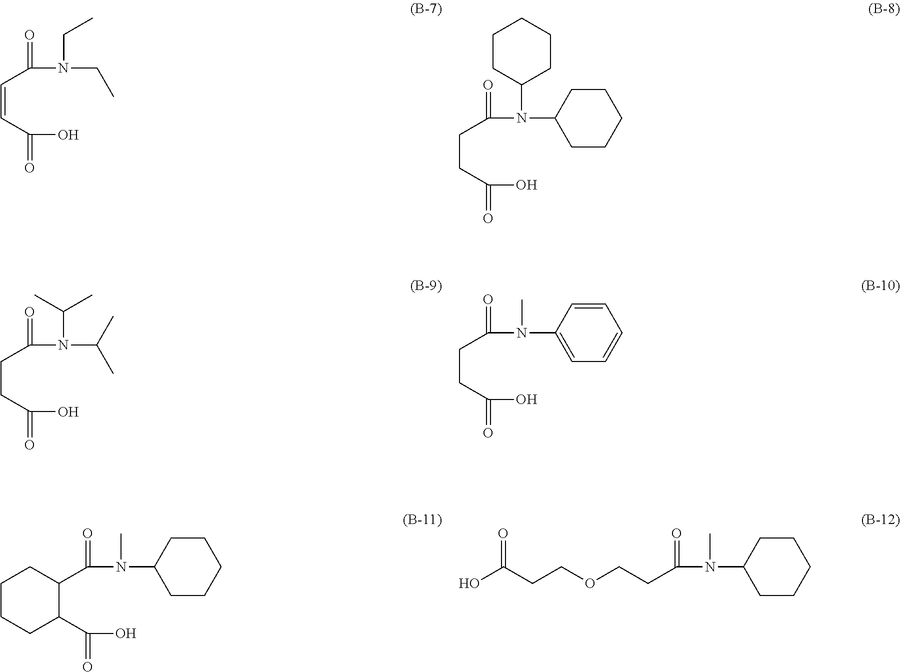 [SMILES: CCN(CC)C(=O)/C=C\C(=O)O ; O=C(O)CCC(=O)N(C1CCCCC1)C1CCCCC1 ; CC(C)N(C(=O)CCC(=O)O)C(C)C ; CN(C(=O)CCC(=O)O)c1ccccc1 ; CN(C(=O)C1CCCCC1C(=O)O)C1CCCCC1 ; CN(C(=O)CCOCCC(=O)O)C1CCCCC1]

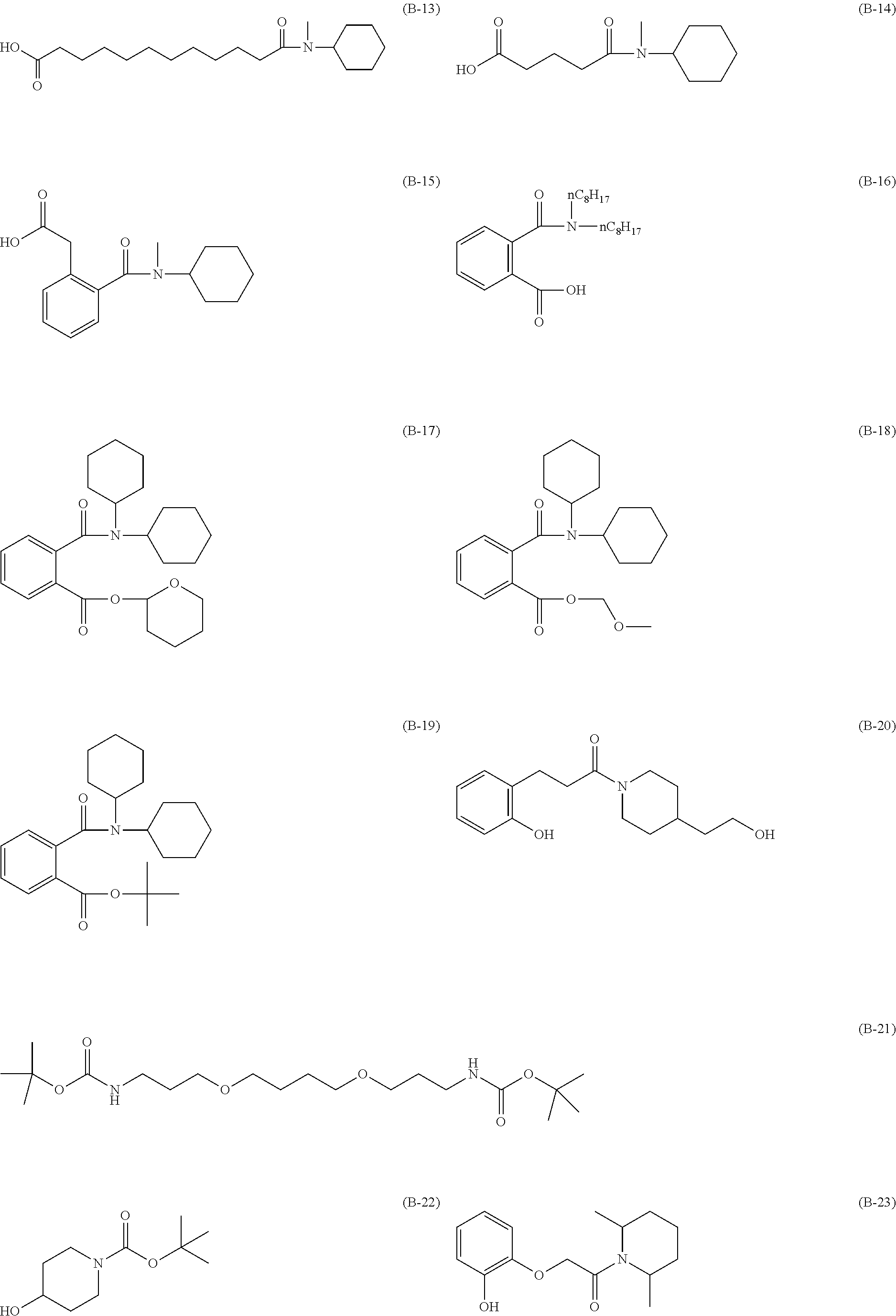

The molecular weight of the nonionic base generator is preferably 800 or less, more preferably 600 or less, and still more preferably 500 or less. The lower limit thereof is preferably 100 or more, more preferably 200 or more, and still more preferably 300 or more.

Examples of the specific preferred compound of the ionic base generator include the compounds described in paragraphs 0148 to 0163 of WO2018/038002A.

Specific examples of the ammonium salt include the following compounds; however, the ammonium salt is not limited thereto.

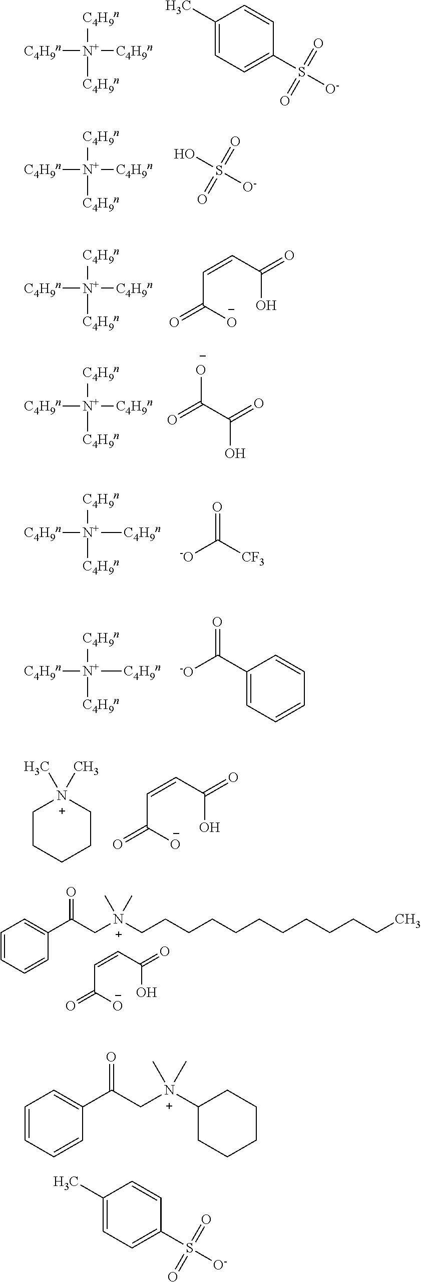

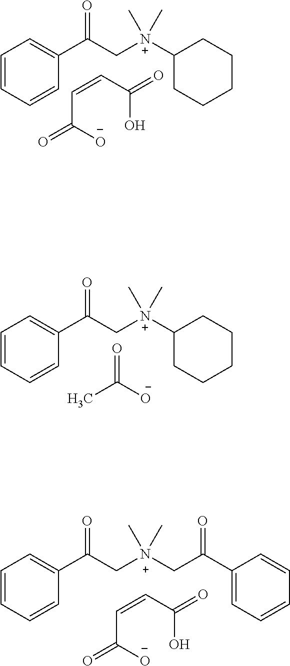

Specific examples of the iminium salt include the following compounds; however, the iminium salt is not limited thereto.

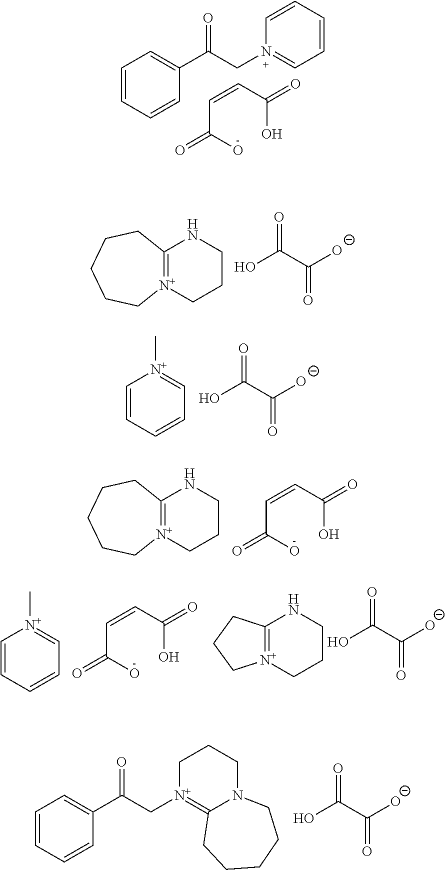

In addition, from the viewpoint of storage stability and generation of a base by deprotection during curing, the base generator is preferably an amine in which an amino group is protected by a t-butoxycarbonyl group.

Examples of the amine compound protected by a t-butoxycarbonyl group include ethanolamine, 3-amino-1-propanol, 1-amino-2-propanol, 2-amino-1-propanol, 4-amino-1-butanol, 2-amino-1-butanol, 1-amino-2-butanol, 3-amino-2,2-dimethyl-1-propanol, 4-amino-2-methyl-1-butanol, valinol, 3-amino-1,2-propanediol, 2-amino-1,3-propanediol, tyramine, norephedrine, 2-amino-1-phenyl-1,3-propanediol, 2-aminocyclohexanol, 4-aminocyclohexanol, 4-aminocyclohexanethanol, 4-(2-aminoethyl)cyclohexanol, N-methylethanolamine, 3-(methylamino)-1-propanol, 3-(isopropylamino)propanol, N-cyclohexylethanolamine, α-[2-(methylamino)ethyl]benzyl alcohol, diethanolamine, diisopropanolamine, 3-pyrrolidinol, 2-pyrrolidinomethanol, 4-hydroxypiperidine, 3-hydroxypiperidine, 4-hydroxy-4-phenylpiperidine, 4-(3-hydroxyphenyl)piperidine, 4-piperidinemethanol, 3-piperidinemethanol, 2-piperidinemethanol, 4-piperidinetanol, 2-piperidinetanol, 2-(4-piperidyl)-2-propanol, 1,4-butanol bis(3-aminopropyl)ether, 1,2-bis(2-aminoethoxy)ethane, 2,2′-oxybis(ethylamine), 1,14-diamino-3,6,9,12-tetraoxatetradecane, 1-aza-15-crown 5-ether, diethylene glycol bis(3-aminopropyl)ether, 1,11-diamino-3,6,9-trioxaundecane, or a compound in which an amino group of an amino acid and a derivative thereof is protected by a t-butoxycarbonyl group, but the present invention is not limited to these examples.

In a case where the composition includes a base generator, a content of the base generator is preferably 0.1 to 50 parts by mass with respect to 100 parts by mass of the resin in the composition. The lower limit thereof is more preferably 0.3 parts by mass or more and still more preferably 0.5 parts by mass or more. The upper limit thereof is more preferably 30 parts by mass or less, still more preferably 20 parts by mass or less, even still more preferably 10 parts by mass or less, even further still more preferably 5 parts by mass or less, and particularly preferably 4 parts by mass or less.

One kind or two or more kinds of base generators can be used. In a case where two or more kinds thereof are used, the total amount is preferably within the above-described range.

### <Solvent>

The composition preferably includes a solvent.

As the solvent, any publicly known solvent can be used. The solvent is preferably an organic solvent. Examples of the organic solvent include compounds such as esters, ethers, ketones, cyclic hydrocarbons, sulfoxides, amides, ureas, and alcohols.

Suitable examples of the esters include ethyl acetate, n-butyl acetate, isobutyl acetate, hexyl acetate, amyl formate, isoamyl acetate, butyl propionate, isopropyl butyrate, ethyl butyrate, butyl butyrate, methyl lactate, ethyl lactate, γ-butyrolactone, ε-caprolactone, δ-valerolactone, γ-valerolactone, alkyl alkyloxyacetate (for example, methyl alkyloxyacetate, ethyl alkyloxyacetate, and butyl alkyloxyacetate (for example, methyl methoxyacetate, ethyl methoxyacetate, butyl methoxyacetate, methyl ethoxyacetate, and ethyl ethoxyacetate)), 3-alkyloxypropionic acid alkyl esters (for example, methyl 3-alkyloxypropionate, and ethyl 3-alkyloxypropionate (for example, methyl 3-methoxypropionate, ethyl 3-methoxypropionate, methyl 3-ethoxypropionate, and ethyl 3-ethoxypropionate)), 2-alkyloxypropionic acid alkyl esters (for example, methyl 2-alkyloxypropionate, ethyl 2-alkyloxypropionate, and propyl 2-alkyloxypropionate (for example, methyl 2-methoxypropionate, ethyl 2-methoxypropionate, propyl 2-methoxypropionate, methyl 2-ethoxypropionate, and ethyl 2-ethoxypropionate)), methyl 2-alkyloxy-2-methylpropionate and ethyl 2-alkyloxy-2-methylpropionate (for example, methyl 2-methoxy-2-methylpropionate and ethyl 2-ethoxy-2-methylpropionate), methyl pyruvate, ethyl pyruvate, propyl pyruvate, methyl acetoacetate, ethyl acetoacetate, methyl 2-oxobutanoate, ethyl 2-oxobutanoate, ethyl hexanoate, ethyl heptanoate, dimethyl malonate, and diethyl malonate.

Suitable examples of ethers include ethylene glycol dimethyl ether, diethylene glycol dimethyl ether, diethylene glycol diethyl ether, diethylene glycol ethyl methyl ether, diethylene glycol butyl methyl ether, triethylene glycol dimethyl ether, tetraethylene glycol dimethyl ether, tetrahydrofuran, ethylene glycol monomethyl ether, ethylene glycol monoethyl ether, methyl cellosolve acetate, ethyl cellosolve acetate, diethylene glycol monomethyl ether, diethylene glycol monoethyl ether, diethylene glycol monobutyl ether, propylene glycol monomethyl ether, propylene glycol dimethyl ether, propylene glycol monomethyl ether acetate, propylene glycol monoethyl ether acetate, ethylene glycol monobutyl ether, ethylene glycol monobutyl ether acetate, propylene glycol monopropyl ether acetate, and dipropylene glycol dimethyl ether.

Suitable examples of the ketones include methyl ethyl ketone, cyclohexanone, cyclopentanone, 2-heptanone, 3-heptanone, 3-methylcyclohexanone, levoglucosenone, and dihydrolevoglucosenone.

Suitable examples of the cyclic hydrocarbon include aromatic hydrocarbons such as toluene, xylene, and anisole, and cyclic terpenes such as limonene.

Suitable examples of the sulfoxides include dimethyl sulfoxide.

Suitable examples of the amide include N-methyl-2-pyrrolidone, N-ethyl-2-pyrrolidone, N-cyclohexyl-2-pyrrolidone, N,N-dimethylacetamide, N,N-dimethylformamide, N,N-dimethylisobutylamide, 3-methoxy-N,N-dimethylpropionamide, 3-butoxy-N,N-dimethylpropionamide, N-formylmorpholine, and N-acetylmorpholine.

Suitable examples of the urea include N,N,N′,N′-tetramethylurea and 1,3-dimethyl-2-imidazolidinone.

Examples of the alcohols include methanol, ethanol, 1-propanol, 2-propanol, 1-butanol, 1-pentanol, 1-hexanol, benzyl alcohol, ethylene glycol monomethyl ether, 1-methoxy-2-propanol, 2-ethoxyethanol, diethylene glycol monoethyl ether, diethylene glycol monohexyl ether, triethylene glycol monomethyl ether, propylene glycol monoethyl ether, propylene glycol monomethyl ether, polyethylene glycol monomethyl ether, polypropylene glycol, tetraethylene glycol, ethylene glycol monobutyl ether, ethylene glycol monobenzyl ether, ethylene glycol monophenyl ether, methylphenyl carbinol, n-amyl alcohol, methylamyl alcohol, and diacetone alcohol.

From the viewpoint of improving the properties of a coated surface or the like, it is also preferable to mix two or more kinds of solvents.

In the present invention, one solvent selected from methyl 3-ethoxypropionate, ethyl 3-ethoxypropionate, ethyl cellosolve acetate, ethyl lactate, diethylene glycol dimethyl ether, butyl acetate, methyl 3-methoxypropionate, 2-heptanone, cyclohexanone, cyclopentanone, γ-butyrolactone, γ-valerolactone, 3-methoxy-N,N-dimethylpropionamide, toluene, dimethyl sulfoxide, ethyl carbitol acetate, butyl carbitol acetate, N-methyl-2-pyrrolidone, propylene glycol methyl ether, and propylene glycol methyl ether acetate, or a mixed solvent composed of two or more thereof is preferable, and it is more preferable that the solvent includes at least one solvent selected from γ-butyrolactone, dimethyl sulfoxide, and N-methyl-2-pyrrolidone.

A combined use of dimethyl sulfoxide and γ-butyrolactone, a combined use of dimethyl sulfoxide and γ-valerolactone, a combined use of 3-methoxy-N,N-dimethylpropionamide and γ-butyrolactone, a combined use of 3-methoxy-N,N-dimethylpropionamide and dimethyl sulfoxide, or, a combined use of N-methyl-2-pyrrolidone and ethyl lactate is particularly preferable. An aspect in which an amount of about 1% to 10% by mass of toluene with respect to the total mass of the solvent is further added to these combinedly used solvents is also one of the preferred aspects of the present invention.

In particular, from the viewpoint of the storage stability or the like of the composition, an aspect in which γ-valerolactone is included as the solvent is also one of the preferred aspects of the present invention. In such an aspect, the content of γ-valerolactone with respect to the total mass of the solvent is preferably 50% by mass or more, more preferably 60% by mass or more, and still more preferably 70% by mass or more. In addition, the upper limit of the above-described content is not particularly limited, and it may be 100% by mass.

The above-described content may be determined in consideration of the solubility of components such as the heterocyclic ring-containing polymer contained in the composition.

In addition, in a case where dimethyl sulfoxide and γ-valerolactone are used in combination, with respect to the total mass of the solvent, it is preferable to contain 60% to 90% by mass of γ-valerolactone and 10% to 40% by mass of dimethyl sulfoxide, it is more preferable to contain 70% to 90% by mass of γ-valerolactone and 10% to 30% by mass of dimethyl sulfoxide, and it is still more preferable to contain 75% to 85% by mass of γ-valerolactone and 15% to 25% by mass of dimethyl sulfoxide.

Regarding the content of the solvent, the amount of the solvent is such that, from the viewpoint of coatability, the concentration of the total solid contents of the composition is preferably 5% to 80% by mass, more preferably 5% to 75% by mass, still more preferably 10% to 70% by mass, and even still more preferably 20% to 70% by mass. The content of the solvent may be adjusted depending on the desired thickness of the coating film and the coating method. In a case where two or more kinds of solvents are contained, the total thereof is preferably within the above-described range.

### <Metal Adhesiveness Improving Agent>

From the viewpoint of improving adhesiveness to a metal material used for an electrode, wiring, or the like, the composition preferably includes a metal adhesiveness improving agent. Examples of the metal adhesiveness improving agent include a silane coupling agent having an alkoxysilyl group, an aluminum-based auxiliary adhesive agent, a titanium-based auxiliary adhesive agent, a compound having a sulfonamide structure and a compound having a thiourea structure, a phosphoric acid derivative compound, a β-ketoester compound, and an amino compound.

### [Silane Coupling Agent]

Examples of the silane coupling agent include the compounds described in paragraph 0316 of WO2021/112189A and the compounds described in paragraphs 0067 to 0078 of JP2018-173573A, the contents of which are incorporated in the present specification. In addition, it is also preferable to use two or more kinds of different silane coupling agents as described in paragraphs 0050 to 0058 of JP2011-128358A. It is also preferable to use the following compound as the silane coupling agent. In the following Formulae, Me represents a methyl group, and Et represents an ethyl group. In addition, examples of R shown below include a structure derived from a blocking agent in a blocked isocyanate group. The blocking agent may be selected depending on the desorption temperature; however, examples thereof include an alcohol compound, a phenol compound, a pyrazole compound, a triazole compound, a lactam compound, and an active methylene compound. It is preferably caprolactam or the like, for example, from the viewpoint of setting the desorption temperature to 160 °C to 180 °C Examples of the commercially available product of such a compound include X-12-1293 (manufactured by Shin-Etsu Chemical Co., Ltd.).

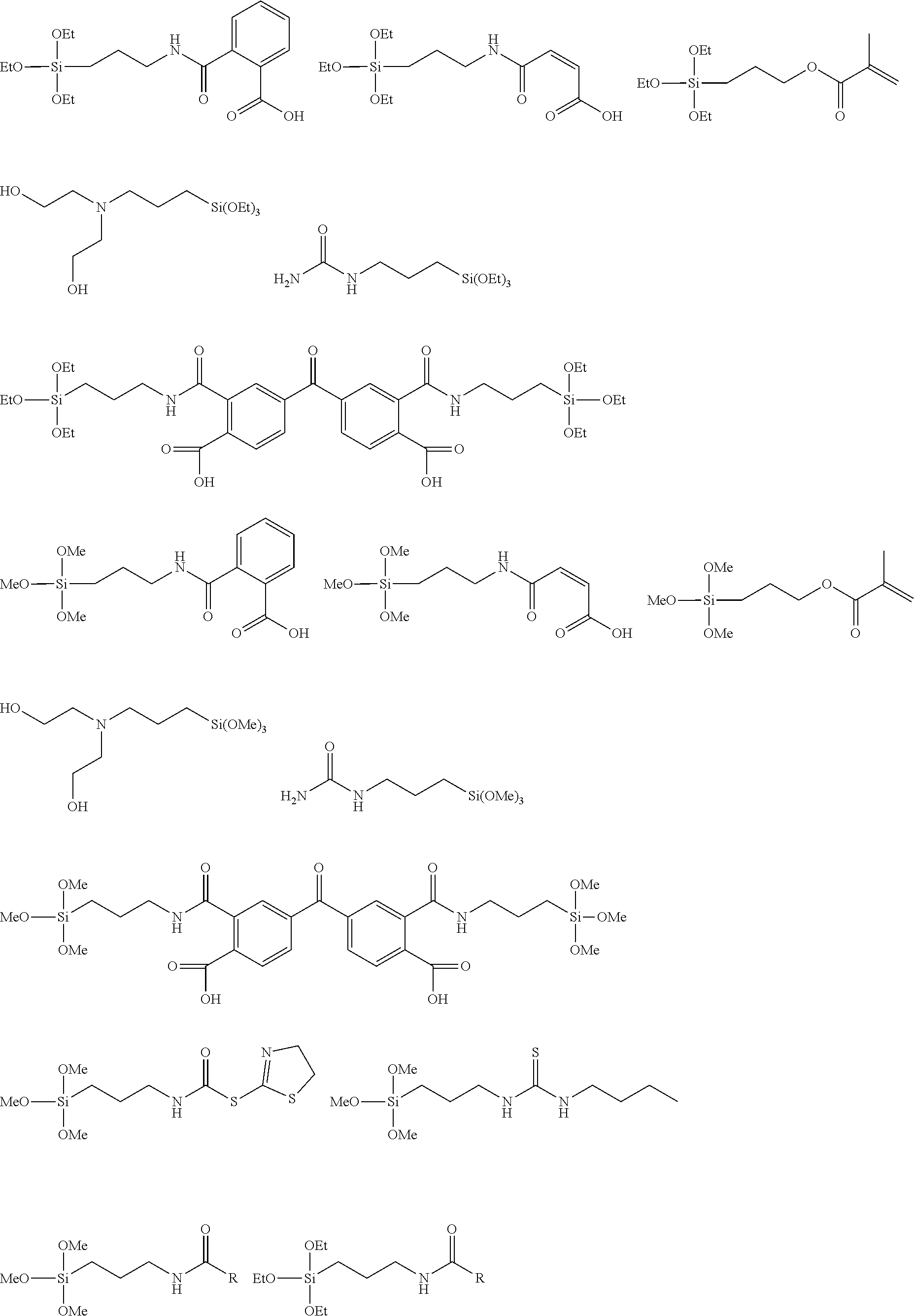

Examples of the other silane coupling agent include vinyltrimethoxysilane, vinyltriethoxysilane, 2-(3,4-epoxycyclohexyl)ethyltrimethoxysilane, 3-glycidoxypropylmethyldimethoxysilane, 3-glycidoxypropyltrimethoxysilane, 3-glycidoxypropylmethyldiethoxysilane, 3-glycidoxypropyltriethoxysilane, p-styryltrimethoxysilane, 3-methacryloxypropylmethyldimethoxysilane, 3-methacryloxypropyltrimethoxysilane, 3-methacryloxypropylmethyldiethoxysilane, 3-methacryloxypropyltriethoxysilane, 3-acryloxypropyltrimethoxysilane, N-2-(aminoethyl)-3-aminopropylmethyldimethoxysilane, N-2-(aminoethyl)-3-aminopropyltrimethoxysilane, 3-aminopropyltrimethoxysilane, 3-aminopropyltriethoxysilane, 3-triethoxysilyl-N-(1,3-dimethyl-butylidene)propylamine, N-phenyl-3-aminopropyltrimethoxysilane, tris-(trimethoxysilylpropyl)isocyanurate, 3-ureidopropyltrialkoxysilane, 3-mercaptopropylmethyldimethoxysilane, 3-mercaptopropyltrimethoxysilane, 3-isocyanatepropyltriethoxysilane, and 3-trimethoxysilylpropylsuccinic acid anhydride. These can be used alone or in a combination of two or more thereof.

In addition, an oligomer type compound having a plurality of alkoxysilyl groups can also be used as the silane coupling agent.

Examples of such an oligomer type compound include a compound containing a repeating unit represented by Formula (S-1).

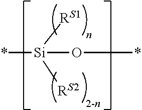

In Formula (S-1), R^{S1} represents a monovalent organic group, R^{S2} represents a hydrogen atom, a hydroxy group, or an alkoxy group, and n represents an integer of 0 to 2.

R^{S1} preferably has a structure including a polymerizable group. Examples of the polymerizable group include a group having an ethylenically unsaturated bond, an epoxy group, an oxetanyl group, a benzoxazolyl group, a blocked isocyanate group, and an amino group. Examples of the group having an ethylenically unsaturated bond include a vinyl group, an allyl group, an isoallyl group, a 2-methylallyl group, a group (for example, a vinylphenyl group) having an aromatic ring that is directly bonded to a vinyl group, and a (meth)acrylamide group, a (meth)acryloyloxy group, where a vinylphenyl group, a (meth)acrylamide group, or a (meth)acryloyloxy group is preferable, a vinylphenyl group or a (meth)acryloyloxy group is more preferable, and a (meth)acryloyloxy group is still more preferable.

R^{S2} is preferably an alkoxy group, and more preferably a methoxy group or an ethoxy group.

n represents an integer of 0 to 2, and it is preferably 1.

Here, structures of a plurality of repeating units represented by Formula (S-1) may be the same, where the plurality of repeating units are contained in the oligomer type compound.

Here, among a plurality of repeating units represented by Formula (S-1), which are contained in the oligomer type compound, it is preferable that at least one repeating unit has n of 1 or 2, it is more preferable that at least two repeating units have n of 1 or 2, and it is still more preferable that at least two repeating units have n of 1.

As such an oligomer type compound, a commercially available product can be used, and examples thereof include KR-513 (manufactured by Shin-Etsu Chemical Co., Ltd.).

### [Aluminum-Based Auxiliary Adhesive Agent]

Examples of the aluminum-based auxiliary adhesive agent include aluminum tris(ethyl acetoacetate), aluminum tris(acetyl acetate), and ethyl acetoacetate aluminum diisopropylate.

As another metal adhesiveness improving agent, the compounds described in paragraphs 0046 to 0049 of JP2014-186186A, and the sulfide-based compounds described in paragraphs 0032 to 0043 of JP2013-072935A can also be used, and the contents of which are incorporated in the present specification.

A content of the metal adhesiveness improving agent is preferably 0.01 to 30 parts by mass, more preferably 0.1 to 10 parts by mass, and still more preferably 0.5 to 5 parts by mass with respect to 100 parts by mass of the heterocyclic ring-containing polymer. In a case where the content is set to be equal to or higher than the above lower limit value, good adhesiveness between a pattern and a metal layer is exhibited, and in a case where the content is set to be equal to or lower than the above upper limit value, good heat resistance of the pattern and good mechanical characteristics are exhibited. Only one kind of metal adhesiveness improving agent may be used, or two or more kinds thereof may be used. In a case where two or more kinds thereof are used, the total content thereof is preferably within the above-described range.

### <Migration Suppressing Agent>

The composition preferably further includes a migration suppressing agent. For example, in a case where the composition is applied to a metal layer (or metal wiring) to form a film, it is possible to effectively suppress the migration of metal ions derived from the metal layer (or the metal wiring) into the film, in a case where a migration suppressing agent is contained.

The migration suppressing agent is not particularly limited; however, examples thereof include a compound having a heterocyclic ring (a pyrrole ring, a furan ring, a thiophene ring, an imidazole ring, an oxazole ring, a thiazole ring, a pyrazole ring, an isoxazole ring, an isothiazole ring, a tetrazole ring, a pyridine ring, a pyridazine ring, a pyrimidine ring, a pyrazine ring, a piperidine ring, a piperazine ring, a morpholine ring, a 2H-pyran ring and a 6H-pyran ring, or a triazine ring), a compound having thioureas and a sulfanyl group, a hindered phenol-based compound, a salicylic acid derivative-based compound, and a hydrazide derivative-based compound. In particular, it is possible to preferably use a triazole-based compound such as 1,2,4-triazole, benzotriazole, 3-amino-1,2,4-triazole, or 3,5-diamino-1,2,4-triazole, or a tetrazole-based compound such as 1H-tetrazole, 5-phenyltetrazole or 5-amino-1H-tetrazole.

As the migration suppressing agent, an ion trap agent that captures an anion such as a halogen ion can also be used.

The rust inhibitors described in paragraph 0094 of JP2013-015701A, the compounds described in paragraphs 0073 to 0076 of JP2009-283711A, the compounds described in paragraph 0052 of JP2011-059656A, the compounds described in paragraphs 0114, 0116, and 0118 of JP2012-194520A, the compounds described in paragraph 0166 of WO2015/199219A, or the like can be used as the other migration suppressing agents, the contents of which are incorporated in the present specification.

Specific examples of the migration suppressing agent include the following compounds.

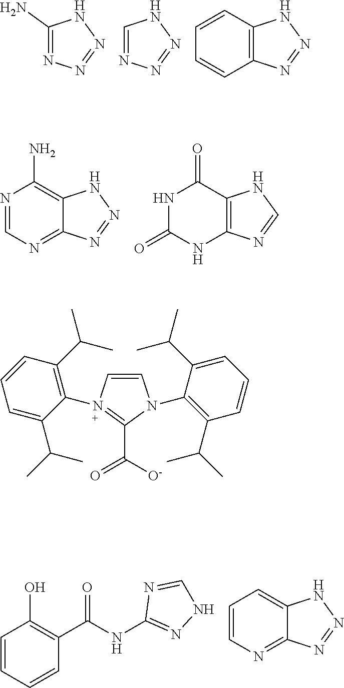

In a case where the composition contains the migration suppressing agent, the content of the migration suppressing agent is preferably 0.01% to 5.0% by mass, more preferably 0.05% to 2.0% by mass, and still more preferably 0.1% to 1.0% by mass, with respect to the total solid content of the composition.

Only one kind of migration suppressing agent may be used alone, or two or more kinds thereof may be used. In a case where two or more kinds of migration suppressing agents are used, the total thereof is preferably within the above-described range.

### <Polymerization Inhibitor>

The composition preferably includes a polymerization inhibitor. Examples of the polymerization inhibitor include a phenol-based compound, a quinone-based compound, an amino-based compound, an N-oxyl-free radical-based compound, a nitro-based compound, a nitroso-based compound, a heteroaromatic ring-based compound, and a metal compound.

Specific examples of the compound of the polymerization inhibitor include the compounds described in paragraph 0310 of WO2021/112189A, p-hydroquinone, o-hydroquinone, a 4-hydroxy-2,2,6,6-tetramethylpiperidine-1-oxyl free radical, phenoxazine, and 1,4,4-trimethyl-2,3-diazabicyclo[3.2.2]nona-2-en-N,N-dioxide. The content thereof is incorporated in the present specification.

In a case where the composition has a polymerization inhibitor, a content of the polymerization inhibitor is preferably 0.01 to 20% by mass, more preferably 0.02 to 15% by mass, and still more preferably 0.05 to 10% by mass with respect to the total solid content of the composition.

Only one kind of polymerization inhibitor may be used, or two or more kinds thereof may be used. In a case where two or more kinds of polymerization inhibitors are used, the total thereof is preferably within the above-described range.

### [Urea Compound, Carbodiimide Compound, and Isourea Compound]

From the viewpoint of breaking elongation and adhesiveness with a metal or a resin layer, the composition may contain at least one compound (hereinafter, also referred to as “urea compound and the like”) selected from the group consisting of a compound having a urea bond (urea compound), a compound having a carbodiimide structure (carbodiimide compound), and a compound having an isourea bond (isourea compound).

Among these, the composition preferably further includes a compound having a urea bond.

The urea compound or the like described here does not include the above-described polymerizable compound and the compound corresponding to the silane coupling agent.

Examples of the urea compound include compounds described in paragraphs 0334 to 0339 of WO2022/070730A.

Specific examples of the urea compound or the like include dicyclohexylurea, diisopropylurea, dicyclohexylcarbodiimide, diisopropylcarbodiimide, dicyclohexylisourea, and diisopropylisourea, which are not limited thereto.

A total content of the urea compound or the like is preferably 0.1 to 10.0 parts by mass, more preferably 0.5 to 8.0 parts by mass, and still more preferably 1.0 to 6.0 parts by mass with respect to 100 parts by mass of the heterocyclic ring-containing polymer.

One kind of urea compound or the like may be used alone, or two or more kinds thereof may be used in combination. In a case where two or more kinds of bases are used in combination in the base-containing treatment liquid, it is preferable that the total content thereof is within the above-described range.

### <Light Absorbing Agent>

The composition preferably includes a compound (light absorbing agent) in which the absorbance at the exposure wavelength is reduced by exposure.

Examples of the light absorbing agent include compounds described in paragraphs 0159 to 0183 of WO2022/202647A and compounds described in paragraphs 0088 to 0108 of JP2019-206689A. The content thereof is incorporated in the present specification.

In addition, an aspect in which a photochromic compound is included as the light absorbing agent is also one of the preferred aspects of the present invention. The photochromic compound refers to a compound in which the absorption spectrum is changed by a change in the geometric structure of the molecule by absorbing light.

Specific examples of the photochromic compound are shown below, but the present invention is not limited thereto.

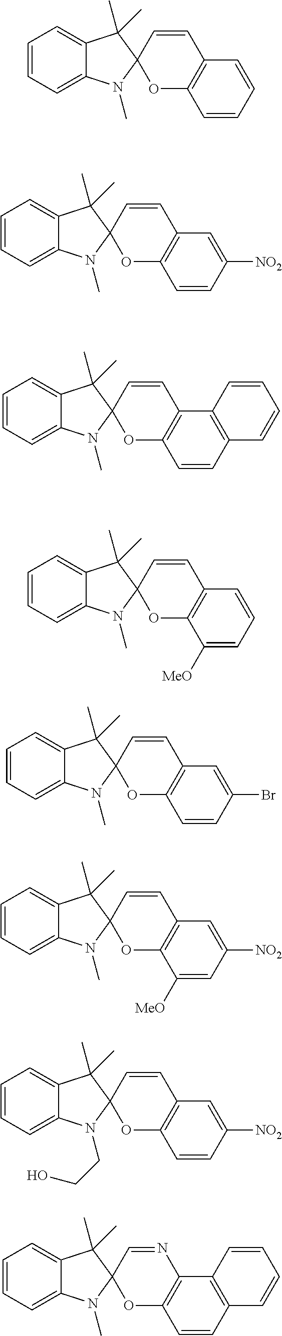

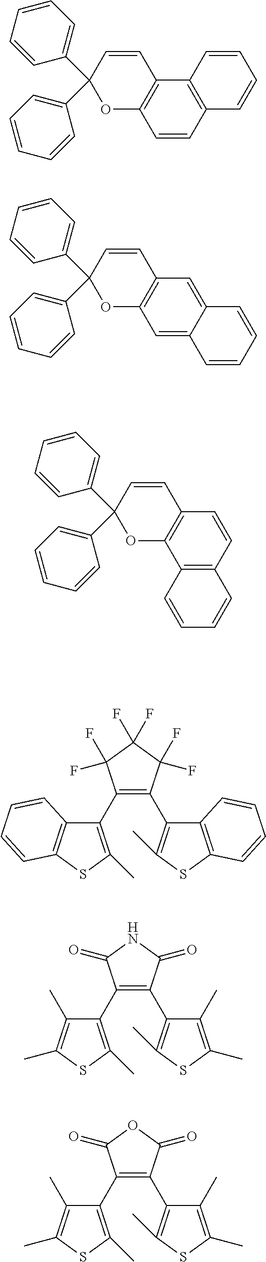

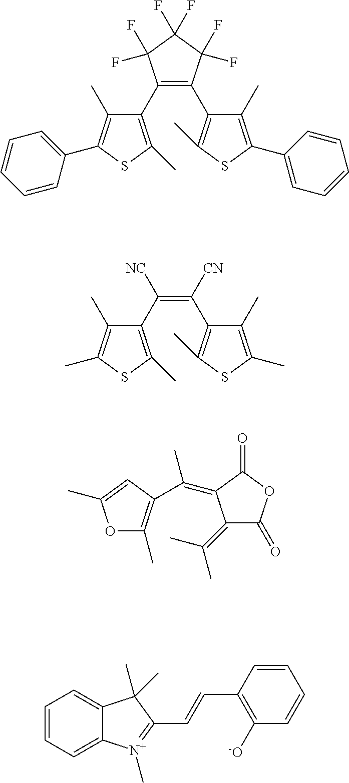

The content of the light absorbing agent with respect to the total solid content of the composition is not particularly limited, but is preferably 0.1% to 20% by mass, more preferably 0.5% to 10% by mass, and still more preferably 1% to 5% by mass.

### <Other Additives>

The composition may contain various additives as necessary, for example, a surfactant, a higher fatty acid derivative, a thermal polymerization initiator, inorganic particles, an ultraviolet absorbing agent, an organic titanium compounds, an antioxidant, a photoacid generator, an aggregation inhibitor, a phenol-based compound, another polymer compound, a plasticizer, and other auxiliary agents (for example, an anti-foaming agent, and a flame retardant) within the scope in which the effect of the present invention is obtained. By appropriately containing these components, properties such as film properties can be adjusted. The details of the components can be found in, for example, paragraph “0183” and subsequent paragraphs of JP2012-003225A (corresponding to paragraph 0237 of US2013/0034812A) and paragraphs 0101 to 0104 and 0107 to 0109 of JP2008-250074A, the contents of which are incorporated in the present specification. In a case of blending these additives, the total content thereof is preferably 3% by mass or less of the solid content of the composition.

### <Properties of Composition>

The viscosity of the composition can be adjusted by the concentration of the solid content of the composition. From the viewpoint of the coating film thickness, it is preferably 1,000 mm²/s to 12,000 mm²/s, more preferably 2,000 mm²/s to 10,000 mm²/s, and still more preferably 2,500 mm²/s to 8,000 mm²/s. Within the above range, it is easy to obtain a coating film having high uniformity. In a case of being 1,000 mm²/s or more, it is easy to carry out coating at a film thickness to be required as, for example, an insulating film for re-distribution of a wiring line, and in a case of being 12,000 mm²/s or less, a coating film having an excellent coating surface shape is obtained.

### <Restriction on Components of Composition>

The moisture content of the resin composition according to the embodiment of the present invention is preferably less than 2.0% by mass, more preferably less than 1.5% by mass, and still more preferably less than 1.0% by mass. In a case of being less than 2.0%, the storage stability of the composition is improved.

Examples of the method of maintaining the moisture content include adjusting the humidity under storage conditions and reducing the void ratio of the storage container during storage.

From the viewpoint of insulating properties, the metal content of the composition is preferably less than 5 parts per million (ppm) by mass, more preferably less than 1 ppm by mass, and still more preferably less than 0.5 ppm by mass. Examples of the metal include sodium, potassium, magnesium, calcium, iron, copper chromium, and nickel, however, a metal contained as a complex of an organic compound and a metal is excluded. In a case where a plurality of metals are contained, the total of these metals is preferably within the above-described range.

In addition, examples of a method of reducing metal impurities unintentionally contained in the composition include a method of selecting a raw material having a low metal content as a raw material constituting the composition, a method of filtering the raw material constituting the composition, and a method of distilling the composition in a condition in which contamination is suppressed as much as possible by lining the inside of the apparatus with polytetrafluoroethylene or the like.

In the composition, in a case of considering the use application as a semiconductor material, the content of halogen atoms is preferably less than 500 ppm by mass, more preferably less than 300 ppm by mass, and still more preferably less than 200 ppm by mass, from the viewpoint of wire corrosiveness. Among these, in a case of being present in a halogen ion state, the content is preferably less than 5 ppm by mass, more preferably less than 1 ppm by mass, and still more preferably less than 0.5 ppm by mass. Examples of the halogen atom include a chlorine atom and a bromine atom. It is preferable that the total content of the chlorine atom and the bromine atom, or the total content of the chlorine ion and the bromine ion is within the above-described range.

Preferred examples of the method of adjusting the content of halogen atoms include ion exchange treatment.

As a storage container of the composition, a storage container known in the related art can be used. As the storage container, for the purpose of suppressing impurities from being mixed into a raw material or a composition, a multilayer bottle having a container inner wall made of six layers of six kinds of resins or a bottle having a seven-layer structure of six kinds of resins is also preferably used. Examples of such a container include the container described in JP2015-123351A.

### <Preparation of Composition>

The composition can be prepared by mixing the above-described components. The mixing method is not particularly limited, and mixing can be carried out by methods publicly known in the related art.

Examples of the mixing method include mixing with a stirring blade, mixing with a ball mill, and mixing by rotating a tank.

The temperature during the mixing is preferably 10 °C to 30 °C, and more preferably 15 °C to 25 °C.

It is preferable to perform filtration using a filter in order to remove foreign substances such as dust and fine particles in the composition. The filter pore diameter is, for example, preferably 5 μm or less, more preferably 1 μm or less, still more preferably 0.5 μm or less, and even still more preferably 0.1 μm or less. The material of the filter is preferably polytetrafluoroethylene, polyethylene, or nylon. In a case where the material of the filter is polyethylene, it is more preferable to use high density polyethylene (HDPE). As the filter, a filter which has been washed with an organic solvent in advance may be used. In the filtration step using the filter, a plurality of kinds of filters may be connected in series or in parallel and used. In a case where a plurality of kinds of filters are used, filters having different pore diameters or different materials may be used in combination. Examples of the connection aspect include an aspect in which an HDPE filter having a pore diameter of 1 μm is connected in series as the first stage and an HDPE filter having a pore diameter of 0.2 μm is connected in series as the second stage. In addition, various materials may be filtered a plurality of times. In a case of being filtered a plurality of times, circulation filtration may be used. In addition, filtration may be carried out under pressure. In a case of carrying out pressurization to carry out filtration, the pressure for pressurization is, for example, preferably 0.01 MPa or more and 1.0 MPa or less, more preferably 0.03 MPa or more and 0.9 MPa or less, still more preferably 0.05 MPa or more and 0.7 MPa or less, and even still more preferably 0.05 MPa or more and 0.5 MPa or less.

In addition to filtration using a filter, impurity removal treatment using an adsorbing material may be carried out. The filtration using a filter and the impurity removal treatment using an adsorbing material may be combined. As the adsorbing material, a publicly known adsorbing material can be used. Examples thereof include an inorganic adsorbing material such as silica gel and zeolite and an organic adsorbing material such as activated carbon.

After filtration using a filter, a step of placing a bottle filled with the composition under reduced pressure to carry out degassing may be provided.

### EXAMPLES

Hereinafter, the present invention will be described in detail using examples. Materials, using amounts, proportions, treatment details, treatment content, and the like shown in the following examples can be appropriately changed without departing from the gist of the present invention. Accordingly, the scope of the present invention is not limited to the following specific examples. Unless otherwise specified, “parts” and “%” are based on mass.

### <Synthesis of Resin>

### Synthesis Example: Synthesis of Polymer 1

20.80 g (40 mmol) of 4,4′-(4,4′-isopropylidenediphenoxy)diphtalic acid anhydride was dissolved in 70 g of N-methylpyrrolidone (NMP). Subsequently, 3.81 g (17.6 mmol) of 3,3′-dihydroxybenzidine and 3.74 g (17.6 mmol) of 2,2′-dimethylbenzidine were dissolved in 50 g of NMP, and the solution was added dropwise thereto over 1 hour at a temperature of 10 °C to 25 °C, stirred at 25 °C for 30 minutes, 10 g of toluene was added thereto, the mixture was reacted at 200 °C for 4 hours while flowing nitrogen, and cooled to 25 °C. Subsequently, 15.3 g (50 mmol) of 4-(chloromethyl)styrene, 16.6 g (120 mmol) of potassium carbonate, 1.66 g (12 mmol) of potassium iodide, and 0.08 g of 2,2,6,6-tetramethylpiperidine 1-oxide free radical were added thereto, the mixture was reacted at 95 °C for 15 hours, cooled to 25 °C, and diluted with 120 g of tetrahydrofuran. Subsequently, the reaction solution was added dropwise to a mixed solution of 1.8 L of methanol and 0.6 L of water, and the mixture was stirred for 15 minutes and a polyimide resin was filtered. Next, the resin was subjected to reslurrying with 1 L of water, filtered, reslurried again with 1 L of methanol, filtered, and dried at 40 °C for 8 hours under reduced pressure. Subsequently, the resin dried as described above was dissolved in 250 g of tetrahydrofuran, 40 g of an ion exchange resin (MB-1: manufactured by ORGANO CORPORATION) was added thereto, the mixture was stirred for 4 hours, the ion exchange resin was filtered and removed, and then the polyimide resin was precipitated in 2 L of methanol and stirred for 15 minutes. The polyimide resin was filtered to be acquired, and dried at 45 °C for 1 day under reduced pressure to obtain a polymer 1. The polymer 1 is a resin having a repeating unit represented by the following formula. The subscript in parentheses of the following repeating unit represents content molar ratios of each repeating unit. The structure of the repeating unit was determined from a ¹H-NMR spectrum. The weight-average molecular weight of the polymer 1 was 25,000, the number-average molecular weight was 10,500, and the imidization rate was 99% or more.

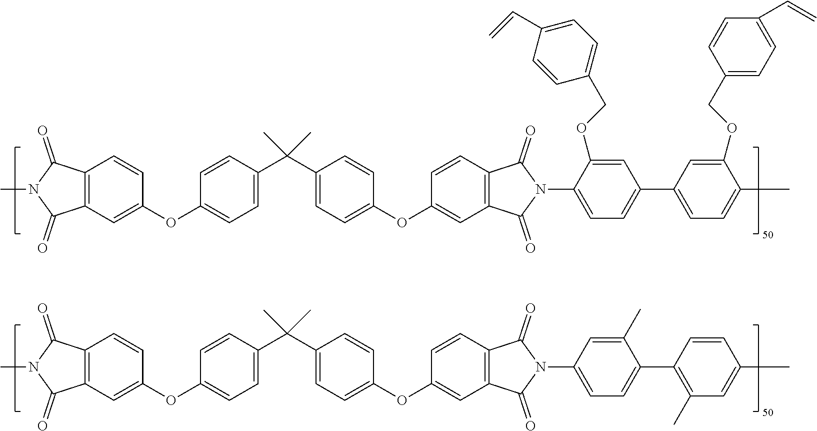

### Synthesis Example: Synthesis of Polymer 2

### —Synthesis of Diamine 2a for Polymer 2 Synthesis—

375 mL of dimethylformamide was mixed with 48.65 g (225 mmol) of 3,3′-dihydroxybenzidine in a flask. 98.21 g (450 millimoles) of di-t-butyl carbonate was added dropwise under ice cooling. Stirring was carried out at a temperature of 60 °C for 5 hours after completion of the dropwise addition. After the completion of the reaction, the mixture was cooled to room temperature, 35 mg of 2,2,6,6-tetramethylpiperidine 1-oxyl free radical, 68.68 g (450 mmol) of p-chloromethylstyrene, 74.63 g (540 mmol) of potassium carbonate, and 8.96 g (54.0 mmol) of potassium iodide were added thereto, and the mixture was stirred at a temperature of 60 °C for 3 hours. After completion of the reaction, filtration was carried out by a suction filtration operation, and the filtrate was added dropwise to 500 mL of water. Since white crystals were precipitated, the precipitated solid was collected by suction filtration. The obtained white solid was recrystallized and purified at 60 °C using 1000 mL of acetone. 125 g (yield: 85.6%) of the following intermediate 2b was obtained.

The structure of 2b is shown below. The following structure was confirmed from the ¹H-NMR spectrum.

¹H-NMR (BRUKER, AVANCE NEO 400): δ(ppm, DMSO-d6) 8.04-7.94 (s, 2H), 7.75-7.64 (d, 2H), 7.56-7.42 (m, 8H), 7.27-7.20 (d, 2H), 7.19-7.12 (d, 2H), 6.79-6.64 (2H), 5.89-5.77 (2H), 5.30-5.15 (6H), 1.49-1.43 (s, 18H)

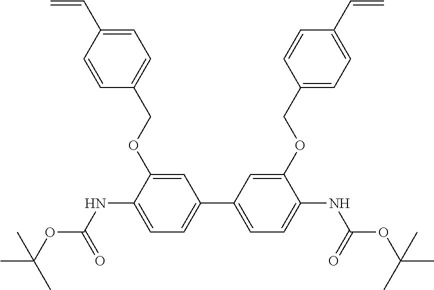 [SMILES: C=Cc1ccc(COc2cc(-c3ccc(NC(=O)OC(C)(C)C)c(OCc4ccc(C=C)cc4)c3)ccc2NC(=O)OC(C)(C)C)cc1]

75.0 g (115.6 millimoles) of 2b and 500 mL of methylene chloride were mixed in a 1 L flask. 131.8 g (1156 mmol) of trifluoroacetic acid was added thereto at room temperature, and the mixture was stirred at a temperature of 40 °C for 5 hours. After completion of the reaction, 250 mL of methanol and then 117.0 g (1156 mmol) of triethylamine were added dropwise under ice cooling. Since pale yellow crystals were precipitated, the precipitated solid was collected by suction filtration. Suspension washing was carried out with 750 mL of methanol to obtain 40.5 g (yield: 73%) of (2a). The structure of 2a is shown below. The following structure was confirmed from the ¹H-NMR spectrum.

¹H-NMR (BRUKER, AVANCE NEO 400): δ(ppm, DMSO-d6) 7.53-7.45 (s, 8H), 7.05-6.98 (d, 2H), 6.92-6.85 (d, 2H), 6.79-6.63 (4H), 5.89-5.78 (d, 2H), 5.29-5.22 (d, 2H), 5.20-5.13 (s, 4H), 4.92-4.64 (4H)

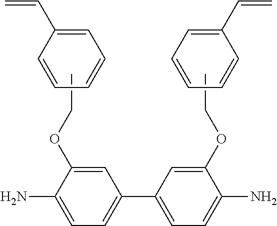

### —Synthesis of Polymer 2 —

30.0 g (57.64 mmol) of 4,4′-(4,4′-isopropylidenediphenoxy)diphtalic acid anhydride and 0.08 g of 2,2,6,6-tetramethylpiperidine 1-oxyl free radical were dissolved in 120 g of N-methylpyrrolidone (NMP) to obtain a solution. Subsequently, 5.50 g (25.9 millimoles) of 2,2′-dimethylbenzidine and 11.62 g (25.9 millimoles) of 2a were dissolved in 100 g of NMP, and the solution was added dropwise to the above-described solution at a temperature of 0 °C to 10 °C over 1 hour, and stirred at 25 °C for 60 minutes, and then 18.2 g of pyridine and 14.7 g of acetic anhydride were added thereto, and the mixture was reacted at 80 °C for 4 hours. After completion of the reaction, the mixture was cooled to 25 °C and diluted with 200 g of tetrahydrofuran. Subsequently, the reaction solution was added dropwise to a mixed solution of 2.0 L of methanol and 0.5 L of water, and the mixture was stirred for 15 minutes and a polyimide resin was filtered. Next, the resin was subjected to reslurrying with 1 L of water, filtered, reslurried again with 1 L of methanol, filtered, and dried at 40 °C for 10 hours under reduced pressure. Subsequently, the resin dried as described above was dissolved in 250 g of tetrahydrofuran, 40 g of an ion exchange resin (MB-1: manufactured by ORGANO CORPORATION) was added thereto, the mixture was stirred for 4 hours, the ion exchange resin was filtered and removed, and then the polyimide resin was precipitated in 2 L of methanol and stirred for 15 minutes. The polyimide resin was filtered to be acquired, and dried at 45 °C for 1 day under reduced pressure to obtain a polymer 2. The polymer 2 is a resin having a repeating unit represented by the following formula. The subscript in parentheses of the following repeating unit represents content molar ratios of each repeating unit. The weight-average molecular weight of the polymer 2 was 25,000, the number-average molecular weight was 12,500, and the imidization rate was 99% or more. The structure of the repeating unit was determined from a ¹H-NMR spectrum.

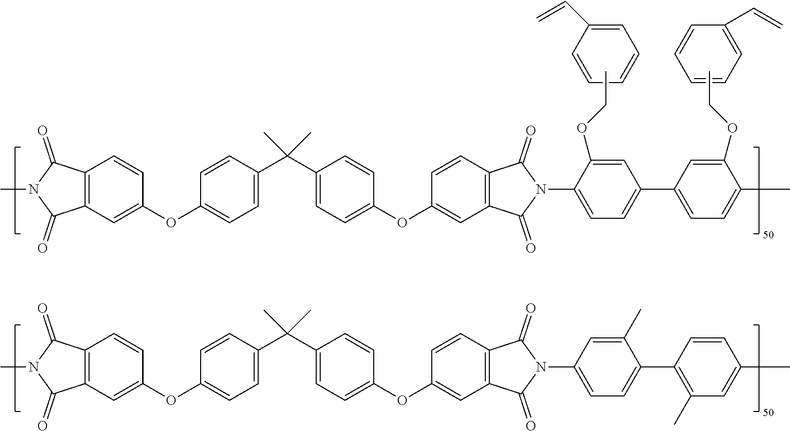

### Synthesis Example: Synthesis of Polymers 5 to 7

Polymers 5 to 7 were synthesized by the same method as in the polymer 2, except that the raw materials used were appropriately changed.

Polymers 5 to 7 are resins having a repeating unit represented by the following formula, respectively. The structure of each repeating unit was determined from a ¹H-NMR spectrum. In the following structures, the subscript of the parentheses represents the molar ratio of each structure. The weight-average molecular weight, the number-average molecular weight, and the imidization rate of these resins are described in the table below.

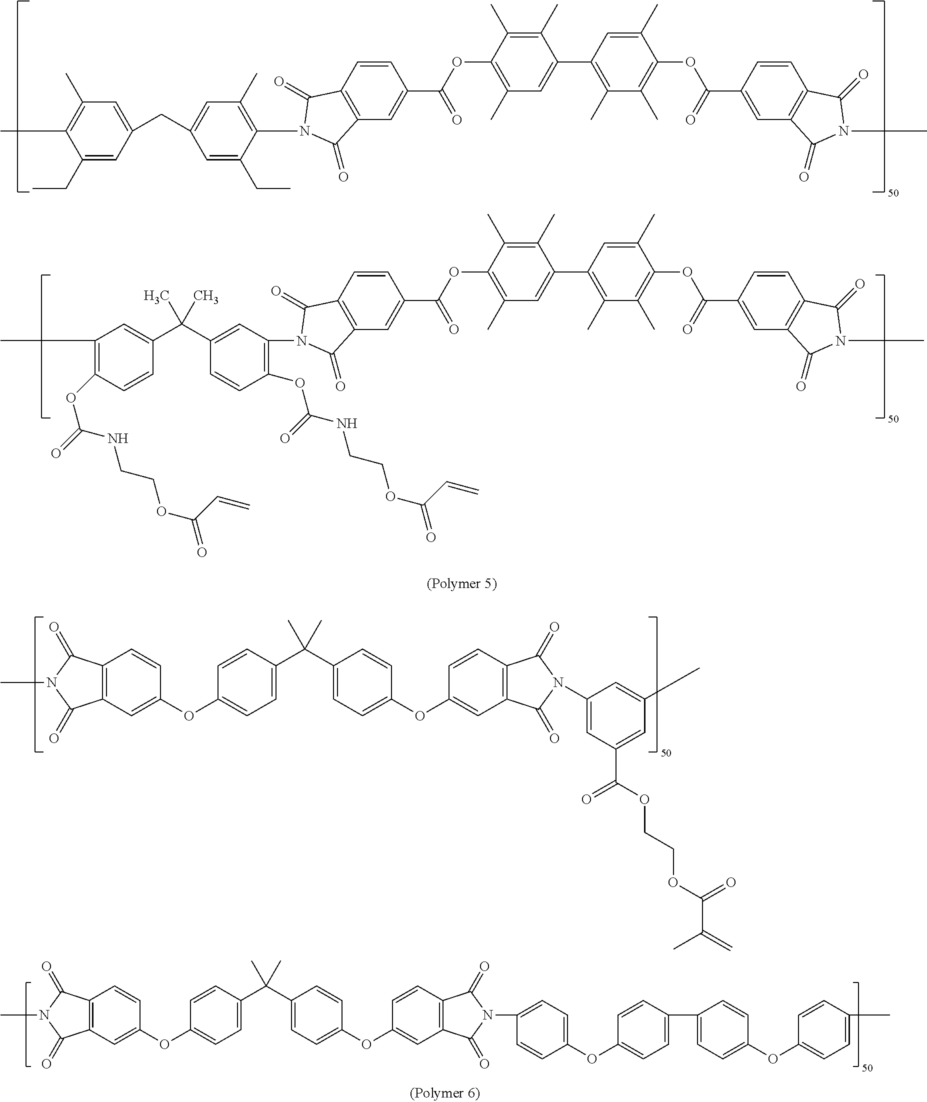

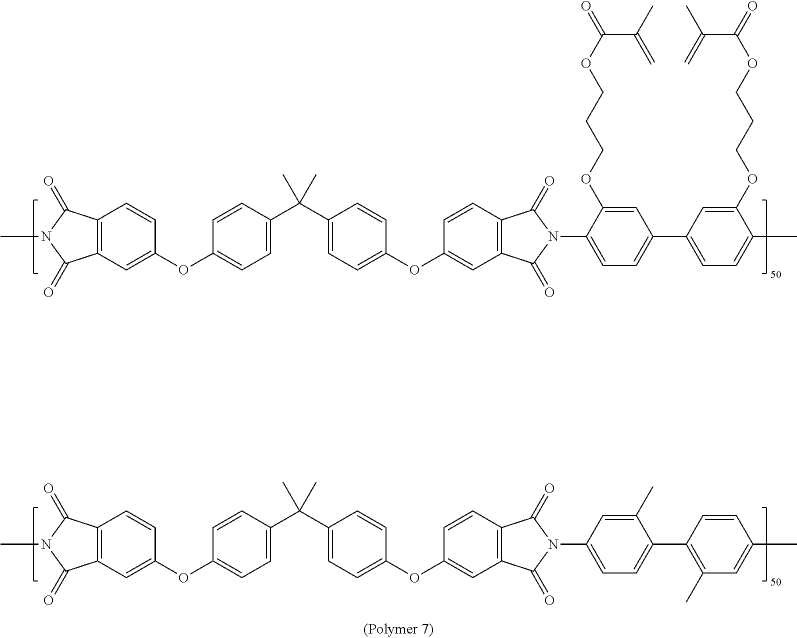

TABLE 1

| | Weight-average | Number-average | |
|---|---|---|---|
| | molecular | molecular | Imidization |
| Resin | weight (Mw) | weight (Mn) | rate (%) |
| Polymer 5 | 25,000 | 10,200 | 99% or more |
| Polymer 6 | 25,000 | 12,000 | 99% or more |
| Polymer 7 | 25,000 | 11,500 | 99% or more |

### Synthesis Example: Synthesis of Polymer 3

10.4 g (47.6 millimoles) of pyromellitic acid anhydride, 10.6 g (20.4 millimoles) of 4,4′-(4,4′-isopropylidenediphenoxy)bis(phthalic acid anhydride), 17.8 g (137 millimoles) of 2-hydroxyethyl methacrylate, 0.05 g of hydroquinone, 22.8 g (289 millimoles) of pyridine, and 75 g of diglyme were mixed and stirred at a temperature of 60 °C for 5 hours to produce a diester between each of pyromellitic acid anhydride and 4,4′-(4,4″-isopropylidenediphenoxy)bis(phthalic acid anhydride), and 2-hydroxyethyl methacrylate. Next, the mixture was cooled to −20 °C, 17.70 g (141 millimoles) of thionyl chloride was subsequently added dropwise over 90 minutes, and stirring was carried out for 2 hours to obtain a white precipitate of pyridinium hydrochloride.

Next, a solution obtained by dissolving 19.3 g (60.5 millimoles) of 4,4′-diamino-2,2′-bis(trifluoromethyl)biphenyl in 100 mL of N-methyl-2-pyrrolidone (NMP) was added dropwise thereto over 2 hours. Next, 10.0 g (217 millimoles) of ethanol was added, and the mixture was stirred for 2 hours. Next, a polyimide precursor was precipitated in 4 L of water, and the water-polyimide precursor mixture was stirred at a speed of 500 rpm for 15 minutes. The polyimide precursor was filtered to be acquired, and stirred again in 4 L of water for 30 minutes and filtered again. Next, the obtained polyimide precursor was dried at 45 °C for 2 days under reduced pressure to obtain a polyimide precursor (polymer 3). The weight-average molecular weight (Mw) of the obtained polyimide precursor (polymer 3) was 25,000, and the number-average molecular weight (Mn) was 10,000. It is presumed that the polyimide precursor (polymer 3) has a structure including two repeating units represented by the following formula (polymer 3). The subscript in parentheses of the following repeating unit represents content molar ratios of each repeating unit. The weight-average molecular weight of the polymer 3 was 25,000, the number-average molecular weight was 10,000, and the imidization rate was less than 5%.

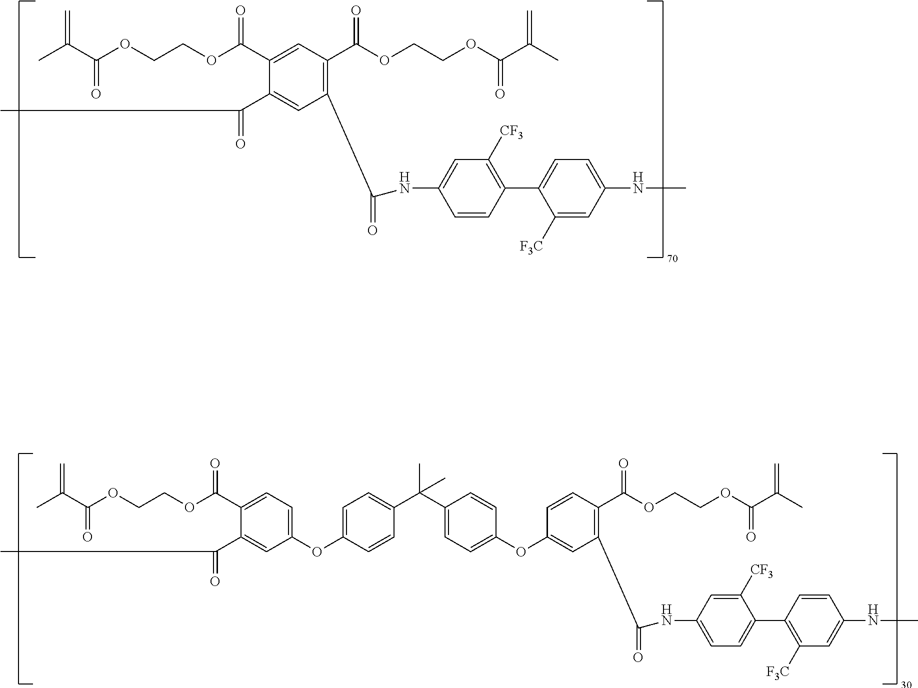

### Synthesis Example: Synthesis of Polymer 4

7.43 g (34.0 millimoles) of pyromellitic acid anhydride, 17.7 g (34.0 millimoles) of 4,4′-(4,4′-isopropylidenediphenoxy)bis(phthalic acid anhydride), 17.8 g (137 millimoles) of 2-hydroxyethyl methacrylate, 0.05 g of hydroquinone, 22.8 g (289 millimoles) of pyridine, and 75 g of diglyme were mixed and stirred at a temperature of 60 °C for 5 hours to produce a diester between each of pyromellitic acid anhydride and 4,4′-(4,4″-isopropylidenediphenoxy)bis(phthalic acid anhydride), and 2-hydroxyethyl methacrylate. Next, the mixture was cooled to −20 °C, 17.70 g (141 millimoles) of thionyl chloride was subsequently added dropwise over 90 minutes, and stirring was carried out for 2 hours to obtain a white precipitate of pyridinium hydrochloride.

Next, 12.7 g (59.8 millimoles) of 2,2′-dimethylbenzidine dissolved in 100 mL of NMP (N-methyl-2-pyrrolidone) was added dropwise thereto over 2 hours. Next, 10.0 g (217 millimoles) of ethanol was added, and the mixture was stirred for 2 hours. Next, a polyimide precursor was precipitated in 4 L of water, and the water-polyimide precursor mixture was stirred at a speed of 500 rpm for 15 minutes. The polyimide precursor was filtered to be acquired, and stirred again in 4 L of water for 30 minutes and filtered again. Next, the obtained polyimide precursor was dried at 45 °C for 2 days under reduced pressure to obtain a polyimide precursor (polymer 4). The weight-average molecular weight (Mw) of the obtained polyimide precursor (polymer 4) was 25,000, and the number-average molecular weight (Mn) was 9,950. It is presumed that the polyimide precursor (polymer 4) has a structure including two repeating units represented by the following formula (polymer 4). The subscript in parentheses of the following repeating unit represents content molar ratios of each repeating unit. The weight-average molecular weight of the polymer 4 was 25,000, the number-average molecular weight was 9,950, and the imidization rate was less than 5%.

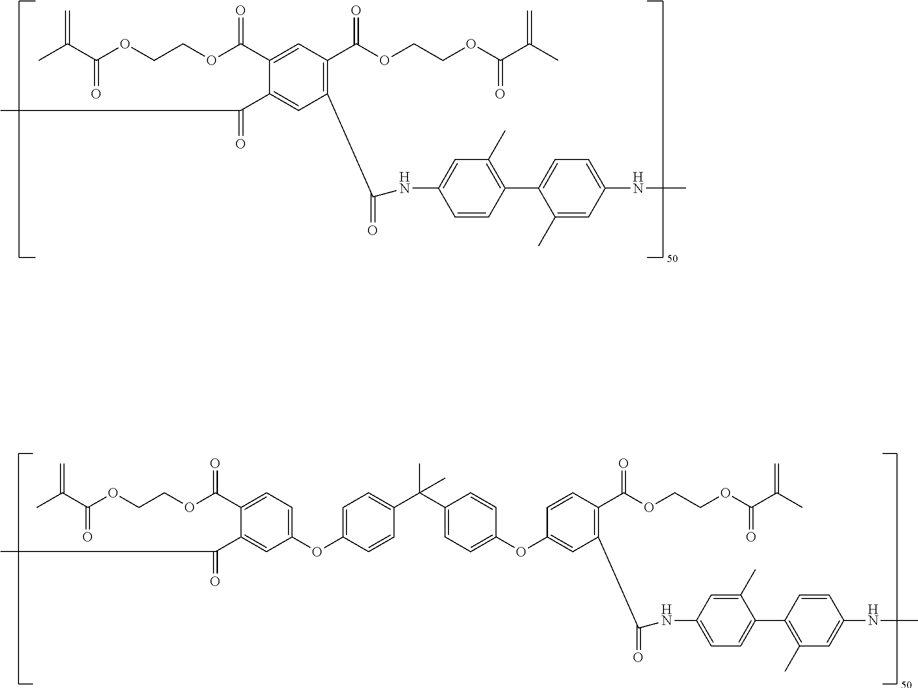

### Synthesis Example: Synthesis of Polymer 8

23.5 g (75.7 millimoles) of 4,4′-oxydiphthalic acid dianhydride (ODPA) and 22.3 g (75.7 millimoles) of bisphthalic acid dianhydride (BPDA) were placed in a separable flask, 39.7 g of 2-hydroxyethyl methacrylate (HEMA) and 136.8 g of tetrahydrofuran were added thereto, and the mixture was stirred at room temperature (25 °C), and 24.7 g of pyridine was added thereto while stirring to obtain a reaction mixture. After the heat generation due to the reaction was stopped, the mixture was allowed to cool to room temperature and left to stand for 16 hours.

Next, Next, under ice-cooling, a solution obtained by dissolving 62.5 g of dicyclohexylcarbodiimide (DCC) in 61.6 g of tetrahydrofuran was added to the reaction mixture over 40 minutes with stirring, and subsequently a suspension obtained by suspending 27.6 g (137.8 mmol) of 4,4′-diaminodiphenyl ether (DADPE) in 119.7 g of tetrahydrofuran was added thereto over 60 minutes with stirring. Further, the mixture was stirred at room temperature for 2 hours, 7.17 g of ethanol was added thereto, and the mixture was stirred for 1 hour, and then 136.8 g of tetrahydrofuran was added thereto. The precipitate formed in the reaction mixture was removed by filtration to obtain a reaction solution.

The obtained reaction solution was added to 716.2 g of ethanol to generate a precipitate consisting of a crude polymer. The generated crude polymer was filtered out and then dissolved in 403.5 g of tetrahydrofuran to obtain a crude polymer solution. The obtained crude polymer solution was added dropwise to 8470 g of water to precipitate the polymer, and the obtained precipitate was filtered. Next, the obtained polyimide precursor was dried at 45 °C for 2 days under reduced pressure to obtain a polyimide precursor (polymer 8). The weight-average molecular weight (Mw) of the obtained polyimide precursor (polymer 8) was 25,300, and the number-average molecular weight (Mn) was 10,150. It is presumed that the polyimide precursor (polymer 8) has a structure including two repeating units represented by the following formula (polymer 8). The subscript in parentheses of the following repeating unit represents content molar ratios of each repeating unit. The weight-average molecular weight of the polymer 8 was 25,000, the number-average molecular weight was 10,150, and the imidization rate was 20%.

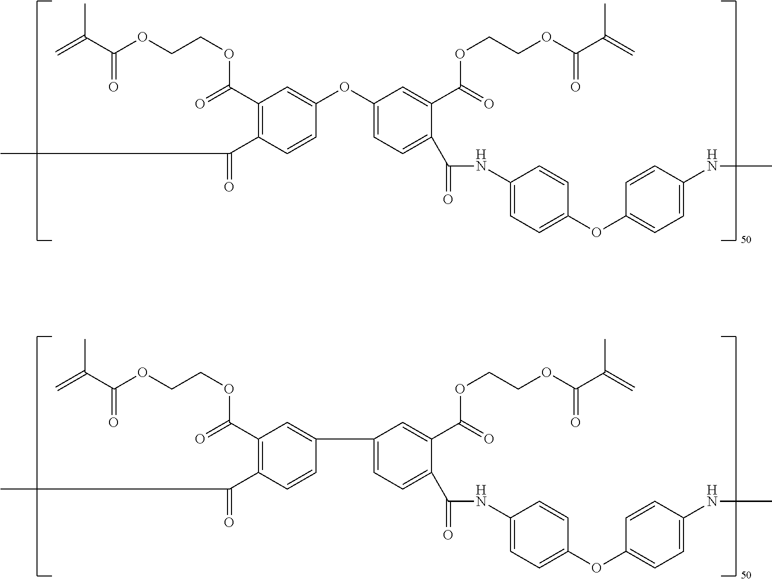

### Synthesis Example: Synthesis of Polymers 9 to 16

Polymers 9 to 15 were synthesized by the same method as in the polymer 3, except that the raw materials used were appropriately changed.

Polymers 9 to 15 are resins having a repeating unit represented by the following formula, respectively. The structure of each repeating unit was determined from a ¹H-NMR spectrum. In the following structures, the subscript of the parentheses represents the molar ratio of each structure. The weight-average molecular weight, the number-average molecular weight, and the imidization rate of these resins are described in the table below.

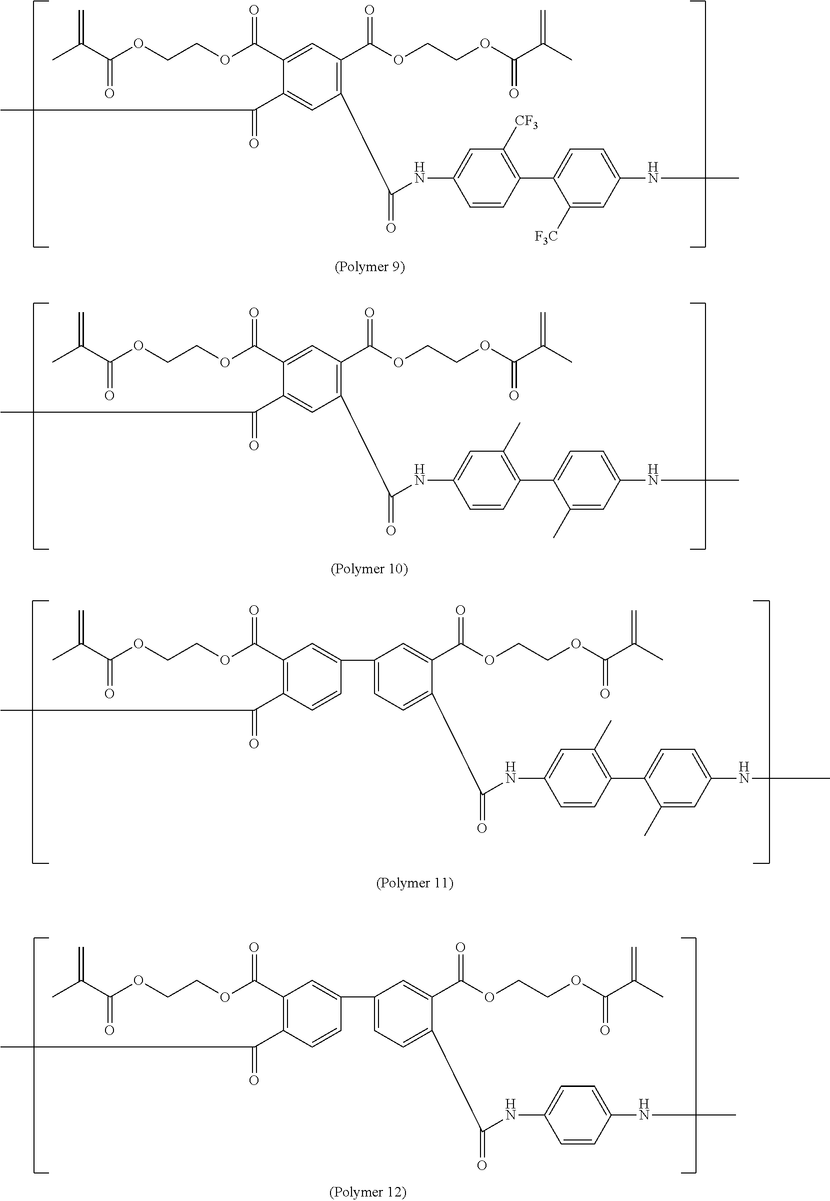

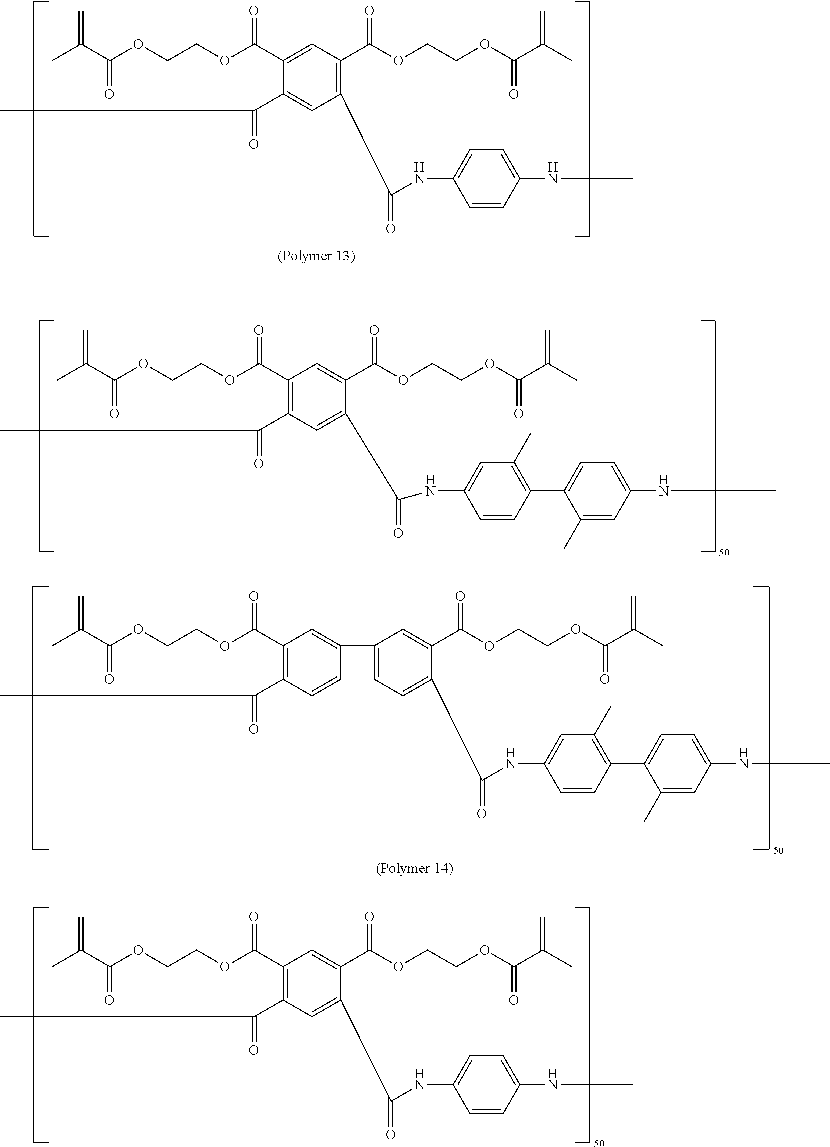

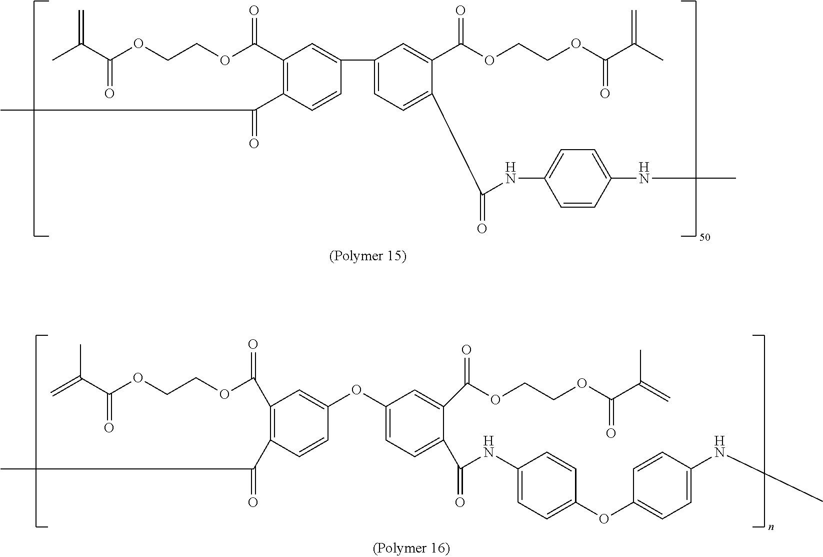

TABLE 2

| | Weight-average | Number-average | |
|---|---|---|---|
| | molecular | molecular | Imidization |
| Resin | weight (Mw) | weight (Mn) | rate (%) |
| Polymer 9 | 25,000 | 10,000 | 2 |
| Polymer 10 | 25,000 | 10,000 | 0 |
| Polymer 11 | 25,000 | 10,500 | 10 |
| Polymer 12 | 25,000 | 10,500 | 10 |
| Polymer 13 | 25,000 | 10,000 | 2 |
| Polymer 14 | 25,000 | 11,000 | 20 |
| Polymer 15 | 25,000 | 12,500 | 15 |
| Polymer 16 | 20,000 | 11,000 | 1 |

### Examples and Comparative Examples

In each of Examples, the components shown in the table below were mixed to obtain each of the negative-tone photosensitive resin compositions.

Specifically, the content of each component described in the table was set to the amount (in terms of parts by mass) described in the column of “Parts by mass” of each column of the table.

The obtained negative-tone photosensitive resin composition was subjected to pressure filtration using a filter made of polypropylene having a pore width of 0.45 μm.

In addition, in the table, the description of “−” indicates that the corresponding component is not contained in the composition.

TABLE 3

| | | Example 1 | Example 2 | Example 3 | Example 4 | Example 5 | Example 6 | Example 7 | Example 8 |
|---|---|---|---|---|---|---|---|---|---|
| Polymer | Name | Polymer 1 | Polymer 2 | Polymer 2 | Polymer 3 | Polymer 3 | Polymer 3 | Polymer 4 | Polymer 4 |
| | Parts by | 75.16 | 75.16 | 73.16 | 79.07 | 77.07 | 77.07 | 79.07 | 77.07 |
| | mass | | | | | | | | |
| Polymer- | Name | Polymer- | Polymer- | Polymer- | Polymer- | Polymer- | Polymer- | Polymer- | Polymer- |
| izable | | izable | izable | izable | izable | izable | izable | izable | izable |
| compound | | compound 1 | compound 1 | compound 1 | compound 1 | compound 2 | compound 2 | compound 2 | compound 2 |
| | Parts by | 18.50 | 18.50 | 18.50 | 12.46 | 12.46 | 12.46 | 12.46 | 12.46 |
| | mass | | | | | | | | |
| Polymer- | Name | Polymer- | Polymer- | Polymer- | Polymer- | Polymer- | Polymer- | Polymer- | Polymer- |
| ization | | ization | ization | ization | ization | ization | ization | ization | ization |
| initiator | | initiator 1 | initiator 1 | initiator 1 | initiator 1 | initiator 1 | initiator 1 | initiator 1 | initiator 1 |
| | Parts by | 4.31 | 4.31 | 4.31 | 2.32 | 2.32 | 2.32 | 2.32 | 2.32 |
| | mass | | | | | | | | |
| | Name | — | — | — | — | — | — | — | — |
| | Parts by | — | — | — | — | — | — | — | — |
| | mass | | | | | | | | |
| | Name | — | — | — | — | — | — | — | — |
| | Parts by | — | — | — | — | — | — | — | — |
| | mass | | | | | | | | |
| Migration | Name | Migration | Migration | Migration | Migration | Migration | Migration | Migration | Migration |
| suppressing | | suppressing | suppressing | suppressing | suppressing | suppressing | suppressing | suppressing | suppressing |
| agent | | agent 1 | agent 1 | agent 1 | agent 1 | agent 1 | agent 1 | agent 1 | agent 1 |
| | Parts by | 0.27 | 0.27 | 0.27 | 0.34 | 0.34 | 0.34 | 0.34 | 0.34 |
| | mass | | | | | | | | |
| Metal | Name | Metal | Metal | Metal | Metal | Metal | Metal | Metal | Metal |
| adhe- | | adhe- | adhe- | adhe- | adhe- | adhe- | adhe- | adhe- | adhe- |
| siveness | | siveness | siveness | siveness | siveness | siveness | siveness | siveness | siveness |
| improving | | improving | improving | improving | improving | improving | improving | improving | improving |
| agent | | agent 1 | agent 1 | agent 1 | agent 1 | agent 1 | agent 1 | agent 1 | agent 1 |
| | Parts by | 1.64 | 1.64 | 1.64 | 1.65 | 1.65 | 1.65 | 1.65 | 1.65 |
| | mass | | | | | | | | |
| Light | Name | — | — | Light | — | Light | Light | — | Light |
| absorbing | | | | absorbing | | absorbing | absorbing | | absorbing |
| agent | | | | agent 1 | | agent 1 | agent 1 | | agent 1 |
| | Parts by | — | — | 2.00 | — | 2.00 | 2.00 | — | 2.00 |
| | mass | | | | | | | | |
| Organic | Name | — | — | — | Organic | Organic | Organic | Organic | Organic |
| titanium | | | | | titanium | titanium | titanium | titanium | titanium |
| compound | | | | | compound 1 | compound 1 | compound 1 | compound 1 | compound 1 |
| | Parts by | — | — | — | 2.00 | 2.00 | 2.00 | 2.00 | 2.00 |
| | mass | | | | | | | | |
| Polymer- | Name | Polymer- | Polymer- | Polymer- | Polymer- | Polymer- | Polymer- | Polymer- | Polymer- |
| ization | | ization | ization | ization | ization | ization | ization | ization | ization |
| inhibitor | | inhibitor 1 | inhibitor 1 | inhibitor 1 | inhibitor 1 | inhibitor 1 | inhibitor 1 | inhibitor 1 | inhibitor 1 |
| | Parts by | 0.11 | 0.11 | 0.11 | 0.11 | 0.11 | 0.11 | 0.11 | 0.11 |
| | mass | | | | | | | | |
| Base | Name | — | — | — | Base | Base | Base | Base | Base |
| generator | | | | | generator 1 | generator 1 | generator 1 | generator 1 | generator 1 |
| | Parts by | — | — | — | 2.04 | 2.04 | 2.04 | 2.04 | 2.04 |
| | mass | | | | | | | | |
| Surfactant | Name | — | — | — | — | — | — | — | — |
| | Parts by | — | — | — | — | — | — | — | — |
| | mass | | | | | | | | |
| Solvent | Name | Solvent 1 | Solvent 1 | Solvent 1 | Solvent 1 | Solvent 1 | Solvent 1 | Solvent 1 | Solvent 1 |
| | Parts by | 200.00 | 200.00 | 200.00 | 160.00 | 160.00 | 160.00 | 160.00 | 160.00 |
| | mass | | | | | | | | |
| | Name | — | — | — | Solvent 3 | Solvent 3 | Solvent 3 | Solvent 3 | Solvent 3 |
| | Parts by | — | — | — | 40.00 | 40.00 | 40.00 | 40.00 | 40.00 |
| | mass | | | | | | | | |
| | | Example 9 | Example 10 | Example 11 | Example 12 | Example 13 | Example 14 | Example 15 | Example 16 |
| Polymer | Name | Polymer 5 | Polymer 6 | Polymer 7 | Polymer 8 | Polymer 8 | Polymer 8 | Polymer 9 | Polymer 10 |
| | Parts by | 75.16 | 75.16 | 75.16 | 79.47 | 77.47 | 77.47 | 79.07 | 79.07 |
| | mass | | | | | | | | |
| Polymer- | Name | Polymer- | Polymer- | Polymer- | Polymer- | Polymer- | Polymer- | Polymer- | Polymer- |
| izable | | izable | izable | izable | izable | izable | izable | izable | izable |
| compound | | compound 1 | compound 1 | compound 1 | compound 1 | compound 1 | compound 1 | compound 2 | compound 2 |
| | Parts by | 18.50 | 18.50 | 18.50 | 7.77 | 7.77 | 7.77 | 12.46 | 12.46 |
| | mass | | | | | | | | |
| Polymer- | Name | Polymer- | Polymer- | Polymer- | Polymer- | Polymer- | Polymer- | Polymer- | Polymer- |
| ization | | ization | ization | ization | ization | ization | ization | ization | ization |
| initiator | | initiator 1 | initiator 1 | initiator 1 | initiator 2 | initiator 2 | initiator 2 | initiator 1 | initiator 1 |
| | Parts by | 4.31 | 4.31 | 4.31 | 3.20 | 3.20 | 3.20 | 232 | 2.32 |
| | mass | | | | | | | | |
| | Name | — | — | — | Polymer- | Polymer- | Polymer- | — | — |
| | | | | | ization | ization | ization | | |
| | | | | | initiator 3 | initiator 3 | initiator 3 | | |
| | Parts by | — | — | — | 2.28 | 2.28 | 2.28 | — | — |
| | mass | | | | | | | | |
| | Name | — | — | — | Polymer- | Polymer- | Polymer- | — | — |
| | | | | | ization | ization | ization | | |
| | | | | | initiator 4 | initiator 4 | initiator 4 | | |
| | Parts by | — | — | — | 5.48 | 5.48 | 5.48 | — | — |
| | mass | | | | | | | | |
| Migration | Name | Migration | Migration | Migration | — | — | — | Migration | Migration |
| suppressing | | suppressing | suppressing | suppressing | | | | suppressing | suppressing |
| agent | | agent 1 | agent 1 | agent 1 | | | | agent 1 | agent 1 |
| | Parts by | 0.27 | 0.27 | 0.27 | — | — | — | 0.34 | 0.34 |
| | mass | | | | | | | | |
| Metal | Name | Metal | Metal | Metal | Metal | Metal | Metal | Metal | Metal |
| adhe- | | adhe- | adhe- | adhe- | adhe- | adhe- | adhe- | adhe- | adhe- |
| siveness | | siveness | siveness | siveness | siveness | siveness | siveness | siveness | siveness |
| | | improving | improving | improving | improving | improving | improving | improving | improving |
| | | agent 1 | agent 1 | agent 1 | agent 2 | agent 2 | agent 2 | agent 1 | agent 1 |
| Improving | Parts by | 1.64 | 1.64 | 1.64 | 0.85 | 0.85 | 0.85 | 1.65 | 1.65 |
| agent | mass | | | | | | | | |
| Light | Name | — | — | — | — | Light | Light | — | — |
| absorbing | | | | | | absorbing | absorbing | | |
| | | | | | | agent 1 | agent 2 | | |
| agent | Parts by | — | — | — | — | 2.00 | 2.00 | — | — |
| | mass | | | | | | | | |
| Organic | Name | — | — | — | Organic | Organic | Organic | Organic | Organic |
| titanium | | | | | titanium | titanium | titanium | titanium | titanium |
| compound | | | | | compound 2 | compound 2 | compound 2 | compound 1 | compound 1 |
| | Parts by | — | — | — | 0.50 | 0.50 | 0.50 | 200 | 2.00 |
| | mass | | | | | | | | |
| Polymer- | Name | Polymer- | Polymer- | Polymer- | Polymer- | Polymer- | Polymer- | Polymer- | Polymer- |
| ization | | ization | ization | ization | ization | ization | ization | ization | ization |
| inhibitor | | inhibitor 1 | inhibitor 1 | inhibitor 1 | inhibitor 2 | inhibitor 2 | inhibitor 2 | inhibitor 1 | inhibitor 1 |
| | Parts by | 0.11 | 0.11 | 0.11 | 0.46 | 0.46 | 0.46 | 0.11 | 0.11 |
| | mass | | | | | | | | |
| Base | Name | — | — | — | — | — | — | Base | Base |
| generator | | | | | | | | generator 1 | generator 1 |
| | Parts by | — | — | — | — | — | — | 2.04 | 2.04 |
| | mass | | | | | | | | |
| Surfactant | Name | — | — | — | — | — | — | — | — |
| | Parts by | — | — | — | — | — | — | — | — |
| | mass | | | | | | | | |
| Solvent | Name | Solvent 1 | Solvent 1 | Solvent 1 | Solvent 2 | Solvent 2 | Solvent 2 | Solvent 1 | Solvent 1 |
| | Parts by | 200.00 | 200.00 | 200.00 | 160.00 | 160.00 | 160.00 | 160.00 | 160.00 |
| | mass | | | | | | | | |
| | Name | — | — | — | Solvent 4 | Solvent 4 | Solvent 4 | Solvent 3 | Solvent 3 |
| | Parts by | — | — | — | 40.00 | 40.00 | 40.00 | 40.00 | 40.00 |
| | mass | | | | | | | | |

TABLE 4

| | | Example 17 | Example 18 | Example 19 | Example 20 | Example 21 | Example 22 | Example 23 | Example 24 |
|---|---|---|---|---|---|---|---|---|---|
| Polymer | Name | Polymer 11 | Polymer 12 | Polymer 13 | Polymer 14 | Polymer 15 | Polymer 4 | Polymer 4 | Polymer 4 |
| | Parts | 79.07 | 79.07 | 79.07 | 79.07 | 79.07 | 79.07 | 79.07 | 79.07 |
| | by | | | | | | | | |
| | mass | | | | | | | | |
| Polymer- | Name | Polymer- | Polymer- | Polymer- | Polymer- | Polymer- | Polymer- | Polymer- | Polymer- |
| izable | | izable | izable | izable | izable | izable | izable | izable | izable |
| compound | | compound 2 | compound 2 | compound 2 | compound 2 | compound 2 | compound 3 | compound 4 | compound 5 |
| | Parts | 12.46 | 12.46 | 12.46 | 12.46 | 12.46 | 12.46 | 12.46 | 12.46 |
| | by | | | | | | | | |
| | mass | | | | | | | | |
| Polymer- | Name | Polymer- | Polymer- | Polymer- | Polymer- | Polymer- | Polymer- | Polymer- | Polymer- |
| ization | | ization | ization | ization | ization | ization | ization | ization | ization |
| initiator | | initiator 1 | initiator 1 | initiator 1 | initiator 1 | initiator 1 | initiator 1 | initiator 1 | initiator 1 |
| | Parts | 2.32 | 2.32 | 2.32 | 2.32 | 2.32 | 2.32 | 2.32 | 2.32 |
| | by | | | | | | | | |
| | mass | | | | | | | | |
| | Name | — | — | — | — | — | — | — | — |
| | Parts | — | — | — | — | — | — | — | — |
| | by | | | | | | | | |
| | mass | | | | | | | | |
| | Name | — | — | — | — | — | — | — | — |
| | Parts | — | — | — | — | — | — | — | — |
| | by | | | | | | | | |
| | mass | | | | | | | | |
| Migration | Name | Migration | Migration | Migration | Migration | Migration | Migration | Migration | Migration |
| suppressing | | suppressing | suppressing | suppressing | suppressing | suppressing | suppressing | suppressing | suppressing |
| agent | | agent 1 | agent 1 | agent 1 | agent 1 | agent 1 | agent 1 | agent 1 | agent 1 |
| | Parts | 0.34 | 0.34 | 0.34 | 0.34 | 0.34 | 0.34 | 0.34 | 0.34 |
| | by | | | | | | | | |
| | mass | | | | | | | | |
| Metal | Name | Meta | Metal | Metal | Metal | Metal | Metal | Metal | Metal |
| adhe- | | adhe- | adhe- | adhe- | adhe- | adhe- | adhe- | adhe- | adhe- |
| siveness | | siveness | siveness | siveness | siveness | siveness | siveness | siveness | siveness |
| improving | | improving | improving | improving | improving | improving | improving | improving | improving |
| agent | | agent 1 | agent 1 | agent 1 | agent | agent 1 | agent 1 | agent 1 | agent 1 |
| | Parts | 1.65 | 1.65 | 1.65 | 1.65 | 1.65 | 1.65 | 1.65 | 1.65 |
| | by | | | | | | | | |
| | mass | | | | | | | | |
| Light | Name | — | — | — | — | — | — | — | — |
| absorbing | Parts | — | — | — | — | — | — | — | — |
| agent | by | | | | | | | | |
| | mass | | | | | | | | |
| Organic | Name | Organic | Organic | Organic | Organic | Organic | Organic | Organic | Organic |
| titanium | | titanium | titanium | titanium | titanium | titanium | titanium | titanium | titanium |
| compound | | compound 1 | compound 1 | compound 1 | compound 1 | compound 1 | compound 1 | compound 1 | compound 1 |
| | Parts | 2.00 | 2.00 | 2.00 | 2.00 | 2.00 | 2.00 | 2.00 | 2.00 |
| | by | | | | | | | | |
| | mass | | | | | | | | |
| Polymer- | Name | Polymer- | Polymer- | Polymer- | Polymer- | Polymer- | Polymer- | Polymer- | Polymer- |
| ization | | ization | ization | ization | ization | ization | ization | ization | ization |
| inhibitor | | inhibitor 1 | inhibitor 1 | inhibitor 1 | inhibitor 1 | inhibitor 1 | inhibitor 1 | inhibitor 1 | inhibitor 1 |
| | Parts | 0.11 | 0.11 | 0.11 | 0.11 | 0.11 | 0.11 | 0.11 | 0.11 |
| | by | | | | | | | | |
| | mass | | | | | | | | |
| Base | Name | Base | Base | Base | Base | Base | Base | Base | Base |
| generator | | generator 1 | generator 1 | generator 1 | generator 1 | generator 1 | generator 1 | generator 1 | generator 1 |
| | Parts | 2.04 | 2.04 | 2.04 | 2.04 | 2.04 | 2.04 | 2.04 | 2.04 |
| | by | | | | | | | | |
| | mass | | | | | | | | |
| Surfactant | Name | — | — | — | — | — | — | — | — |
| | Parts | — | — | — | — | — | — | — | — |
| | by | | | | | | | | |
| | mass | | | | | | | | |
| Solvent | Name | Solvent 1 | Solvent 1 | Solvent 1 | Solvent 1 | Solvent 1 | Solvent 1 | Solvent 1 | Solvent 1 |
| | Parts | 160.00 | 160.00 | 160.00 | 160.00 | 160.00 | 160.00 | 160.00 | 160.00 |
| | by | | | | | | | | |
| | mass | | | | | | | | |
| | Name | Solvent 3 | Solvent 3 | Solvent 3 | Solvent 3 | Solvent 3 | Solvent 3 | Solvent 3 | Solvent 3 |
| | Parts | 40.00 | 40.00 | 40.00 | 40.00 | 40.00 | 40.00 | 40.00 | 40.00 |
| | by | | | | | | | | |
| | mass | | | | | | | | |
| | | Example 25 | Example 26 | Example 27 | Example 28 | Example 29 | Example 30 | Example 31 | Example 32 |
| Polymer | Name | Polymer 4 | Polymer 4 | Polymer 4 | Polymer 4 | Polymer 4 | Polymer 4 | Polymer 4 | Polymer 4 |
| | Parts | 79.07 | 76.75 | 79.07 | 79.07 | 79.07 | 79.07 | 79.07 | 79.07 |
| | by | | | | | | | | |
| | mass | | | | | | | | |
| Polymer- | Name | Polymer- | Polymer- | Polymer- | Polymer- | Polymer- | Polymer- | Polymer- | Polymer- |
| izable | | izable | izable | izable | izable | izable | izable | izable | izable |
| compound | | compound 6 | compound 2 | compound 2 | compound 2 | compound 2 | compound 2 | compound 2 | compound 2 |
| | Parts | 12.46 | 12.46 | 12.46 | 12.46 | 12.46 | 12.46 | 12.46 | 12.46 |
| | by | | | | | | | | |
| | mass | | | | | | | | |
| Polymer- | Name | Polymer- | Polymer- | Polymer- | Polymer- | Polymer- | Polymer- | Polymer- | Polymer- |
| ization | | ization | ization | ization | ization | ization | ization | ization | ization |
| initiator | | initiator 1 | initiator 1 | initiator 1 | initiator 1 | initiator 1 | initiator 1 | initiator 1 | initiator 1 |
| | Parts | 2.32 | 2.32 | 2.32 | 2.32 | 2.32 | 2.32 | 2.32 | 2.32 |
| | by | | | | | | | | |
| | mass | | | | | | | | |
| | Name | — | Polymer- | — | — | — | — | — | — |
| | | | ization | | | | | | |
| | | | initiator 5 | | | | | | |
| | Parts | — | 2.32 | — | — | — | — | — | — |
| | by | | | | | | | | |
| | mass | | | | | | | | |
| | Name | — | — | — | — | — | — | — | — |
| | Parts | — | — | — | — | — | — | — | — |
| | by | | | | | | | | |
| | mass | | | | | | | | |
| Migration | Name | Migration | Migration | Migration | Migration | Migration | Migration | Migration | Migration |
| suppressing | | suppressing | suppressing | suppressing | suppressing | suppressing | suppressing | suppressing | suppressing |
| agent | | agent 1 | agent 1 | agent 2 | agent 3 | agent 4 | agent 1 | agent 1 | agent 1 |
| | Parts | 0.34 | 0.34 | 0.34 | 0.34 | 0.34 | 0.34 | 0.34 | 0.34 |
| | by | | | | | | | | |
| | mass | | | | | | | | |
| Metal | Name | Metal | Metal | Metal | Metal | Metal | Metal | Metal | Metal |
| adhe- | | adhe- | adhe- | adhe- | adhe- | ache- | adhe- | adhe- | adhe- |
| siveness | | siveness | siveness | siveness | siveness | siveness | siveness | siveness | siveness |
| improving | | improving | improving | improving | improving | improving | improving | improving | improving |
| agent | | agent 1 | agent 1 | agent 1 | agent 1 | agent 1 | agent 2 | agent 3 | agent 1 |
| | Parts | 165 | 165 | 165 | 165 | 165 | 1.65 | 1.65 | 1.65 |
| | by | | | | | | | | |
| | mass | | | | | | | | |
| Light | Name | — | — | — | — | — | — | — | — |
| absorbing | Parts | — | — | — | — | — | — | — | — |
| agent | by | | | | | | | | |
| | mass | | | | | | | | |
| Organic | Name | Organic | Organic | Organic | Organic | Organic | Organic | Organic | Organic |
| titanium | | titanium | titanium | titanium | titanium | titanium | titanium | titanium | titanium |
| compound | | compound 1 | compound 1 | compound 1 | compound 1 | compound 1 | compound 1 | compound 1 | compound 1 |
| | Parts | 2.00 | 2.00 | 2.00 | 2.00 | 2.00 | 2.00 | 2.00 | 2.00 |
| | by | | | | | | | | |
| | mass | | | | | | | | |
| Polymer- | Name | Polymer- | Polymer- | Polymer- | Polymer- | Polymer- | Polymer- | Polymer- | Polymer- |
| ization | | ization | ization | ization | ization | ization | ization | ization | ization |
| inhibitor | | inhibitor 1 | inhibitor 1 | inhibitor 1 | inhibitor 1 | inhibitor 1 | inhibitor 1 | inhibitor 1 | inhibitor 3 |
| | Parts | 0.11 | 0.11 | 0.11 | 0.11 | 0.11 | 0.11 | 0.11 | 0.11 |
| | by | | | | | | | | |
| | mass | | | | | | | | |
| Base | Name | Base | Base | Base | Base | Base | Base | Base | Base |
| generator | | generator 1 | generator 1 | generator 1 | generator 1 | generator 1 | generator 1 | generator 1 | generator 1 |
| | Parts | 2.04 | 2.04 | 2.04 | 2.04 | 2.04 | 2.04 | 2.04 | 2.04 |
| | by | | | | | | | | |
| | mass | | | | | | | | |
| Surfactant | Name | — | — | — | — | — | — | — | — |
| | Parts | — | — | — | — | — | — | — | — |
| | by | | | | | | | | |
| | mass | | | | | | | | |
| Solvent | Name | Solvent 1 | Solvent 1 | Solvent 1 | Solvent 1 | Solvent 1 | Solvent 1 | Solvent 1 | Solvent 1 |
| | Parts | 160.00 | 160.00 | 160.00 | 160.00 | 160.00 | 160.00 | 160.00 | 160.00 |
| | by | | | | | | | | |
| | mass | | | | | | | | |
| | Name | Solvent 3 | Solvent 3 | Solvent 3 | Solvent 3 | Solvent 3 | Solvent 3 | Solvent 3 | Solvent 3 |
| | Parts | 40.00 | 40.00 | 40.00 | 40.00 | 40.00 | 40.00 | 40.00 | 40.00 |
| | by | | | | | | | | |
| | mass | | | | | | | | |

TABLE 5

| | | Example 33 | Example 34 | Example 35 | Example 36 | Example 37 | Example 38 | Example 39 | Example 40 |
|---|---|---|---|---|---|---|---|---|---|
| Polymer | Name | Polymer 4 | Polymer 4 | Polymer 4 | Polymer 4 | Polymer 4 | Polymer 4 | Polymer 4 | Polymer 4 |
| | Parts | 79.07 | 79.07 | 79.07 | 79.07 | 79.07 | 79.07 | 79.07 | 79.07 |
| | by | | | | | | | | |
| | mass | | | | | | | | |
| Polymer- | Name | Polymer- | Polymer- | Polymer- | Polymer- | Polymer- | Polymer- | Polymer- | Polymer- |
| izable | | izable | izable | izable | izable | izable | izable | izable | izable |
| compound | | compound 2 | compound 2 | compound 2 | compound 2 | compound 2 | compound 2 | compound 2 | compound 2 |
| | Parts | 12.46 | 12.46 | 12.46 | 12.46 | 12.46 | 12.46 | 12.46 | 12.46 |
| | by | | | | | | | | |
| | mass | | | | | | | | |
| Polymer- | Name | Polymer- | Polymer- | Polymer- | Polymer- | Polymer- | Polymer- | Polymer- | Polymer- |
| ization | | ization | ization | ization | ization | ization | ization | ization | ization |
| initiator | | initiator 1 | initiator 1 | initiator 1 | initiator 1 | initiator 1 | initiator 1 | initiator 1 | initiator 1 |
| | Parts | 2.32 | 2.32 | 2.32 | 2.32 | 2.32 | 2.32 | 2.32 | 2.32 |
| | by | | | | | | | | |
| | mass | | | | | | | | |
| | Name | — | — | — | — | — | — | — | — |
| | Parts | — | — | — | — | — | — | — | — |
| | by | | | | | | | | |
| | mass | | | | | | | | |
| | Name | — | — | — | — | — | — | — | — |
| | Parts | — | — | — | — | — | — | — | — |
| | by | | | | | | | | |
| | mass | | | | | | | | |
| Migration | Name | Migration | Migration | Migration | Migration | Migration | Migration | Migration | Migration |
| suppressing | | suppressing | suppressing | suppressing | suppressing | suppressing | suppressing | suppressing | suppressing |
| agent | | agent 1 | agent 1 | agent 1 | agent 1 | agent 1 | agent 1 | agent 1 | agent 1 |
| | Parts | 0.34 | 0.34 | 0.34 | 0.34 | 0.34 | 0.34 | 0.34 | 0.34 |
| | by | | | | | | | | |
| | mass | | | | | | | | |
| Metal | Name | Metal | Metal | Metal | Metal | Metal | Metal | Metal | Metal |
| adhe- | | adhe- | adhe- | adhe- | adhe- | adhe- | adhe- | adhe- | adhe- |
| siveness | | siveness | siveness | siveness | siveness | siveness | siveness | siveness | siveness |
| improving | | improving | improving | improving | improving | improving | improving | improving | improving |
| agent | | agent 1 | agent 1 | agent 1 | agent 1 | agent 1 | agent 1 | agent 1 | agent 1 |
| | Parts | 1.65 | 1.65 | 1.65 | 1.65 | 1.65 | 1.65 | 1.65 | 1.65 |
| | by | | | | | | | | |
| | mass | | | | | | | | |
| Light | Name | — | — | — | — | — | — | — | — |
| absorbing | Parts | — | — | — | — | — | — | — | — |
| agent | by | | | | | | | | |
| | mass | | | | | | | | |
| Organic | Name | Organic | Organic | Organic | Organic | Organic | Organic | Organic | Organic |
| titanium | | titanium | titanium | titanium | titanium | titanium | titanium | titanium | titanium |
| compound | | compound 1 | compound 1 | compound 1 | compound 1 | compound 1 | compound 1 | compound 1 | compound 1 |
| | Parts | 2.00 | 2.00 | 2.00 | 2.00 | 2.00 | 2.00 | 2.00 | 2.00 |
| | by | | | | | | | | |
| | mass | | | | | | | | |
| Polymer- | Name | Polymer- | Polymer- | Polymer- | Polymer- | Polymer- | Polymer- | Polymer- | Polymer- |
| ization | | ization | ization | ization | ization | ization | ization | ization | ization |
| inhibitor | | inhibitor 4 | inhibitor 1 | inhibitor 1 | inhibitor 1 | inhibitor 1 | inhibitor 1 | inhibitor 1 | inhibitor 1 |
| | Parts | 0.11 | 0.11 | 0.11 | 0.11 | 0.11 | 0.11 | 0.11 | 0.11 |
| | by | | | | | | | | |
| | mass | | | | | | | | |
| Base | Name | Base | Base | Base | Base | Base | Base | Base | Base |
| generator | | generator 1 | generator 2 | generator 1 | generator 1 | generator 1 | generator 1 | generator 1 | generator 1 |
| | Parts | 2.04 | 2.04 | 2.04 | 2.04 | 2.04 | 2.04 | 2.04 | 2.04 |
| | by | | | | | | | | |
| | mass | | | | | | | | |
| Surfactant | Name | — | — | — | — | — | | — | — |
| | Part | — | — | — | — | — | | — | — |
| | by | | | | | | | | |
| | mass | | | | | | | | |
| Solvent | Name | Solvent 1 | Solvent 1 | Solvent 5 | Solvent 6 | Solvent 7 | Solvent 7 | Solvent 7 | Solvent 7 |
| | Parts | 160.00 | 160.00 | 160.00 | 160.00 | 160.00 | 160.00 | 160.00 | 160.00 |
| | by | | | | | | | | |
| | mass | | | | | | | | |
| | Name | Solvent 3 | Solvent 3 | Solvent 3 | Solvent 3 | Solvent 3 | Solvent 3 | Solvent 3 | Solvent 3 |
| | Parts | 40.00 | 40.00 | 40.00 | 40.00 | 40.00 | 40.00 | 40.00 | 40.00 |
| | by | | | | | | | | |
| | mass | | | | | | | | |

| | | Example 41 | Example 42 | Example 43 | Example 44 | Example 45 | Example 46 | Example 47 |
|---|---|---|---|---|---|---|---|---|
| Polymer | Name | Polymer 4 | Polymer 4 | Polymer 4 | Polymer 16 | Polymer 16 | Polymer 16 | Polymer 16 |
| | Parts | 79.07 | 79.07 | 79.07 | 80.77 | 80.51 | 79.22 | 81.09 |
| | by | | | | | | | |
| | mass | | | | | | | |
| Polymer- | Name | Polymer- | Polymer- | Polymer- | Polymer- | Polymer- | Polymer- | Polymer- |
| izable | | izable | izable | izable | izable | izable | izable | izable |
| compound | | compound 2 | compound 2 | compound 2 | compound 2/ | compound 2 | compound 2 | compound 8 |
| | | | | | Polymer- | | | |
| | | | | | izable | | | |
| | | | | | compound | | | |
| | | | | | 7 = 1/1 | | | |
| | Parts | 12.46 | 12.46 | 12.46 | 12.34 | 12.16 | 12.17 | 12.08 |
| | by | | | | | | | |
| | mass | | | | | | | |
| Polymer- | Name | Polymer- | Polymer- | Polymer- | Polymer- | Polymer- | Polymer- | Polymer- |
| ization | | ization | ization | ization | ization | ization | ization | ization |
| initiator | | initiator 1 | initiator 1 | initiator 1 | initiator 1 | initiator 1 | initiator 1 | initiator 1 |
| | Parts | 2.32 | 2.32 | 2.32 | 2.88 | 2.27 | 2.26 | 2.83 |
| | by | | | | | | | |
| | mass | | | | | | | |
| | Name | — | — | — | — | — | — | — |
| | Parts | — | — | — | — | — | — | — |
| | by | | | | | | | |
| | mass | | | | | | | |
| | Name | — | — | — | — | — | — | — |
| | Parts | — | — | — | — | — | — | — |
| | by | | | | | | | |
| | mass | | | | | | | |
| Migration | Name | Migration | Migration | Migration | Migration | Migration | Migration | Migration |
| suppressing | | suppressing | suppressing | suppressing | suppressing | suppressing | suppressing | suppressing |
| agent | | agent 1 | agent 1 | agent 1 | agent 1 | agent 1 | agent 1 | agent 2 |
| | Parts | 0.34 | 0.34 | 0.34 | 0.27 | 0.33 | 0.33 | 0.27 |
| | by | | | | | | | |
| | mass | | | | | | | |
| Metal | Name | Metal | Metal | Metal | Metal | Metal | Metal | Metal |
| adhe- | | adhe- | adhe- | adhe- | adhe- | adhe- | adhe- | adhe- |
| siveness | | siveness | siveness | siveness | siveness | siveness | siveness | siveness |
| improving | | improving | improving | improving | improving | improving | improving | improving |
| agent | | agent 1 | agent 1 | agent 1 | agent 1 | agent 1 | agent 1 | agent 1 |
| | Parts | 1.65 | 1.65 | 1.65 | 1.64 | 1.62 | 1.63 | 1.63 |
| | by | | | | | | | |
| | mass | | | | | | | |
| Light | Name | — | — | — | — | — | — | — |
| absorbing | Parts | — | — | — | — | — | — | — |
| agent | by | | | | | | | |
| | mass | | | | | | | |
| Organic | Name | Organic | Organic | Organic | — | — | Organic | — |
| titanium | | titanium | titanium | titanium | | | titanium | |
| compound | | compound 1 | compound 1 | compound 1 | | | compound 1 | |
| | Parts | 2.00 | 2.00 | 2.00 | — | — | 2.16 | — |
| | by | | | | | | | |
| | mass | | | | | | | |
| Polymer- | Name | Polymer- | Polymer- | Polymer- | Polymer- | Polymer- | Polymer- | Polymer- |
| ization | | ization | ization | ization | ization | ization | ization | ization |
| inhibitor | | inhibitor 1 | inhibitor 1 | inhibitor 1 | inhibitor 1 | inhibitor 1 | inhibitor 1 | inhibitor 1 |
| | Parts | 0.11 | 0.11 | 0.11 | 0.11 | 0.11 | 0.11 | 0.11 |
| | by | | | | | | | |
| | mass | | | | | | | |
| Base | Name | Base | Base | Base | Base | Base | Base | Base |
| generator | | generator 1 | generator 1 | generator 1 | generator 3 | generator 3 | generator 3 | generator 3 |
| | Parts | 2.04 | 2.04 | 2.04 | 1.99 | 3.00 | 2.12 | 1.99 |
| | by | | | | | | | |
| | mass | | | | | | | |
| Surfactant | Name | — | — | — | — | — | — | — |
| | Part | — | — | — | — | — | — | — |
| | by | | | | | | | |
| | mass | | | | | | | |
| Solvent | Name | Solvent 7 | Solvent 7 | Solvent 7 | Solvent 1 | Solvent 5 | Solvent 5 | Solvent 1 |
| | Parts | 160.00 | 160.00 | 160.00 | 140.00 | 140.00 | 140.00 | 140.00 |
| | by | | | | | | | |
| | mass | | | | | | | |
| | Name | Solvent 3 | Solvent 3 | Solvent 3 | Solvent 3 | Solvent 3 | Solvent 3 | Solvent 3 |
| | Parts | 40.00 | 40.00 | 40.00 | 35.00 | 35.00 | 35.00 | 35.00 |
| | by | | | | | | | |
| | mass | | | | | | | |

TABLE 6

| | | Example 48 | Example 49 | Example 50 | Example 51 | Example 52 | Example 53 | Example 54 | Example 55 | Example 56 |
|---|---|---|---|---|---|---|---|---|---|---|
| Polymer | Name | Polymer 16 | Polymer 16 | Polymer 16 | Polymer 16 | Polymer 16 | Polymer 16 | Polymer 16 | Polymer 16 | Polymer 16 |
| | Parts | 81.09 | 79.71 | 78.70 | 79.71 | 78.70 | 79.71 | 78.70 | 78.70 | 79.71 |
| | by | | | | | | | | | |
| | mass | | | | | | | | | |
| Polymer- | Name | Polymer- | Polymer- | Polymer- | Polymer- | Polymer- | Polymer- | Polymer- | Polymer- | Polymer- |
| izable | | izable | izable | izable | izable | izable | izable | izable | izable | izable |
| compound | | compound 8 | compound 2 | compound 2 | compound 2 | compound 2 | compound 2 | compound 2 | compound 2 | compound 2 |
| | Parts | 12.08 | 12.04 | 12.04 | 12.04 | 12.04 | 12.04 | 12.04 | 12.04 | 12.04 |
| | by | | | | | | | | | |
| | mass | | | | | | | | | |
| Polymer- | Name | Polymer- | Polymer- | Polymer- | Polymer- | Polymer- | Polymer- | Polymer- | Polymer- | Polymer- |
| ization | | ization | ization | ization | ization | ization | ization | ization | ization | ization |
| initiator | | initiator 1 | initiator 1 | initiator 1 | initiator 1 | initiator 1 | initiator 1 | initiator 1 | initiator 1 | initiator 1 |
| | Parts | 2.83 | 2.25 | 2.25 | 2.25 | 2.25 | 2.25 | 2.25 | 2.25 | 2.25 |
| | by | | | | | | | | | |
| | mass | | | | | | | | | |
| | Name | — | — | — | — | — | — | — | — | — |
| | Parts | — | — | — | — | — | — | — | — | — |
| | by | | | | | | | | | |
| | mass | | | | | | | | | |
| | Name | — | — | — | — | — | — | — | — | — |
| | Parts | — | — | — | — | — | — | — | — | — |
| | by | | | | | | | | | |
| | mass | | | | | | | | | |
| Migration | Name | Migration | Migration | Migration | Migration | Migration | Migration | Migration | Migration | Migration |
| suppressing | | suppressing | suppressing | suppressing | suppressing | suppressing | suppressing | suppressing | suppressing | suppressing |
| agent | | agent 2 | agent 1 | agent 1 | agent 5 | agent 5 | agent 6 | agent 6 | agent 1 | agent 1 |
| | Parts | 0.27 | 0.33 | 0.33 | 0.33 | 0.33 | 0.33 | 0.33 | 0.33 | 0.33 |
| | by | | | | | | | | | |
| | mass | | | | | | | | | |
| Metal | Name | Metal | Metal | Metal | Metal | Metal | Metal | Metal | Metal | Metal |
| adhe- | | adhe- | adhe- | adhe- | adhe- | adhe- | adhe- | adhe- | adhe- | adhe- |
| siveness | | siveness | siveness | siveness | siveness | siveness | siveness | siveness | siveness | siveness |
| improving | | improving | improving | improving | improving | improving | improving | improving | improving | improving |
| agent | | agent 1 | agent 1 | agent 1 | agent 1 | agent 1 | agent 1 | agent 1 | agent 1 | agent 1 |
| | Parts | 1.63 | 1.60 | 1.60 | 1.60 | 1.60 | 1.60 | 1.60 | 1.60 | 1.60 |
| | by | | | | | | | | | |
| | mass | | | | | | | | | |
| Light | Name | — | — | — | — | — | — | — | — | — |
| absorbing | Parts | — | — | — | — | — | — | — | — | — |
| agent | by | | | | | | | | | |
| | mass | | | | | | | | | |
| Organic | Name | — | — | Organic | — | Organic | — | Organic | Organic | — |
| titanium | | | | titanium | | titanium | | titanium | titanium | |
| compound | | | | compound 1 | | compound 1 | | compound 1 | compound 1 | |
| | Parts | — | — | 2.01 | — | 2.01 | — | 2.01 | 2.01 | — |
| | by | | | | | | | | | |
| | mass | | | | | | | | | |
| Polymer- | Name | Polymer- | Polymer- | Polymer- | Polymer- | Polymer- | Polymer- | Polymer- | Polymer- | Polymer- |
| ization | | ization | ization | ization | ization | ization | ization | ization | ization | ization |
| inhibitor | | inhibitor 1 | inhibitor 1 | inhibitor 1 | inhibitor 1 | inhibitor 1 | inhibitor 1 | inhibitor 1 | inhibitor 1 | inhibitor 1 |
| | Parts | 0.11 | 0.11 | 0.11 | 0.11 | 0.11 | 0.11 | 0.11 | 0.11 | 0.11 |
| | by | | | | | | | | | |
| | mass | | | | | | | | | |
| Base | Name | Base | Base | Base | Base | Base | Base | Base | Base | Base |
| generator | | generator 3 | generator 3 | generator 3 | generator 3 | generator 3 | generator 3 | generator 3 | generator 3 | generator 3 |
| | Parts | 1.99 | 1.97 | 1.97 | 1.97 | 1.97 | 1.97 | 1.97 | 1.97 | 1.97 |
| | by | | | | | | | | | |
| | mass | | | | | | | | | |
| Surfactant | Name | — | — | — | — | — | — | — | Surfac- | Surfac- |
| | | | | | | | | | tant 1 | tant 1 |
| | Parts | — | — | — | — | — | — | — | 0.03 | 0.03 |
| | by | | | | | | | | | |
| | mass | | | | | | | | | |
| Solvent | Name | Solvent 1 | Solvent 5 | Solvent 5 | Solvent 5 | Solvent 5 | Solvent 5 | Solvent 5 | Solvent 5 | Solvent 5 |
| | Parts | 95.00 | 140.80 | 140.80 | 140.80 | 140.80 | 140.80 | 140.80 | 140.80 | 140.80 |
| | by | | | | | | | | | |
| | mass | | | | | | | | | |
| | Name | Solvent 3 | Solvent 3 | Solvent 3 | Solvent 3 | Solvent 3 | Solvent 3 | Solvent 3 | Solvent 3 | Solvent 3 |
| | Parts | 23.75 | 35.20 | 35.20 | 35.20 | 35.20 | 35.20 | 35.20 | 35.20 | 35.20 |
| | by | | | | | | | | | |
| | mass | | | | | | | | | |

Details of each of the components listed in the table are as follows.

### [Polymer (Resin)]

Polymers 1 to 16: polymers 1 to 16 synthesized as described above

### [Polymerizable Compound]

Polymerizable compound 1: compound having the following structure
   Polymerizable compound 2: compound having the following structure (in the following structure, the number represents the molar ratio of each structure)
Polymerizable compounds 3 to 8: compound having the following structure

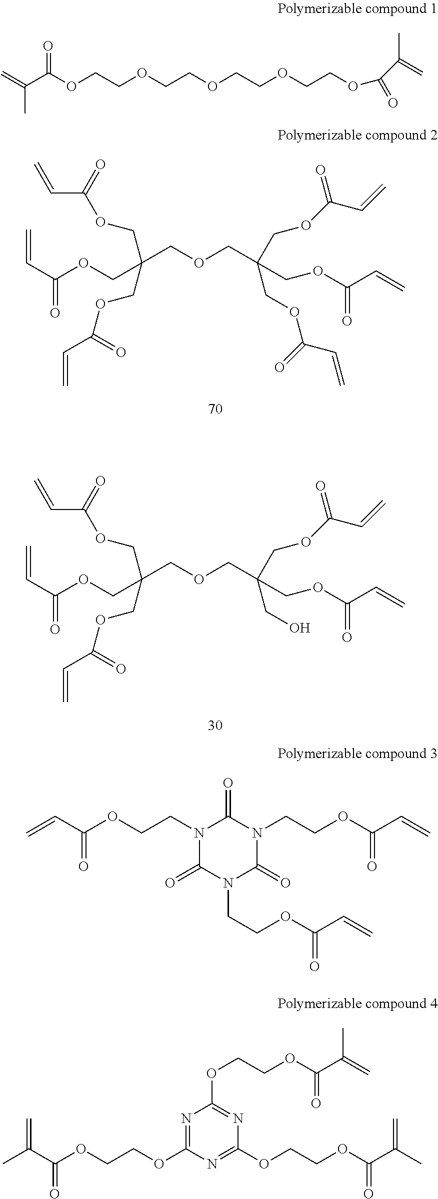

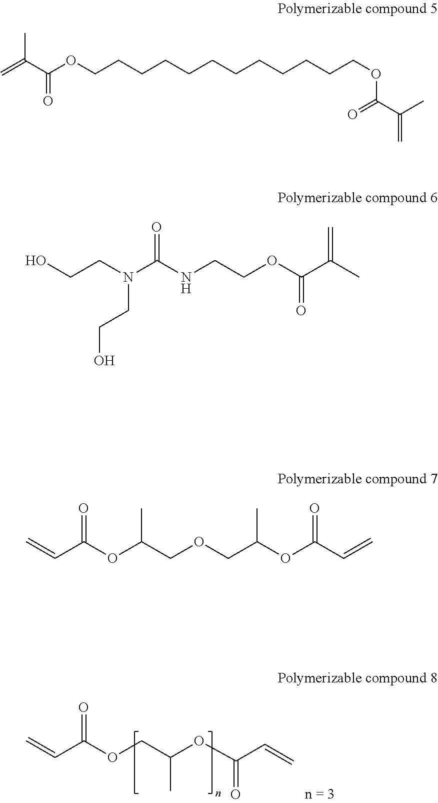

### [Polymerization Initiator]

Polymerization initiators 1 to 4: compound having the following structure
   Polymerization initiator 5: benzoyl peroxide (manufactured by Tokyo Chemical Industry Co., Ltd.)

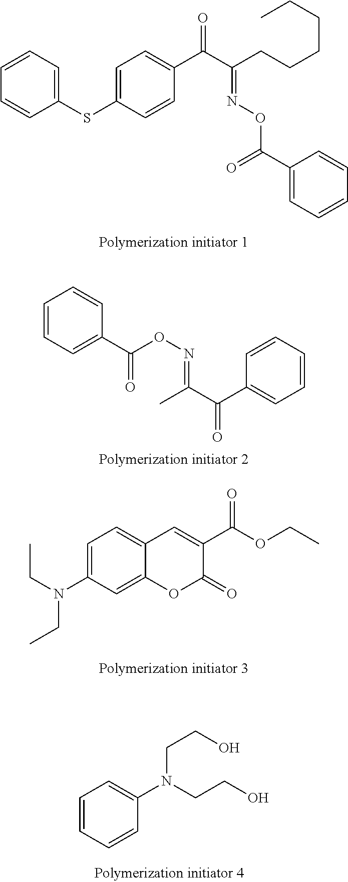 [SMILES: CCCCCC/C(=N\OC(=O)c1ccccc1)C(=O)c1ccc(Sc2ccccc2)cc1 ; C/C(=N\OC(=O)c1ccccc1)C(=O)c1ccccc1 ; CCOC(=O)c1cc2ccc(N(CC)CC)cc2oc1=O ; OCCN(CCO)c1ccccc1]

### [Migration Suppressing Agent]

Migration suppressing agents 1 to 6: compound having the following structure

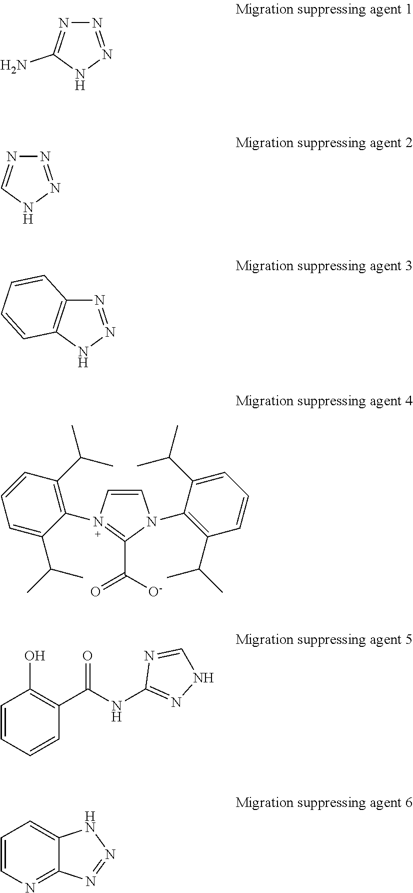

### [Metal Adhesiveness Improving Agent]

Metal adhesiveness improving agents 1 to 3: compound having the following structure

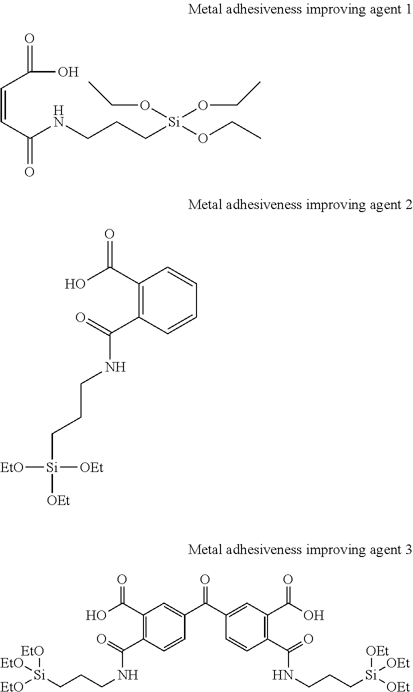 [SMILES: CCO[Si](CCCNC(=O)/C=C\C(=O)O)(OCC)OCC ; CCO[Si](CCCNC(=O)c1ccccc1C(=O)O)(OCC)OCC ; CCO[Si](CCCNC(=O)c1ccc(C(=O)c2ccc(C(=O)NCCC[Si](OCC)(OCC)OCC)c(C(=O)O)c2)cc1C(=O)O)(OCC)OCC]

### [Light Absorbing Agent]

Light absorbing agent 1: compound having the following structure
   Light absorber 2: ester (NQD (naphthoquinonediazide)) with 1~2:2,2′,3,3′-tetrahydro-3,3,3′,3′-tetramethyl-1,1′-spirobi(1H-inden)-5,5′,6,6′,7,7′hexanol and 1,2-naphthoquinone-(2)-diazoo-5-sulfonic acid

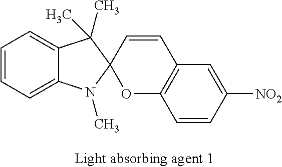 [SMILES: CN1c2ccccc2C(C)(C)C12C=Cc1cc([N+](=O)[O-])ccc1O2]

### [Organic Titanium Compound]

Organic titanium compound 1: compound having the following structure
Organic titanium compound 2: TC-750 (manufactured by Matsumoto Fine Chemical Co., Ltd.)

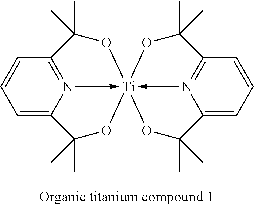

### [Polymerization Inhibitor]

Polymerization inhibitors 1 to 4: compound having the following structure

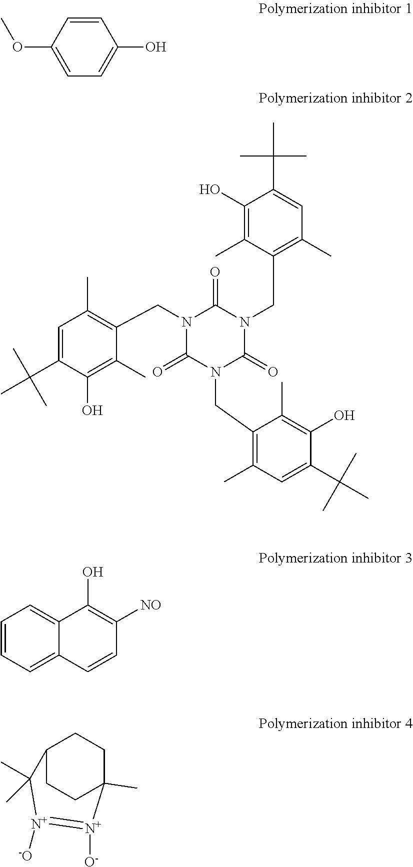

### [Base Generator]

Base generators 1 to 3: compound having the following structure

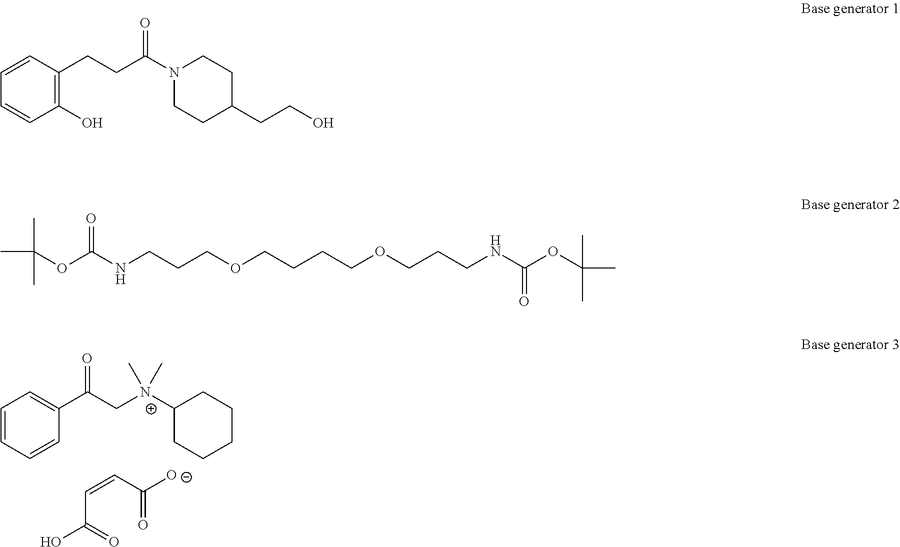 [SMILES: O=C(CCc1ccccc1O)N1CCC(CCO)CC1 ; CC(C)(C)OC(=O)NCCCOCCCCOCCCNC(=O)OC(C)(C)C ; C[N+](C)(CC(=O)c1ccccc1)C1CCCCC1 ; O=C([O-])/C=C\C(=O)O]

### [Solvent]

Solvent 1: GBL (7-butyrolactone)
Solvent 2: NMP (N-methyl-2-pyrrolidone)
Solvent 3: DMSO (dimethyl sulfoxide)
Solvent 4: EL (ethyl lactate)
Solvent 5: γ-valerolactone
Solvent 6: 3-methoxy-N,N-dimethylpropanamide
Solvent 7: anisole

### [Surfactant]

Surfactant 1: BYK-333 (manufactured by BYK Chemie)

### <Evaluation>

### [Measurement of Taper Angle]

In each of Examples, the composition was applied by a spin coating method and dried at 100 °C for 5 minutes to form a uniform resin composition layer having a thickness of 5 μm on a silicon wafer.

In each of Comparative Examples, a uniform resin composition layer was formed in the same manner as in Example 14, except that the same composition as in Example 14 was used.

The resin composition layer on the silicon wafer was exposed through a mask having a circular mask portion having a diameter of 5 μm, using an i-line stepper (manufactured by Canon Inc., FPR-3000i5) at a numerical aperture (Na) shown in the column of “Exposure Na” in the table described later, the exposure illuminance shown in the column of “Exposure illuminance” in the table, and the exposure amount shown in the column of “Exposure amount” in the table.

Thereafter, the resin composition layer was developed for 15 seconds using cyclopentanone as a developer, and rinsed for 30 seconds using PGMEA as a rinsing liquid to obtain a precursor pattern of the insulating pattern.

Further, the resin composition layer was heated at 230 °C for 3 hours in a nitrogen atmosphere to obtain an insulating pattern.

A Ti layer having a thickness of 50 nm was formed as a conductive layer on the region between the insulating patterns and on the insulating pattern by sputtering, and a Cu layer having a thickness of 200 nm was formed on the Ti layer by plating. Thereafter, a Cu layer (conductive layer) having a thickness of 2500 nm was formed on the Cu layer by plating.

The conductive layer was polished using a chemical mechanical polishing (CMP) machine (manufactured by Fujikoshi Machinery Corp.) using silica as a slurry, at a polishing time of 2.5 minutes and a polishing pressure of 3 psi, and the insulating pattern, the Ti layer formed as a seed layer, and the conductive pattern (via pattern) formed in the region between the insulating patterns were exposed on the surface.

In the present specification, 1 psi is 6.895 kPa.

In each of Examples and Comparative Examples, the insulating pattern and the conductive pattern were cut at a surface including the center of the conductive pattern, the cross section was polished with a milling device ArBlade 5000 (manufactured by Hitachi, Ltd.), an SEM image was acquired using FE-SEM SU-4800 (manufactured by Hitachi, Ltd.), and an angle between the bottom surface of the insulating pattern and the side surface of the insulating pattern (taper angle) was measured. The measurement results are shown in the column of “Via taper angle (degree)”.

[uHAST Test (Unsaturated Vapor Pressure Test)]

In each of Examples, the composition prepared in each of Examples was applied onto the surface of the substrate including one semiconductor die and a sealing material, on which the semiconductor die was exposed, by a spin coating method, and dried at 100 °C for 5 minutes to form a uniform resin composition layer having a thickness of 5 μm.

In each of Comparative Examples, a uniform resin composition layer was formed in the same manner as in Example 14, except that the same composition as in Example 14 was used. Next, the entire surface was exposed at exposure NA 0.16, exposure illuminance 10000 W/m², and exposure amount 400 mj/cm² using an i-line stepper (manufactured by Canon Inc., FPR-3000i5), and the exposure was performed on the entire surface, and the development, the rinsing, and the heat treatment were performed by the same method as in the measurement of the taper angle described above, except that the exposure was performed on the entire surface, thereby forming a flat insulating film on the silicon wafer.

Further, the insulating pattern and the conductive pattern were formed on the insulating film by the same method as in the measurement of the taper angle.

Further, each composition was applied again, and the entire surface was exposed, developed, rinsed, and heat-treated to prepare a laminate to be subjected to a reliability test.

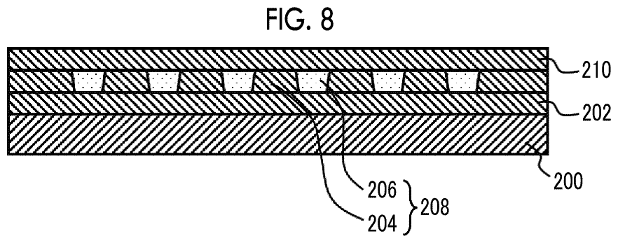

FIG. 8 shows a schematic cross-sectional view of the formed laminate.

In FIG. 8, a first insulating film 202 is formed on the surface of a substrate 200 including a semiconductor die and a sealing material, on which the semiconductor die is exposed, an insulating layer 208 including a wiring comprising an insulating pattern 204 and a conductive pattern 206 is formed on a surface of the first insulating film 202 on a side opposite to a surface of the substrate 200 including the semiconductor die and the sealing material, on which the semiconductor die is exposed, and a second insulating layer 210 is further formed on a side of the insulating layer 208 including the wiring opposite to the first insulating layer 202.

The obtained laminate was allowed to stand for 198 hours, 396 hours, and 594 hours under conditions of 130 °C and a relative humidity of 85%, and the cross section of the wiring portion was observed with a scanning electron microscope (SEM) to confirm the presence or absence of an abnormality such as a crack, peeling, or void.

The evaluation was performed according to the following evaluation standard, and the evaluation results are shown in the column of “uHAST test” in the table.

### —Evaluation Standards—

A: The cross section of the wiring was observed with SEM 594 hours later, and no abnormality such as a crack, peeling, or void was observed.
B: The cross section of the wiring was observed with SEM 594 hours later, and an abnormality such as a crack, peeling, or void was observed, but the cross section of the wiring was observed with SEM 396 hours later, and no abnormality such as a crack, peeling, or void was observed.
C: The cross section of the wiring was observed with SEM 396 hours later, and an abnormality such as a crack, peeling, or void was observed, but the cross section of the wiring was observed with SEM 198 hours later, and no abnormality such as a crack, peeling, or void was observed.

### [High Temperature Storage (HTS) Test]

The same laminate as the laminate used in the above-described uHAST test was allowed to stand for 500 hours, 1000 hours, and 1500 hours under conditions of 150 °C, and the cross section of the wiring portion was observed with a scanning electron microscope (SEM) to confirm the presence or absence of an abnormality such as a crack, peeling, or void.

The evaluation was performed according to the following evaluation standard, and the evaluation results are shown in the column of “HTS test” in the table.

### —Evaluation Standards—

A: The cross section of the wiring was observed with SEM 1500 hours later, and no abnormality such as a crack, peeling, or void was observed.
B: The cross section of the wiring was observed with SEM 1500 hours later, and an abnormality such as a crack, peeling, or void was observed, but the cross section of the wiring was observed with SEM 1000 hours later, and no abnormality such as a crack, peeling, or void was observed.
C: The cross section of the wiring was observed with SEM 1000 hours later, and an abnormality such as a crack, peeling, or void was observed, but the cross section of the wiring was observed with SEM 500 hours later, and no abnormality such as a crack, peeling, or void was observed.

### [Thermal Cycle Test]

The same laminate as the laminate used in the above-described uHAST test was subjected to a temperature cycle test of −40 °C to 125 °C using a heat shock test device (COSMOPIA S) (manufactured by Hitachi Global Life Solutions, Inc.).

The cross section of the wiring portion was observed with a scanning electron microscope (SEM) at the point of 750 cycles, 1500 cycles, and 2250 cycles, and the presence or absence of an abnormality such as a crack, peeling, or void was confirmed.

The evaluation was performed according to the following evaluation standard, and the evaluation results are shown in the column of “Thermal cycle test” in the table.

### —Evaluation Standards—

A: The cross section of the wiring was observed with SEM 2250 cycles later, and no abnormality such as a crack, peeling, or void was observed.
B: The cross section of the wiring was observed with SEM 2250 cycles later, and an abnormality such as a crack, peeling, or void was observed, but the cross section of the wiring was observed with SEM 1500 cycles later, and no abnormality such as a crack, peeling, or void was observed.
C: The cross section of the wiring was observed with SEM 1500 cycles later, and an abnormality such as a crack, peeling, or void was observed, but the cross section of the wiring was observed with SEM 750 cycles later, and no abnormality such as a crack, peeling, or void was observed.

TABLE 7

| | Exposure | Exposure | Amount of | Via taper angle | uHAST | HTS | Thermal |
|---|---|---|---|---|---|---|---|
| | Na | illuminance | exposure | (degree) | test | TEST | cycle test |
| Example 1 | 0.16 | 10000 W/m² | 400 mj/cm² | 81 | A | B | A |
| Example 2 | 0.16 | 10000 W/m² | 400 mj/cm² | 82 | B | A | A |
| Example 3 | 0.16 | 10000 W/m² | 400 mj/cm² | 74 | A | B | B |
| Example 4 | 0.16 | 10000 W/m² | 400 mj/cm² | 83 | A | B | A |
| Example 5 | 0.16 | 10000 W/m² | 400 mj/cm² | 72 | B | B | B |
| Example 6 | 0.16 | 10000 W/m² | 400 mj/cm² | 75 | A | B | B |
| Example 7 | 0.16 | 10000 W/m² | 400 mj/cm² | 87 | A | A | A |
| Example 8 | 0.16 | 10000 W/m² | 400 mj/cm² | 81 | A | B | A |
| Example 9 | 0.16 | 10000 W/m² | 400 mj/cm² | 83 | A | A | A |
| Example 10 | 0.16 | 10000 W/m² | 400 mj/cm² | 82 | A | B | A |
| Example 11 | 0.16 | 10000 W/m² | 400 mj/cm² | 83 | B | A | A |
| Example 12 | 0.16 | 10000 W/m² | 400 mj/cm² | 80 | A | B | A |
| Example 13 | 0.16 | 10000 W/m² | 400 mj/cm² | 73 | B | B | B |
| Example 14 | 0.16 | 10000 W/m² | 400 mj/cm² | 71 | B | B | B |
| Example 15 | 0.16 | 10000 W/m² | 400 mj/cm² | 82 | A | B | A |
| Example 16 | 0.16 | 10000 W/m² | 400 mj/cm² | 80 | A | A | B |
| Example 17 | 0.16 | 10000 W/m² | 400 mj/cm² | 81 | B | A | A |
| Example 18 | 0.16 | 10000 W/m² | 400 mj/cm² | 82 | A | B | A |
| Example 19 | 0.16 | 10000 W/m² | 400 mj/cm² | 84 | A | A | B |
| Example 20 | 0.16 | 10000 W/m² | 400 mj/cm² | 83 | B | A | A |
| Example 21 | 0.16 | 10000 W/m² | 400 mj/cm² | 82 | A | B | A |
| Example 22 | 0.16 | 10000 W/m² | 400 mj/cm² | 86 | A | A | A |
| Example 23 | 0.16 | 10000 W/m² | 400 mj/cm² | 88 | A | A | A |
| Example 24 | 0.16 | 10000 W/m² | 400 mj/cm² | 87 | A | A | A |
| Example 25 | 0.16 | 10000 W/m² | 400 mj/cm² | 87 | A | A | A |
| Example 26 | 0.16 | 10000 W/m² | 400 mj/cm² | 85 | A | A | A |
| Example 27 | 0.16 | 10000 W/m² | 400 mj/cm² | 86 | A | A | A |
| Example 28 | 0.16 | 10000 W/m² | 400 mj/cm² | 84 | A | A | A |
| Example 29 | 0.16 | 10000 W/m² | 400 mj/cm² | 85 | A | A | A |
| Example 30 | 0.16 | 10000 W/m² | 400 mj/cm² | 87 | A | A | A |
| Example 31 | 0.16 | 10000 W/m² | 400 mj/cm² | 88 | A | A | A |
| Example 32 | 0.16 | 10000 W/m² | 400 mj/cm² | 89 | A | A | A |
| Example 33 | 0.16 | 10000 W/m² | 400 mj/cm² | 87 | A | A | A |
| Example 34 | 0.16 | 10000 W/m² | 400 mj/cm² | 84 | A | A | A |
| Example 35 | 0.16 | 10000 W/m² | 400 mj/cm² | 84 | A | A | A |
| Example 36 | 0.16 | 10000 W/m² | 400 mj/cm² | 85 | A | A | A |
| Example 37 | 0.16 | 10000 W/m² | 400 mj/cm² | 86 | A | A | A |
| Example 38 | 0.24 | 10000 W/m² | 400 mj/cm² | 87 | A | A | A |
| Example 39 | 0.50 | 10000 W/m² | 400 mj/cm² | 89 | A | A | A |
| Example 40 | 0.16 | 6000 W/m² | 400 mj/cm² | 84 | A | A | A |
| Example 41 | 0.16 | 30000 W/m² | 400 mj/cm² | 86 | A | A | A |
| Example 42 | 0.16 | 10000 W/m² | 200 mj/cm² | 81 | A | A | A |
| Example 43 | 0.16 | 10000 W/m² | 600 mj/cm² | 90 | A | A | A |
| Example 44 | 0.16 | 10000 W/m² | 400 mj/cm² | 83 | A | A | A |
| Example 45 | 0.16 | 10000 W/m² | 400 mj/cm² | 74 | B | B | B |

TABLE 8

| | Exposure | Exposure | Amount of | Via taper angle | uHAST | HTS | Thermal |
|---|---|---|---|---|---|---|---|
| | Na | illuminance | exposure | (degree) | test | TEST | cycle test |
| Example 46 | 0.16 | 10000 W/m² | 400 mj/cm² | 72 | B | B | B |
| Example 47 | 0.16 | 10000 W/m² | 400 mj/cm² | 83 | A | B | A |
| Example 48 | 0.16 | 10000 W/m² | 400 mj/cm² | 84 | B | A | A |
| Example 49 | 0.16 | 10000 W/m² | 400 mj/cm² | 80 | B | B | B |
| Example 50 | 0.16 | 10000 W/m² | 400 mj/cm² | 79 | A | B | A |
| Example 51 | 0.16 | 10000 W/m² | 400 mj/cm² | 80 | A | A | A |
| Example 52 | 0.16 | 10000 W/m² | 400 mj/cm² | 78 | A | A | A |
| Example 53 | 0.16 | 10000 W/m² | 400 mj/cm² | 81 | A | A | A |
| Example 54 | 0.16 | 10000 W/m² | 400 mj/cm² | 80 | A | A | A |
| Example 55 | 0.16 | 10000 W/m² | 400 mj/cm² | 81 | B | B | B |
| Example 56 | 0.16 | 10000 W/m² | 400 mj/cm² | 80 | A | B | A |
| Comparative | 0.10 | 10000 W/m² | 400 mj/cm² | 68 | B | C | C |
| Example 1 | | | | | | | |
| Comparative | 0.16 | 10000 W/m² | 40 mj/cm² | 111 | C | C | B |
| Example 2 | | | | | | | |

### Example (101)

A semiconductor package was prepared under the same conditions as in Example 1, except that the number of semiconductor dies of the semiconductor package of Example 1 was changed from one to two. The evaluation results were the same as in Example 1.

From the above results, it was found that the semiconductor package according to the embodiment of the present invention exhibited favorable results in all of the uHAST test, the HTS test, and the thermal cycle test.

The invention according to Comparative Example 1 has a taper angle of less than 70°. According to such an aspect, it was found that the results were poor in the HTS test and the thermal cycle test.

The invention according to Comparative Example 2 has a taper angle of more than 110°. According to such an aspect, it was found that the results were poor in the uHAST test and the HTS test.

### EXPLANATION OF REFERENCES

10: re-distribution layer A
12: insulating pattern A
14: conductive pattern A
16: conductive pad
18: exposed portion
20: semiconductor package
22: sealing layer
24: conductive connecting portion
26: substrate
28: semiconductor die
30: sealing material
32: electrode
34: other conductive connecting portion
36: conductive through via
38: other semiconductor die
40: other conductive pad
42: other conductive connecting portion
44: insulating layer
46: layer formed of curable resin composition
62: carrier wafer
64: second carrier wafer
102: conductive connecting portion
104: conductive pad
106: insulating pattern A in outermost layer of re-distribution layer A
108: conductive pattern A in outermost layer of re-distribution layer A
110: solder member
112: pillar
200: substrate including semiconductor die and sealing material
202: first insulating film
204: insulating pattern
206: conductive pattern
208: insulating layer including wiring
210: second insulating layer

What is claimed is:

1. A semiconductor package comprising:
a sealing layer containing at least one semiconductor die and a sealing material;
a re-distribution layer A in contact with the at least one semiconductor die and connected to a circuit of the semiconductor die;
a conductive connecting portion connected to the re-distribution layer A; and
a substrate connected to the conductive connecting portion,
wherein the re-distribution layer A is formed by laminating layers including an insulating pattern A and a conductive pattern A existing between patterns of the insulating pattern A, and
the insulating pattern A has a via structure, and an angle formed by a side surface of the via structure and a bottom surface of the insulating pattern A is 70° to 110°.

2. The semiconductor package according to claim 1,
wherein the sealing layer is a sealing layer including two or more semiconductor dies and a sealing material, and circuits of at least two of the two or more semiconductor dies are connected to the re-distribution layer A.

3. The semiconductor package according to claim 1, further comprising:
one or more semiconductor dies existing outside the sealing layer and connected to the re-distribution layer A.

4. The semiconductor package according to claim 1,
wherein the re-distribution layer A includes a laminated structure of four or more layers.

5. The semiconductor package according to claim 1,
wherein wiring in the re-distribution layer A includes a line pattern, and a minimum line width of the line pattern is 0.1 to 10 μm.

6. The semiconductor package according to claim 1,
wherein the insulating pattern A contains a resin having a repeating unit represented by Formula (1-1), 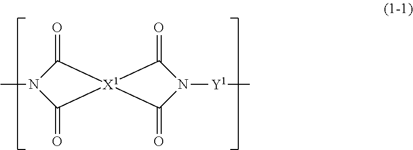
in Formula (1-1), X¹ represents an organic group having 4 or more carbon atoms, and Y¹ represents an organic group having 4 or more carbon atoms.

7. The semiconductor package according to claim 6,
wherein X¹ and Y¹ in Formula (1-1) each independently represent an organic group including a structure in which two or more hydrogen atoms are removed from a structure represented by any one of Formulae (V-1) to (V-4), 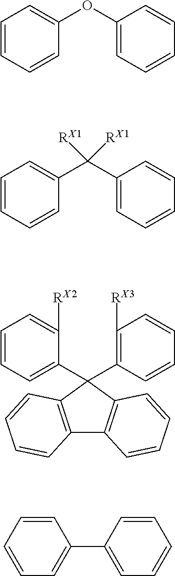
in Formula (V-2), R^{X1}'s each independently represent a hydrogen atom, an alkyl group, or a halogenated alkyl group,
in Formula (V-3), R^{X2} and R^{X3} each independently represent a hydrogen atom or a substituent, and R^{X2} and R^{X3} may be bonded to each other to form a ring structure.

8. A manufacturing method of a semiconductor package, comprising:
a sealing layer forming step of embedding a semiconductor die in a sealing material and forming a sealing layer in which a circuit of the semiconductor die is exposed on one surface and the circuit of the semiconductor die is not exposed on the other surface;
a re-distribution layer A forming step of forming a re-distribution layer A by laminating layers including an insulating pattern A and a conductive pattern A existing between patterns of the insulating pattern A, on the surface of the sealing layer on which the circuit is exposed;
a connecting portion forming step of forming a conductive connecting portion on a surface of the re-distribution layer A different from a surface in contact with the sealing layer; and
a step of connecting the connecting portion and a substrate,
wherein the re-distribution layer A forming step includes forming a via structure by the insulating pattern A, and
an angle formed by a side surface of the via structure and a bottom surface of the insulating pattern A is 70° to 110°.

9. The manufacturing method of a semiconductor package according to claim 8,
wherein the insulating pattern A is formed of a negative-tone photosensitive resin composition.

10. The manufacturing method of a semiconductor package according to claim 9,
wherein the negative-tone photosensitive resin composition contains a resin having at least one repeating unit of a repeating unit represented by Formula (4-1) or a repeating unit represented by Formula (4-2), 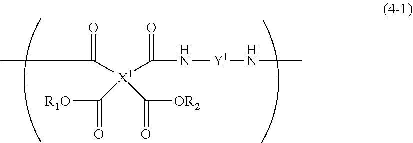
in Formula (4-1), X¹ represents a tetravalent organic group, Y¹ is a divalent organic group, and R¹ and R² each independently represent a hydrogen atom or a monovalent organic group, 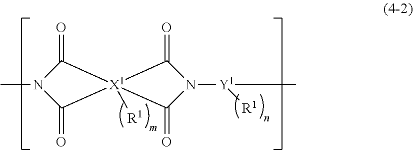
in Formula (4-2), X¹ represents an organic group having 4 or more carbon atoms, Y¹ represents an organic group having 4 or more carbon atoms, R¹'s each independently represent a structure including a polymerizable group, and n and m each independently represent an integer of 0 to 4.

11. The manufacturing method of a semiconductor package according to claim 10,
wherein X¹ and Y¹ in Formula (4-1) each independently represent an organic group including a structure in which two or more hydrogen atoms are removed from a structure represented by any one of Formulae (V-1) to (V-4), and X¹ and Y¹ in Formula (4-2) each independently represent an organic group including a structure in which two or more hydrogen atoms are removed from the structure represented by any one of Formulae (V-1) to (V-4), 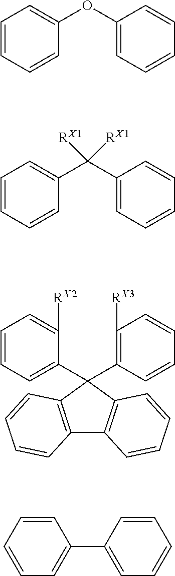
in Formula (V-2), R^{X1} 's each independently represent a hydrogen atom, an alkyl group, or a halogenated alkyl group,
in Formula (V-3), R^{X2} and R^{X3} each independently represent a hydrogen atom or a substituent, and R^{X2} and R^{X3} may be bonded to each other to form a ring structure.

12. The manufacturing method of a semiconductor package according to claim 9,
wherein the negative-tone photosensitive resin composition contains an oxime initiator.

13. The manufacturing method of a semiconductor package according to claim 9,
wherein the negative-tone photosensitive resin composition contains a polymerizable compound having two or more ethylenically unsaturated bonds.

14. The manufacturing method of a semiconductor package according to claim 9,
wherein in the re-distribution layer A forming step, a photosensitive film formed of the negative-tone photosensitive resin composition is exposed using an i-line stepper.

15. The manufacturing method of a semiconductor package according to claim 14,
wherein a numerical aperture of the i-line stepper is 0.10 to 0.60.

16. The manufacturing method of a semiconductor package according to claim 14,
wherein an exposure illuminance of the i-line stepper is 500 to 50,000 W/m².

17. The manufacturing method of a semiconductor package according to claim 14,
wherein an exposure amount using the i-line stepper is 1 to 2,000 mJ/cm².

18. The manufacturing method of a semiconductor package according to claim 8,
wherein the via structure is formed by development using a solvent as a developer.
